(19) United States
(12) Patent Application Publication
(10) Pub. No.: US 2024/0352775 A1
(43) Pub. Date: Oct. 24, 2024

(54) SYSTEM FOR CONTROLLING AN OPERATING STATE OF AN ACCESS CLOSURE OF A MOTOR VEHICLE

(71) Applicant: ADAC PLASTICS, INC., Grand Rapids, MI (US)

(72) Inventors: Keith SCHEIERN, Lowell, MI (US); Anne ADAMCZYK, Grand Rapids, MI (US); Alexander GABIER, Kentwood, MI (US); Josh GOULET, Dorr, MI (US); Ryan BUSSIS, Caledonia, MI (US)

(21) Appl. No.: 18/747,067

(22) Filed: Jun. 18, 2024

Related U.S. Application Data
(63) Continuation-in-part of application No. 18/182,805, filed on Mar. 13, 2023, now Pat. No. 12,044,047.
Application No. 18/182,805 is a continuation of application No. 17/898,592, filed on Aug. 30, 2022, now Pat. No. 11,739,573.
Application No. 17/898,592 is a continuation of application No. 16/209,498, filed on Dec. 4, 2018, now Pat. No. 11,441,341.
(60) Provisional application No. 63/509,439, filed on Jun. 21, 2023.
(60) Provisional application No. 62/594,900, filed on Dec. 5, 2017.

(51) Int. Cl. E05B 85/16; E05B 77/34; E05B 81/76; G01D 5/12; G01R 27/26

(52) U.S. Cl. CPC E05B 85/16; E05B 81/77; G01D 5/12; G01R 27/2605; G01R 27/2611; E05B 77/34

(57) ABSTRACT

A system for at least two of locking, unlocking, unlatching, opening or closing an access closure of a motor vehicle may include a plurality of sensors, each mounted to or within an access closure handle mounted to the access closure or to or within at least one component of the motor vehicle that is not an access closure handle, the plurality of sensors including first and second sensors configured to produce respective first and second sensor signals and to produce detectable changes in the sensor signals upon detection of at least one respective sensor activation event, one or more signal processing circuits configured to be responsive to the detectable changes in the sensor signals to produce respective control signals, and means responsive to the control signals to carry out at least two of locking, unlocking, unlatching, opening or closing of the access closure of the motor vehicle.

### CROSS-REFERENCE TO RELATED APPLICATIONS

This patent application claims the benefit of and priority to U.S. Provisional Patent Application Ser. No. 63/509,439, filed Jun. 21, 2023, and is a continuation-in-part of application Ser. No. 18/182,805, filed Mar. 13, 2023, which is a continuation of application Ser. No. 17/898,592, filed Aug. 30, 2022 and now U.S. Pat. No. 11,739,573, which is a continuation of application Ser. No. 16/209,498, filed Dec. 4, 2018 and now U.S. Pat. No. 11,441,341, which claims the benefit of and priority to U.S. Provisional Patent Application Ser. No. 62/594,900, filed Dec. 5, 2017, the disclosures of which are all incorporated herein by reference in their entireties.

### FIELD OF THE INVENTION

The present invention relates generally to access closures of motor vehicles, and more specifically to systems for controlling operating states of such access closures.

### BACKGROUND

Access closure assemblies for motor vehicles which include keyless entry features are generally known. It is desirable to provide improved access closure capabilities with one or more sensor-based control features.

### SUMMARY

The present invention may comprise one or more of the features recited in the attached claims, and/or one or more of the following features and combinations thereof. In a first aspect, a system for at least one of locking, unlocking, unlatching, opening or closing an access closure of a motor vehicle may comprise at least one sensor, mounted to or within at least one component of the motor vehicle, and configured to produce at least one sensor signal, the at least one sensor configured to produce a detectable change in the at least one sensor signal upon detection of at least one sensor activation event, one or more signal processing circuits configured to be responsive to the detectable change in the at least one sensor signal to produce at least one corresponding control signal, and means responsive to the at least one control signal to at least one of lock, unlock, unlatch, open or close the access closure of the motor vehicle.

A second aspect includes the features of the first aspect, and wherein the at least one sensor comprises two or more sensors mounted to or within the at least one component of the motor vehicle, wherein the one or more signal processing circuits is configured to be responsive to the detectable change in the at least one sensor signal produced by one of the two or more sensors to produce a first control signal, and to be responsive to the detectable change in the at least one sensor signal produced by another of the two or more sensor signals to produce a second control signal, and wherein the means responsive to the at least one control signal is responsive to the first control signal to lock the access closure and to the second control signal to unlock the access closure.

A third aspect includes the features of the second aspect, and wherein the one or more signal processing circuits is configured to be responsive to the detectable change in the at least one sensor signal produced by yet another of the two or more sensors to produce a third control signal, and wherein the means responsive to the at least one control signal is responsive to the third control signal to unlatch the access closure after the access closure is unlocked.

A fourth aspect includes the features of the first aspect, and wherein the at least one sensor comprises two or more sensors mounted to or within the at least one component of the motor vehicle, wherein the one or more signal processing circuits is configured to be responsive to the detectable change in the at least one sensor signal produced by one of the two or more sensors to produce a first control signal, and to be responsive to the detectable change in the at least one sensor signal produced by another of the two or more sensor signals to produce a second control signal, and wherein the means responsive to the at least one control signal is responsive to the first control signal to at least one of lock or unlock the access closure and to the second control signal to unlatch the access closure.

A fifth aspect includes the features of the fourth aspect, and wherein the one or more signal processing circuits is configured to be responsive to the detectable change in the at least one sensor signal produced by yet another of the two or more sensors to produce a third control signal, and wherein the means responsive to the at least one control signal is responsive to the first control signal to one of lock or unlock the access closure and to the third control signal to the other of lock or unlock the access closure.

A sixth aspect includes the features of the first aspect, and wherein the at least one sensor comprises a first sensor mounted to or within the at least one component of the motor vehicle, wherein the one or more signal processing circuits is configured to be responsive to a first detectable change in the at least one sensor signal produced by the first sensor to produce a first control signal and to be responsive to a second detectable change in the at least one sensor signal produced by the first sensor to produce a second control signal, and wherein the means responsive to the at least one control signal is responsive to the first control signal to one of open or close the access closure and to the second control signal to the other of open or close the access closure.

A seventh aspect includes the features of the sixth aspect, and wherein the at least one sensor further comprises a second sensor mounted to or within the at least one component of the motor vehicle, wherein the one or more signal processing circuits is configured to be responsive to a first detectable change in the at least one sensor signal produced by the second sensor to produce a third control signal and to be responsive to a second detectable change in the at least one sensor signal produced by the second sensor to produce a fourth control signal, and wherein the means responsive to the at least one control signal is responsive to the third control signal to one of lock or unlock the access closure and to the fourth control signal to the other of lock or unlock the access closure.

An eighth aspect includes the features of the sixth aspect, and wherein the at least one sensor further comprises second and third sensors mounted to or within the at least one component of the motor vehicle, wherein the one or more signal processing circuits is configured to be responsive to a detectable change in the at least one sensor signal produced by the second sensor to produce a third control signal and to be responsive to a detectable change in the at least one sensor signal produced by the third sensor to produce a fourth control signal, and wherein the means responsive to the at least one control signal is responsive to the third control signal to one of lock or unlock the access closure and to the fourth control signal to the other of lock or unlock the access closure.

A ninth aspect includes the features of the first aspect, and wherein the at least one sensor comprises two or more sensors mounted to or within the at least one component of the motor vehicle, wherein the one or more signal processing circuits is configured to be responsive to the detectable change in the at least one sensor signal produced by one of the two or more sensors to produce a first control signal, and to be responsive to the detectable change in the at least one sensor signal produced by another of the two or more sensor signals to produce a second control signal, and wherein the means responsive to the at least one control signal is responsive to the first control signal to open the access closure and to the second control signal to close the access closure.

A tenth aspect includes the features of the ninth aspect, and wherein the one or more signal processing circuits is configured to be responsive to the detectable change in the at least one sensor signal produced by yet another of the two or more sensors to produce a third control signal, and wherein the means responsive to the at least one control signal is responsive to the third control signal to at least one of lock and unlock the access closure.

An eleventh aspect includes the features of the tenth aspect, and wherein the one or more signal processing circuits is configured to be responsive to the detectable change in the at least one sensor signal produced by a further of the two or more sensor signals to produce a fourth control signal, and wherein the means responsive to the at least one control signal is responsive to the third control signal to one of lock or unlock the access closure, and to the fourth control signal to the other of lock or unlock the access closure.

A twelfth aspect includes the features of the first aspect, and wherein the at least one component of the motor vehicle is not an access closure handle.

A thirteenth aspect includes the features of the twelfth aspect, and wherein the at least one component of the motor vehicle comprises at least one or any combination of a front access closure, a rear access closure, a window frame, an A-pillar, a B-pillar, a C-pillar, a top, a housing of a side-view mirror, a mirror of a side-view mirror, one or more windows, a rear side panel, a front side panel, a hood, a frunk lid, a rocker panel, a headlamp, a headlamp housing, a front running lamp or housing, a turn signal lamp or housing, a front dam or skirt, an underside, a trunk lid, a tail lamp or housing, a rear bumper or skirt, a charge port closure or a badge of the motor vehicle.

A fourteenth aspect includes the features of the first aspect, and further comprising an access closure handle mounted to the access closure of the motor vehicle, wherein the at least one sensor is mounted to or within the access closure handle, wherein the at least one sensor comprises two or more sensors mounted to or within the access closure handle, wherein the one or more signal processing circuits is configured to be responsive to the detectable change in the at least one sensor signal produced by one of the two or more sensors to produce a first control signal, and to be responsive to the detectable change in the at least one sensor signal produced by another of the two or more sensor signals to produce a second control signal, and wherein the means responsive to the at least one control signal is responsive to the first control signal to lock the access closure and to the second control signal to unlock the access closure.

A fifteenth aspect includes the features of the fourteenth aspect, and wherein the one or more signal processing circuits is configured to be responsive to the detectable change in the at least one sensor signal produced by yet another of the two or more sensors to produce a third control signal, and wherein the means responsive to the at least one control signal is responsive to the third control signal to unlatch the access closure after the access closure is unlocked.

A sixteenth aspect includes the features of the first aspect, and further comprising an access closure handle mounted to the access closure of the motor vehicle, wherein the at least one sensor is mounted to or within the access closure handle, wherein the at least one sensor comprises two or more sensors mounted to or within the access closure handle, wherein the one or more signal processing circuits is configured to be responsive to the detectable change in the at least one sensor signal produced by one of the two or more sensors to produce a first control signal, and to be responsive to the detectable change in the at least one sensor signal produced by another of the two or more sensor signals to produce a second control signal, and wherein the means responsive to the at least one control signal is responsive to the first control signal to at least one of lock or unlock the access closure and to the second control signal to unlatch the access closure.

A seventeenth aspect includes the features of the sixteenth aspect, and wherein the one or more signal processing circuits is configured to be responsive to the detectable change in the at least one sensor signal produced by yet another of the two or more sensors to produce a third control signal, and wherein the means responsive to the at least one control signal is responsive to the first control signal to one of lock or unlock the access closure and to the third control signal to the other of lock or unlock the access closure.

An eighteenth aspect includes the features of the first aspect, and further comprising an access closure handle mounted to the access closure of the motor vehicle, wherein the at least one sensor comprises a first sensor mounted to or within the access closure handle, wherein the one or more signal processing circuits is configured to be responsive to a first detectable change in the at least one sensor signal produced by the first sensor to produce a first control signal and to be responsive to a second detectable change in the at least one sensor signal produced by the first sensor to produce a second control signal, and wherein the means responsive to the at least one control signal is responsive to the first control signal to one of open or close the access closure and to the second control signal to the other of open or close the access closure.

A nineteenth aspect includes the features of the eighteenth aspect, and wherein the at least one sensor further comprises a second sensor mounted to or within the access closure handle, wherein the one or more signal processing circuits is configured to be responsive to a first detectable change in the at least one sensor signal produced by the second sensor to produce a third control signal and to be responsive to a second detectable change in the at least one sensor signal produced by the second sensor to produce a fourth control signal, and wherein the means responsive to the at least one control signal is responsive to the third control signal to one of lock or unlock the access closure and to the fourth control signal to the other of lock or unlock the access closure.

A twentieth aspect includes the features of the eighteenth aspect, and wherein the at least one sensor further comprises second and third sensors mounted to or within the access closure handle, wherein the one or more signal processing circuits is configured to be responsive to a detectable change in the at least one sensor signal produced by the second sensor to produce a third control signal and to be responsive to a detectable change in the at least one sensor signal produced by the third sensor to produce a fourth control signal, and wherein the means responsive to the at least one control signal is responsive to the third control signal to one of lock or unlock the access closure and to the fourth control signal to the other of lock or unlock the access closure

A twenty first aspect includes the features of the first aspect, and further comprising an access closure handle mounted to the access closure of the motor vehicle, wherein the at least one sensor is mounted to or within the access closure handle, wherein the at least one sensor comprises two or more sensors mounted to or within the access closure handle, wherein the one or more signal processing circuits is configured to be responsive to the detectable change in the at least one sensor signal produced by one of the two or more sensors to produce a first control signal, and to be responsive to the detectable change in the at least one sensor signal produced by another of the two or more sensor signals to produce a second control signal, and wherein the means responsive to the at least one control signal is responsive to the first control signal to open the access closure and to the second control signal to close the access closure.

A twenty second aspect includes the features of the twenty first aspect, and wherein the two or more sensors comprises a third sensor mounted to or within the access closure handle, wherein the one or more signal processing circuits is configured to be responsive to the detectable change in the at least one sensor signal produced by the third sensor to produce a third control signal, and wherein the means responsive to the at least one control signal is responsive to the third control signal to at least one of lock and unlock the access closure.

A twenty third aspect includes the features of the twenty second aspect, and wherein the two or more sensors comprises a fourth sensor mounted to or within the access closure handle, wherein the one or more signal processing circuits is configured to be responsive to the detectable change in the at least one sensor signal produced by the fourth sensor to produce a fourth control signal, and wherein the means responsive to the at least one control signal is responsive to the third control signal to one of lock and unlock the access closure and to the fourth control signal to the other of lock and unlock the access closure.

A twenty fourth aspect may include the features of the first aspect, and may further comprise an access closure handle mounted to the access closure of the motor vehicle, and wherein the at least one sensor may comprise two or more sensors, and wherein one of the two or more sensors may be mounted to or within the access closure handle, and another of the two or more sensors may be mounted to or within a component of the motor vehicle that is separate from the access closure handle, and wherein the one or more signal processing circuits may be configured to be responsive to the detectable change in the at least one sensor signal produced by the one of the two or more sensors to produce a first control signal, and to be responsive to the detectable change in the at least one sensor signal produced by the another of the two or more sensor signals to produce a second control signal, and wherein the means responsive to the at least one control signal may be responsive to the first control signal to at least one of lock the access closure or unlock the access closure, and to the second control signal to unlatch the access closure.

A twenty fifth aspect may include the features of the twenty fourth aspect, and wherein yet another of the two or more sensors may be mounted to or within the access closure handle, and wherein the one or more signal processing circuits may be configured to be responsive to the detectable change in the at least one sensor signal produced by the yet another of the two or more sensors to produce a third control signal, and wherein the means responsive to the at least one control signal may be responsive to the first control signal to lock the access closure and to the third control signal to unlock the access closure.

A twenty sixth aspect may include the features of the twenty fourth aspect, and wherein yet another of the two or more sensors may be mounted to or within the component of the motor vehicle that is separate from the access closure handle or to or within another component of the motor vehicle that is separate from the access closure handle, and wherein the one or more signal processing circuits may be configured to be responsive to the detectable change in the at least one sensor signal produced by the yet another of the two or more sensors to produce a third control signal, and wherein the means responsive to the at least one control signal may be responsive to the first control signal to lock the access closure and to the third control signal to unlock the access closure.

A twenty seventh aspect may include the features of the first aspect, and may further comprise an access closure handle mounted to the access closure of the motor vehicle, and wherein the at least one sensor may comprise two or more sensors, and wherein one of the two or more sensors may be mounted to or within the access closure handle, and another of the two or more sensors may be mounted to or within a component of the motor vehicle that is separate from the access closure handle, and wherein the one or more signal processing circuits may be configured to be responsive to the detectable change in the at least one sensor signal produced by the one of the two or more sensors to produce a first control signal, and to be responsive to the detectable change in the at least one sensor signal produced by the another of the two or more sensor signals to produce a second control signal, and wherein the means responsive to the at least one control signal may be responsive to the first control signal to unlatch the access closure, and to the second control signal to at least one of lock the access closure or unlock the access closure.

A twenty eighth aspect may include the features of the twenty seventh aspect, and wherein yet another of the two or more sensors may be mounted to or within the access closure handle, and wherein the one or more signal processing circuits may be configured to be responsive to the detectable change in the at least one sensor signal produced by the yet another of the two or more sensors to produce a third control signal, and wherein the means responsive to the at least one control signal may be responsive to the second control signal to one of lock or unlock the access closure, and to the third control signal to the other of lock or unlock the access closure.

A twenty ninth aspect may include the features of the twenty seventh aspect, and wherein yet another of the two or more sensors may be mounted to or within the component of the motor vehicle that is separate from the access closure handle or to or within another component of the motor vehicle that is separate from the access closure handle, and wherein the one or more signal processing circuits may be configured to be responsive to the detectable change in the at least one sensor signal produced by the yet another of the two or more sensors to produce a third control signal, and wherein the means responsive to the at least one control signal may be responsive to the second control signal to lock the access closure and to the third control signal to unlock the access closure.

A thirtieth aspect may include the features of the first aspect, and may further comprise an access closure handle mounted to the access closure of the motor vehicle, and wherein the at least one sensor may comprise two or more sensors, and wherein one of the two or more sensors may be mounted to or within the access closure handle, and another of the two or more sensors may be mounted to or within a component of the motor vehicle that is separate from the access closure handle, and wherein the one or more signal processing circuits may be configured to be responsive to the detectable change in the at least one sensor signal produced by the one of the two or more sensors to produce a first control signal, and to be responsive to the detectable change in the at least one sensor signal produced by the another of the two or more sensor signals to produce a second control signal, and wherein the means responsive to the at least one control signal may be responsive to the first control signal to one of open or close the access closure, and to the second control signal to the other of open or close the access closure.

A thirty first aspect may include the features of the thirtieth aspect, and wherein yet another of the two or more sensors may be mounted to or within the access closure handle, and wherein the one or more signal processing circuits may be configured to be responsive to the detectable change in the at least one sensor signal produced by the yet another of the two or more sensors to produce a third control signal, and wherein the means responsive to the at least one control signal may be responsive to the third control signal to one of lock or unlock the access closure.

A thirty second aspect may include the features of the thirty first aspect, and wherein a further of the two or more sensors may be mounted to or within the access closure handle, and wherein the one or more signal processing circuits may be configured to be responsive to the detectable change in the at least one sensor signal produced by the further of the two or more sensors to produce a fourth control signal, and wherein the means responsive to the at least one control signal may be responsive to the fourth control signal to the other of lock or unlock the access closure.

A thirty third aspect may include the features of the thirty first aspect, and wherein a further of the two or more sensors may be mounted to or within the component of the motor vehicle that is separate from the access closure handle or mounted to or within another component of the motor vehicle that is separate from the access closure handle, and wherein the one or more signal processing circuits may be configured to be responsive to the detectable change in the at least one sensor signal produced by the further of the two or more sensors to produce a fourth control signal, and wherein the means responsive to the at least one control signal may be responsive to the second control signal to the other of lock or unlock the access closure.

A thirty fourth aspect may include the features of the thirtieth aspect, and wherein yet another of the two or more sensors may be mounted to or within the component of the motor vehicle that is separate from the access closure handle or mounted to or within another component of the motor vehicle that is separate from the access closure handle, and a further of the two or more sensors is mounted to or within the component of the motor vehicle that is separate from the access closure handle, mounted to or within the another component of the motor vehicle that is separate from the access closure handle, or mounted to or within yet another component of the motor vehicle that is separate from the access closure handle, and wherein the one or more signal processing circuits may be configured to be responsive to the detectable change in the at least one sensor signal produced by the yet another of the two or more sensors to produce a third control signal and to the at least one sensor signal produced by the further of the two or more sensors to produce a fourth control signal, and wherein the means responsive to the at least one control signal may be responsive to the third control signal to one of lock or unlock the access closure and to the fourth control signal to the other of lock or unlock the access closure.

A thirty fifth aspect may include the features of any one or combination of the first through thirty fourth aspects, and wherein the at least one sensor may comprise one or any combination of at least one short range, non-contacting proximity sensor, at least one long range, non-contacting proximity sensor, at least one deflective touch sensor, at least one non-deflective touch sensor, or at least one other sensor.

A thirty sixth aspect includes the features of any of the first through fifth, seventh through eighth, tenth through seventeenth, nineteenth through twentieth, twenty second through twenty ninth, or thirty first through thirty fifth aspects, and wherein the means responsive to the at least one control signal to at least one of lock or unlock the access closure comprises an actuator, and a closure lock, the actuator responsive to the at least one control signal to cause the closure lock to lock or unlock.

A thirty seventh aspect includes the features of any of the first through fifth, seventh through eighth, tenth through seventeenth, nineteenth through twentieth, twenty second through twenty ninth, or thirty first through thirty fifth aspects, wherein the means responsive to the at least one control signal to at least one of lock or unlock the access closure comprises an E-latch module, and a closure lock, the E-latch module responsive to the at least one control signal to cause the closure lock to lock or unlock.

A thirty eighth aspect includes the features of any of the first, third through fifth, fifteenth through seventeenth, twenty fourth through twenty ninth, or thirty fifth aspects, wherein the means responsive to the at least one control signal to unlatch the access closure comprises a closure latch, and an E-latch module, the E-latch module responsive to the at least one control signal to cause the closure latch to unlatch.

A thirty ninth aspect includes the features of any of the first, sixth through eleventh, eighteenth through twenty third, or thirtieth through thirty fifth aspects, wherein the means responsive to the at least one control signal to open or close the access closure comprises a motor, and a motor driver, the motor driver responsive to the at least one control signal to cause the motor to open or close the access closure.

A fortieth aspect includes the features of any of the first through thirty ninth aspects, and further comprising at least one accessory associated with the system or with the motor vehicle, and wherein the at least one accessory is responsive to the at least one control signal to control operation of the at least one accessory.

A forty first aspect includes the features of the fortieth aspect, and wherein the at least one accessory comprises one or any combination at least one lamp internal to the motor vehicle, at least one lamp external to the motor vehicle, at least one power window, at least one power occupant seat, at least one occupant seat heater, at least one occupant seat cooling device, at least one occupant seat support or comfort device, at least one haptic feedback device internal to the motor vehicle, at least one haptic feedback device external to the motor vehicle, a climate control system of the motor vehicle, an entertainment system of the motor vehicle, a color of at least one interior or external surface of the motor vehicle, a retractable roof of the motor vehicle, a position of a rearview or side mirror, a position of a steering wheel position of the motor vehicle, and a display screen mounted within or to an external surface of the motor vehicle.

A forty second aspect includes the features of any of the first through forty first aspect, wherein the one or more signal processing circuits comprises a processor, and a memory having instructions stored therein executable by the processor to cause the processor to be responsive to the detectable change in the at least one sensor signal to produce the at least one corresponding control signal.

A forty third aspect includes the features of the forty second aspect, and wherein the processor and the memory are mounted to or within the at least one component of the motor vehicle.

In a forty fourth aspect, a door handle assembly for a motor vehicle door may comprise a first housing component having an inner surface and an outer surface, a second housing component having an inner surface and an outer surface, the first and second housing components together forming a housing with the inner surfaces of the first and second housing components facing one another and with outer surfaces of the first and second housing components together defining an outer surface of the housing, the housing configured to be mounted to the motor vehicle door to define at least a portion of a door handle, a first sensor mounted in the housing along a first detection surface defined by at least a portion of the outer surface of the housing, the first sensor configured to produce a first sensor signal upon detection of one of an object within a detection proximity of the first detection surface and deflection of at least a portion of the inner surface of the housing opposite the first detection surface to within a detection proximity of the first sensor, and a second sensor mounted in the housing along a second detection surface defined by at least another portion of the outer surface of the housing, the second sensor configured to produce a second sensor signal upon detection of deflection of at least a portion of the inner surface of the housing opposite the second detection surface to within a detection proximity of the second sensor, wherein the first and second sensor signals are configured to enable any of locking, unlocking, latching, unlatching, automatically opening and automatically closing of the motor vehicle door.

A forty fifth aspect includes the features of the forty fourth aspect, and wherein the first sensor signal is configured to enable one of unlocking and unlocking of the motor vehicle door and the second sensor signal is configured to enable the other of locking and unlocking of the motor vehicle door.

A forty sixth aspect includes the features of the forty fourth aspect, and wherein one of the first and second sensor signals is configured to enable at least one of unlocking and unlocking of the motor vehicle door, and the other of the first and second sensor signals is configured to enable unlatching of the motor vehicle door.

A forty seventh aspect includes the features of the forty fourth aspect, and wherein one of the first and second sensor signals is configured to enable at least one of unlocking and unlocking of the motor vehicle door, and the other of the first and second sensor signals is configured to enable at least one of automatic opening and automatic closing of the motor vehicle door.

A forty eighth aspect includes the features of any of the forty fourth through forty seventh aspects, and further comprising a processor mounted in the housing, and memory mounted in the housing and having instructions stored therein executable by the processor cause the processor to be responsive to the first and second sensor signals to control any of the locking, unlocking, latching, unlatching, automatically opening and automatically closing of the motor vehicle door.

In a forty ninth aspect, a system for at least two of locking, unlocking, unlatching, opening or closing an access closure of a motor vehicle may comprise a plurality of sensors, each mounted to or within an access closure handle mounted to the access closure of the motor vehicle or to or within at least one component of the motor vehicle that is not an access closure handle, the plurality of sensors including first and second sensors configured to produce respective first and second sensor signals and to produce detectable changes in the respective first and second sensor signals upon detection of at least one respective sensor activation event, one or more signal processing circuits configured to be responsive to the detectable changes in the first and second sensor signals to produce respective first and second control signals, and means responsive to the first and second control signals to carry out at least two of locking, unlocking, unlatching, opening or closing of the access closure of the motor vehicle.

A fiftieth aspect includes the features of the forty ninth aspect, and wherein the means responsive to the first and second control signals is responsive to one of the first and second control signals to at least one of lock or unlock the access closure and to the other of the first and second control signals to unlatch the access closure.

A fifty first aspect includes the features of the fiftieth aspect, and wherein the means responsive to the first and second control signals is responsive to the one of the first and second control signals to lock and unlock the access closure.

A fifty second aspect includes the features of the fiftieth aspect, and wherein the plurality of sensors includes a third sensor configured to produce a third sensor signal and to produce detectable change in the third sensor signal upon detection by the third sensor of at least one corresponding sensor activation event, and wherein the means responsive to the first and second control signals is responsive to the one of the first and second control signals to one of lock or unlock the access closure and to the third control signal to the other of lock or unlock the access closure.

A fifty third aspect includes the features of the forty ninth aspect, and wherein the means responsive to the first and second control signals is responsive to one of the first and second control signals to lock the access closure and to the other of the first and second control signals to unlock the access closure.

A fifty fourth aspect includes the features of the fifty third aspect, and wherein the plurality of sensors includes a third sensor configured to produce a third sensor signal and to produce detectable change in the third sensor signal upon detection by the third sensor of at least one corresponding sensor activation event, and wherein the one or more signal processing circuits is configured to be responsive to the detectable change in the third sensor signal to produce a third control signal, and wherein the means responsive to the first and second control signals is responsive to the third control signal to unlatch the access closure after the access closure is unlocked.

A fifty fifth aspect includes the features of the forty ninth aspect, and wherein the means responsive to the first and second control signals is responsive to one of the first and second control signals to at least one of open or close the access closure and to the other of the first and second control signals to at least one of lock or unlock the access closure.

A fifty sixth aspect includes the features of the fifty fifth aspect, and wherein the means responsive to the first and second control signals is responsive to the one of the first and second control signals to open and close the access closure.

A fifty seventh aspect includes the features of the fifty sixth aspect, and wherein the means responsive to the first and second control signals is responsive to the other of the first and second control signals lock and unlock the access closure.

A fifty eighth aspect includes the features of the fifty sixth aspect, and wherein the plurality of sensors includes a third sensor configured to produce a third sensor signal and to produce detectable change in the third sensor signal upon detection by the third sensor of at least one corresponding sensor activation event, and wherein the one or more signal processing circuits is configured to be responsive to the detectable change in the third sensor signal to produce a third control signal, and wherein the means responsive to the first and second control signals is responsive to the other of the first and second control signals to one of lock or unlock the access closure and to the third control signal to the other of lock or unlock the access closure.

A fifty ninth aspect includes the features of the fifty fifth aspect, and wherein the plurality of sensors includes a third sensor configured to produce a third sensor signal and to produce detectable change in the third sensor signal upon detection by the third sensor of at least one corresponding sensor activation event, and wherein the one or more signal processing circuits is configured to be responsive to the detectable change in the third sensor signal to produce a third control signal, and wherein the means responsive to the first and second control signals is responsive to the one of the first and second control signals to one of open or close the access closure and to the third control signal to the other of open or close the access closure.

A sixtieth aspect includes the features of the fifty ninth aspect, and wherein the means responsive to the first and second control signals is responsive to the other of the first and second control signals lock and unlock the access closure.

A sixty first aspect includes the features of the fifty ninth aspect, and wherein the plurality of sensors includes a fourth sensor configured to produce a fourth sensor signal and to produce detectable change in the fourth sensor signal upon detection by the fourth sensor of at least one corresponding sensor activation event, and wherein the one or more signal processing circuits is configured to be responsive to the detectable change in the fourth sensor signal to produce a fourth control signal, and wherein the means responsive to the first and second control signals is responsive to the other of the first and second control signals to one of lock or unlock the access closure and to the fourth control signal to the other of lock or unlock the access closure.

A sixty second aspect includes the features of any of the forty ninth through sixty first aspects, and wherein the at least one component of the motor vehicle comprises one or any combination of a front access closure, a rear access closure, a window frame, an A-pillar, a B-pillar, a C-pillar, a top, a housing of a side-view mirror, a mirror of a side-view mirror, one or more windows, a rear side panel, a front side panel, a hood, a frunk lid, a rocker panel, a headlamp, a headlamp housing, a front running lamp or housing, a turn signal lamp or housing, a front dam or skirt, an underside, a trunk lid, a tail lamp or housing, a rear bumper or skirt, a charge port closure or a badge of the motor vehicle.

A sixty third aspect includes the features of any of the forty ninth through sixty second aspects, and wherein the plurality of sensors comprises any of one or more short range, non-contacting proximity sensors, one or more long range, non-contacting proximity sensors, one or more deflective touch sensors, one or more non-deflective touch sensors, or one or more other sensors, or any combination thereof.

A sixty fourth aspect includes the features of any of the forty ninth through sixty third aspects, and wherein the means responsive to the first and second control signals includes an actuator, and a closure lock, wherein the actuator is responsive to at least one of the first and second control signals to cause the closure lock to lock and unlock.

A sixty fifth aspect includes the features of any of the forty ninth through sixty third aspects, and wherein the means responsive to the first and second control signals includes an E-latch module, and a closure lock, wherein the E-latch module is responsive to at least one of the first and second control signals to cause the closure lock to lock and unlock.

A sixty sixth aspect includes the features of any of the forty ninth through sixty third aspects, and wherein the means responsive to the first and second control signals includes a closure latch, and an E-latch module, wherein the E-latch module is responsive to at least one of the first and second control signals to cause the closure latch to unlatch.

A sixty seventh aspect includes the features of any of the forty ninth through sixty sixth aspects, and further comprising at least one accessory associated with the system or with the motor vehicle, and wherein the at least one accessory is responsive to the first or second control signal to control operation of the at least one accessory, and wherein the at least one accessory comprises one or any combination at least one lamp internal to the motor vehicle, at least one lamp external to the motor vehicle, at least one power window, at least one power occupant seat, at least one occupant seat heater, at least one occupant seat cooling device, at least one occupant seat support or comfort device, at least one haptic feedback device internal to the motor vehicle, at least one haptic feedback device external to the motor vehicle, a climate control system of the motor vehicle, an entertainment system of the motor vehicle, a color of at least one interior or external surface of the motor vehicle, a retractable roof of the motor vehicle, a position of a rearview or side mirror, a position of a steering wheel position of the motor vehicle, and a display screen mounted within or to an external surface of the motor vehicle.

A sixty eighth aspect includes the features of any of the forty ninth through sixty seventh aspects, and wherein the one or more signal processing circuits comprises a processor, and a memory having instructions stored therein executable by the processor to cause the processor to be responsive to the detectable changes in the first and second sensor signals to produce the respective first and second control signals.

### BRIEF DESCRIPTION OF THE DRAWINGS

This disclosure is illustrated by way of example and not by way of limitation in the accompanying Figures. Where considered appropriate, reference labels have been repeated among the Figures to indicate corresponding or analogous elements.

FIG. 1 is a front perspective view of an embodiment of a door handle assembly.

FIG. 2 is a front perspective exploded view of the door handle assembly depicted in FIG. 1.

FIG. 3 is a perspective view of a circuit board subassembly of the door handle assembly of FIG. 2 in which the circuit board is mounted to the circuit board carrier and the sensor cartridge assembly is electrically connected to the circuit board.

FIG. 4 is a perspective view of the sensor assembly illustrated in FIGS. 2 and 3.

FIG. 5 is a perspective view of the sensor cartridge illustrated in FIGS. 2 and 3.

FIG. 6 is a rear perspective view of the grip cover depicted in FIGS. 1 and 2.

FIG. 7 is a rear perspective view similar to FIG. 6 and further illustrating mounting therein of the circuit board subassembly.

FIG. 8A is a magnified view of a portion of the rear side of the grip cover illustrating mounting of the sensor cartridge assembly thereto.

FIG. 8B is a magnified view similar to FIG. 8A but with the sensor cartridge omitted to illustrate positioning of the sensor relative to the grip cover.

FIG. 9 is a cross-sectional view of the handle base of FIG. 1 as viewed along section lines 9-9 and with the grip cover omitted to illustrate an embodiment of a sensor positioned adjacent to the rear surface of the handle base.

FIG. 10 is a front perspective and partial cutaway view of the door handle assembly of FIGS. 1-9 shown mounted to a door of a motor vehicle and operatively connected to a door latch and processor of the motor vehicle.

FIG. 11 is a front perspective view of the door handle assembly of FIGS. 1-9 mounted to a door of a motor vehicle, shown with a portion of a hand inserted between the door and the door handle assembly which causes a detectable change in the output of one of the sensors carried by the door handle assembly.

FIG. 12 is a front perspective view similar to FIG. 11 showing the hand exerting an outward force against the door handle assembly to actuate the door latch actuator and open the door of the motor vehicle.

FIG. 13 is a front perspective view similar to FIGS. 11 and 12 showing exertion of a force or pressure against a portion of the grip cover which causes a detectable change in the electrical output of another of the sensors carried by the door handle assembly.

FIG. 14 is a block diagram schematic of an embodiment of a motor vehicle access closure control system.

FIG. 15 is a front perspective view of an example motor vehicle showing one or more sensors which may be mounted to or within various components of and about the motor vehicle, and showing an embodiment of an access closure handle mounted to an access closure of the motor vehicle, and further showing one or more sensors which may be mounted to or within the access closure handle.

FIG. 16 is a front perspective view of an example motor vehicle showing another embodiment of an access closure handle mounted to an access closure of the motor vehicle, and further showing one or more sensors which may be mounted to or within the access closure handle.

FIG. 17A is a front perspective view of an example motor vehicle showing another embodiment of an access closure handle including front and rear handle components mounted to respective front and rear an access closures of the motor vehicle, and further showing one or more sensors which may be mounted to or within either of both of the access closure handle components.

FIG. 17B is a front perspective view of an example motor vehicle showing another embodiment of an access closure handle including front and rear handle components mounted to respective front and rear an access closures of the motor vehicle, and further showing one or more sensors which may be mounted to or within either of both of the access closure handle components.

FIG. 17C is a front perspective view of an example motor vehicle showing another embodiment of an access closure handle including front and rear handle components mounted to respective front and rear an access closures of the motor vehicle, and further showing one or more sensors which may be mounted to or within either of both of the access closure handle components.

FIG. 18 is a rear perspective view of an example motor vehicle showing another embodiment of an access closure handle mounted to an access closure of the motor vehicle, and further showing one or more sensors which may be mounted to or within the access closure handle, and further showing one or more sensors which may alternatively or additionally be mounted to or within various components of and about the motor vehicle.

FIG. 19 is a rear perspective view of an example motor vehicle showing another embodiment of an access closure handle mounted to an access closure of the motor vehicle, and further showing one or more sensors which may be mounted to or within the access closure handle.

FIG. 20 is a front perspective view of an example motor vehicle showing another embodiment of an access closure handle mounted to an access closure of the motor vehicle, and further showing one or more sensors which may be mounted to or within the access closure handle.

FIG. 21 is a front perspective view of an example motor vehicle showing an embodiment of a modular access closure handle which may be mounted with various orientations to an access closure of the motor vehicle, and further showing one or more sensors which may be mounted to or within the access closure handle.

FIG. 22A is a front perspective view of an example motor vehicle showing another embodiment of an access closure handle mounted to an access closure of the motor vehicle with the access closure handle in a closed position, and further showing one or more sensors which may be mounted to or within the access closure handle.

FIG. 22B is a front perspective view similar to FIG. 22A and showing the access closure handle in an open position, and further showing one or more sensors which may alternatively or additionally be mounted to or within the access closure handle.

FIG. 23A is a front perspective view of an example motor vehicle showing another embodiment of an access closure handle mounted to an access closure of the motor vehicle with the access closure handle in a closed position, and further showing one or more sensors which may be mounted to or within the access closure handle.

FIG. 23B is a front perspective view similar to FIG. 22A and showing the access closure handle in an open position, and further showing one or more sensors which may alternatively or additionally be mounted to or within the access closure handle.

FIG. 24 is a rear perspective view of an example motor vehicle showing another embodiment of an access closure handle mounted to an access closure of the motor vehicle, and further showing one or more sensors which may be mounted to or within the access closure handle.

FIG. 25 is a front perspective view of an example motor vehicle showing another embodiment of an access closure handle mounted to an access closure of the motor vehicle, and further showing one or more sensors which may be mounted to or within the access closure handle.

FIG. 26 is a front perspective view of an example motor vehicle showing an embodiment of badge assembly, including front and rear badge components mounted to respective front and rear an access closures of the motor vehicle, and further showing one or more sensors which may be mounted to or within either of both of the badge components.

FIG. 27 is a front perspective view of an example motor vehicle showing an embodiment in which one or more sensors are mounted to or within an access closure of the motor vehicle along a portion of a beltline of the access closure.

FIG. 28 is a front perspective view of an example motor vehicle showing an embodiment in which a display unit is mounted to or within a window frame of the motor vehicle, and showing one or more sensors are mounted to or within a display screen of the display unit.

FIG. 29 is a front perspective view of an example motor vehicle showing an embodiment in which one or more sensors are mounted to a rocker panel and/or to an underside of the motor vehicle.

FIG. 30 is a rear perspective view of an example motor vehicle showing an embodiment of badge mounted to a trunk lid of the motor vehicle, and further showing one or more sensors which may be mounted to or within the badge.

### DETAILED DESCRIPTION OF THE DRAWINGS

While the concepts of the present disclosure are susceptible to various modifications and alternative forms, specific exemplary embodiments thereof have been shown by way of example in the drawing and will herein be described in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases may or may not necessarily refer to the same embodiment. Further, when a particular feature, structure or characteristic is described in connection with an embodiment, it is submitted that it is within the knowledge of one skilled in the art to effect such feature, structure or characteristic in connection with other embodiments whether or not explicitly described. Further still, it is contemplated that any single feature, structure or characteristic disclosed herein may be combined with any one or more other disclosed feature, structure or characteristic, whether or not explicitly described, and that no limitations on the types and/or number of such combinations should therefore be inferred.

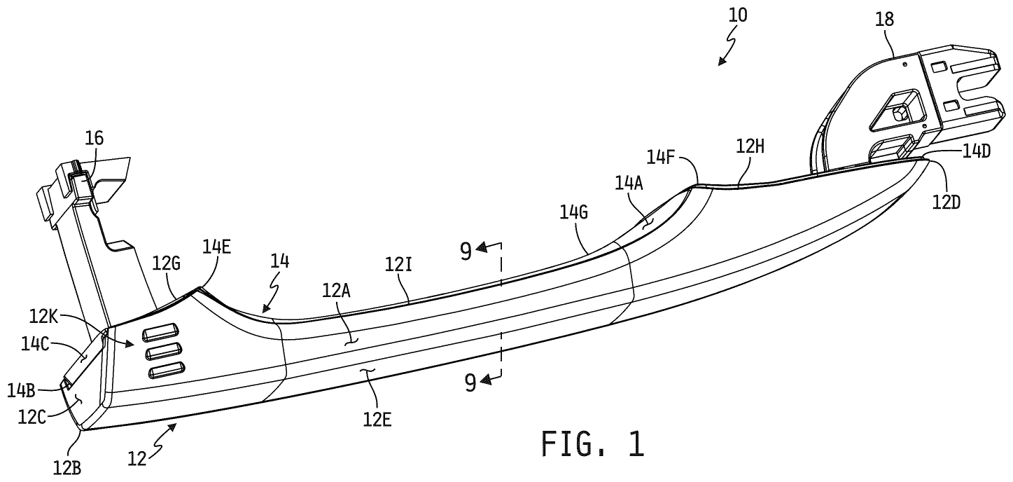

Referring now to FIG. 1, an embodiment is shown of a door handle assembly 10 for a motor vehicle. The door handle assembly 10 illustratively includes a grip cover 12 that mates with a handle base 14. The handle base 14 illustratively includes a pivot mount 18 configured to be pivotally mounted to an entry door of a motor vehicle and a latch actuator 16 operatively coupled with a door latch assembly located within the entry door. Together, the grip cover 12 and the handle base 14 form a grip configured to be grasped by a human hand. As will be described in greater detail below, the grip cover 12 and handle base 14 together form a housing which carries two sensors; one which may be triggered or otherwise activated to cause a door latch of the entry door to lock and thereby prevent manual actuation of the handle assembly 10 to open the entry door and/or to latch the handle assembly 10 to the entry door, and another which may be triggered or otherwise activated to cause the door latch of the entry door to unlock or unlatch so that the door handle assembly 10 may be manually actuated in a conventional manner to open the entry door.

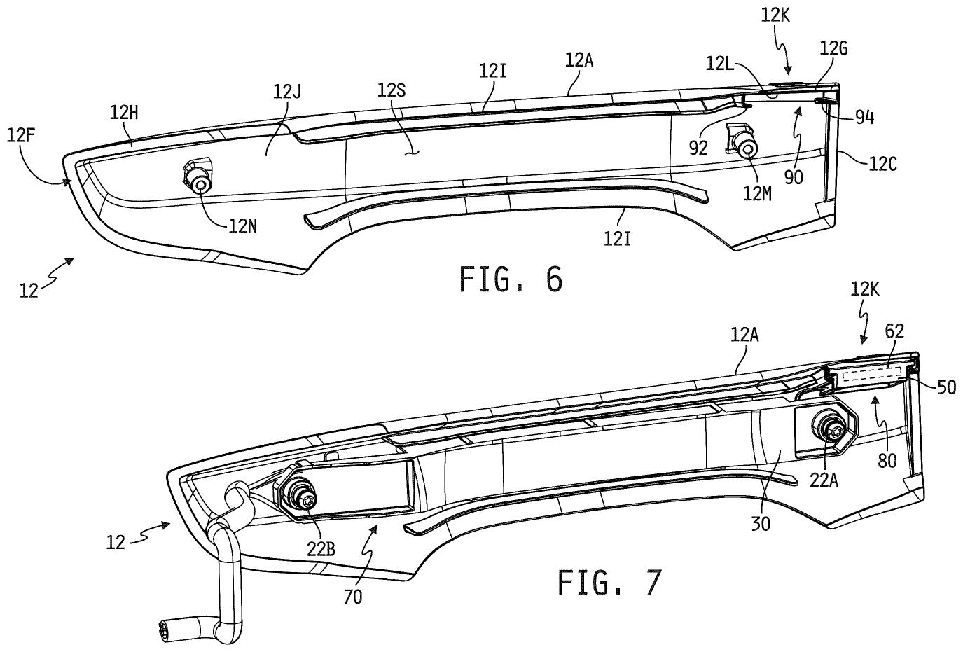

In the illustrated embodiment, the grip cover 12 comprises opposing upper and lower walls 12A, 12B respectively and opposing side walls 12C, 12D respectively. All such walls 12A-12D are joined by an elongated and front wall 12E which may be at least partially arcuate. Between the side walls 12C, 12D, the upper and lower walls 12A, 12B of the grip cover 12 define a rear lip 12F which illustratively defines an arcuate and generally concave section 121 between and relative to two opposing end sections 12G, 12H (see FIG. 6). Between the rear lip 12F and interior surfaces of the upper and lower walls 12A, 12B, the side walls 12C, 12D and the rear surface 12J of the front wall 12E, the grip cover 12 defines an internal or interior space 12S. In one embodiment, the grip cover 12 is of uniform construction, although in other embodiments the grip cover 12 may be formed by securing together two or more component parts. The grip cover 12 may be formed of one or more conventional materials, and in one embodiment the grip cover 12 is a plastic component covered by a metallic film or coating to simulate a chrome handle. Alternatively or additionally, the plastic grip cover 12 may be covered by one or more colored films or coatings and/or by one or more clear films or coatings. In still other embodiments, the grip cover 12 may be formed of or include one or more coated or uncoated metals or metal composites.

The handle base 14 illustratively has opposing upper and lower walls 14A, 14B respectively and opposing side walls 14C, 14D respectively. All such walls 14A-14D are joined by an elongated rear wall 14G which is illustratively at least partially arcuate to match the at least partially arcuate shape of the front wall 12E of the grip cover 12. Between the side walls 14C, 14D, the upper and lower walls 14A, 14B of the handle base 14 define a front lip 14L which illustratively defines an arcuate and generally concave section between and relative to two opposing end sections configured to match the concave section 121 and end sections 12G, 12H of the grip cover 12 such that the front lip 14L of the handle base 14 receives in contact the rear lip 12F of the grip cover 12 when the grip cover 12 and the handle base 14 are brought together as illustrated in FIG. 1. Between the front lip 14L and interior surfaces of the upper and lower walls 14A, 14B, the side walls 14C, 14D and the front surface 14H of the rear wall 14G, the handle base 14 defines an internal or interior space 14S.

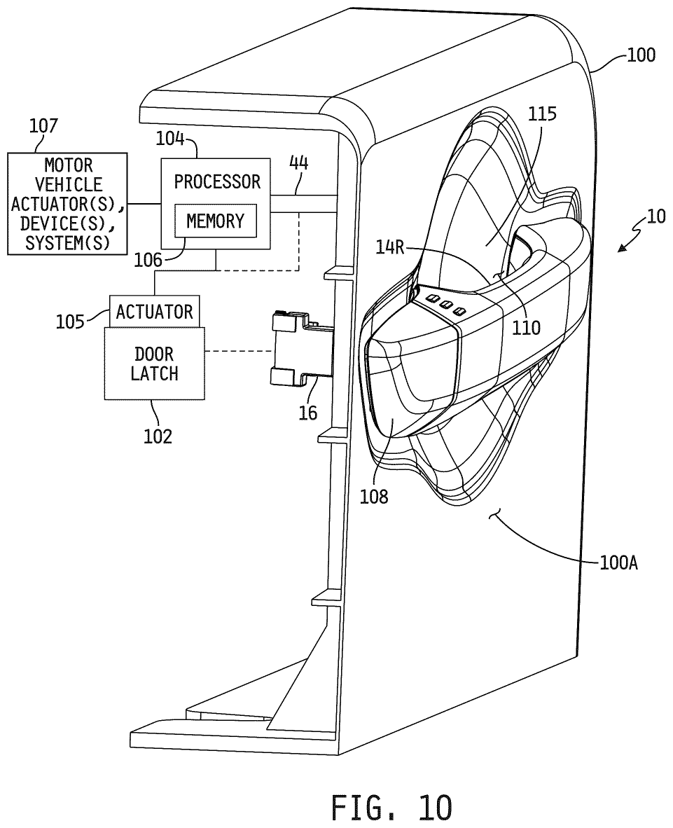

A latch actuator 16 extends rearwardly from the handle base 14 adjacent to one of the side walls 14C, and a pivot mount 18 extends rearwardly from the handle base 14 adjacent to the opposite side wall 14D. The latch actuator 16 is illustratively configured to operatively couple to a conventional door latch assembly carried by a door of a motor vehicle to which the handle assembly 10 is mounted (see, e.g., FIG. 10). The pivot mount 18 is illustratively configured to extend into the door and pivotally couple to one or more structures therein. Movement of the handle base 14 about the pivot mount 18 illustratively moves the latch actuator 16 to actuate the door latch assembly in a conventional manner to enable the user to open the motor vehicle door. Two bores 20A, 20B are formed through the handle base 14; one bore 20A is formed adjacent to the latch actuator 16 and the other bore 20B is formed adjacent to the pivot mount 18.

Adjacent to the latch actuator 16, the handle base 14 defines a protrusion 14E between the upper and lower walls 14A, 14B, and adjacent to the pivot mount 18 the handle base defines a protrusion 14F between the upper and lower walls 14A, 14B. Each protrusion 14E, 14F illustratively extends rearwardly from the handle base 14, and the arcuate rear wall 14G extends between the protrusions 14E, 14F and between the upper and lower walls 14A, 14B. As illustrated most clearly in FIGS. 10-13, the protrusions 14E, 14F extending rearwardly from the handle base 14 are illustratively sized and configured to contact the outer skin 100A of the motor vehicle door 100 when the door assembly 10 is mounted to the motor vehicle door 100, and a space 110 is defined between a portion 115 of the outer surface of the outer skin 100A of the door 100 and the rear surface 14R of the arcuate rear wall 14G of the handle base 14. The arcuate profile of the rear wall 14G of the handle base 14 is, along with sizes and shapes of the protrusions 14E, 14F, illustratively configured to produce the space 110 with a size and shape suitable to allow one or more fingers and at least a portion of a human hand 120 to extend sufficiently therein to come into contact with the rear surface 14R of the rear wall 14G so that the hand 120 can then grasp the combination of the handle base 14 and the grip cover 12 with at least one finger extending into the space 110 and wrapped around the rear surface 14R of the arcuate rear wall 14G of the handle base 14 in a conventional fashion.

In one embodiment the handle base 14 is of uniform construction, although in other embodiments the handle base 14 may be formed by securing together two or more component parts. The handle base 14 may be formed of one or more conventional materials, and in one embodiment the handle base 14 is a plastic component covered by one or more suitable films or coatings. In alternate embodiments, the handle base 14 may be formed of or include one or more other suitable coated or uncoated materials.

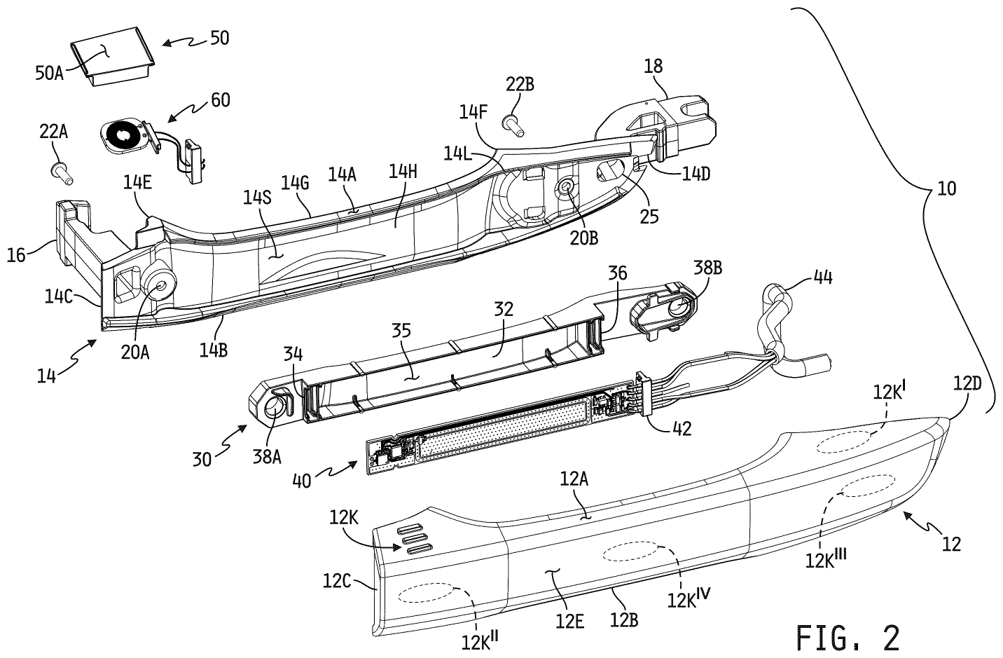

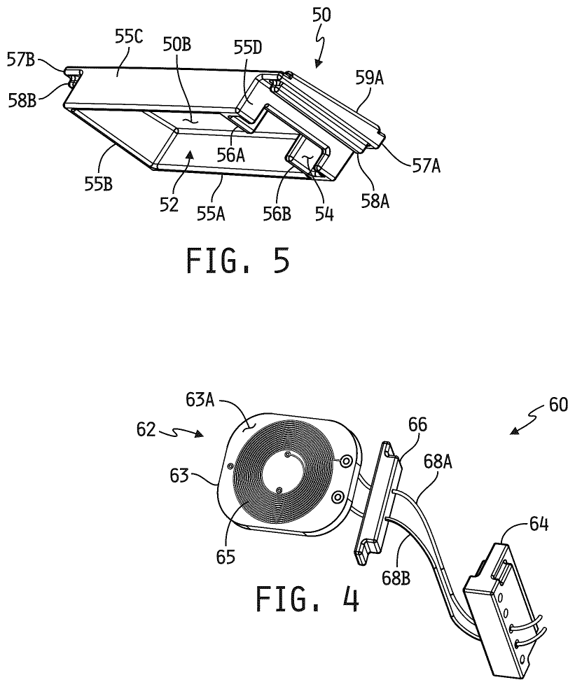

The interior space 12S of the grip cover 12 and the interior space 14S of the handle base 14 together define a space sized to house electronic components when the grip cover 12 and the handle base 14 are secured together. Referring now to FIG. 2, the door handle assembly 10 illustratively further includes a circuit board carrier 30 to which a circuit board 40 is mounted, and the circuit board carrier 30 and circuit board 40 are together mounted within the space defined by and between the interior spaces 12S and 14S of the grip cover 12 and the handle base 14 respectively. A sensor cartridge 50 is received within the grip cover 12 separately from the circuit board carrier 30 and the circuit board 40, and a sensor assembly 60, including a sensor 62 (see also FIG. 4), mountable to the sensor cartridge 50 is electrically connectable to the circuit board 40. In the illustrated embodiment, and as will be described in greater detail below, the sensor assembly 60 is mounted to the sensor cartridge 50, and the sensor cartridge 50 is then mounted to the grip cover 12 such that the sensing surface of the sensor 62 is operatively spaced apart from a sensor triggering portion 12K of the grip cover 12. In some embodiments, the sensor triggering portion 12K of the grip cover 12K is configured to be visually identifiable with the naked eye. In other embodiments, the sensor triggering portion 12K may be visually identified via an illumination source carried within the grip cover 12. Although the sensor triggering portion 12K is illustrated in FIGS. 1 and 2 as being a portion of the upper wall 12A of the grip cover 12 adjacent to the side wall 12C, it will be understood that the sensor triggering portion 12K may alternatively be located anywhere along the upper wall 12A, e.g., such as the alternate portion 12K′ of the top wall 12A adjacent to the side wall 12D as illustrated by dashed-line configuration in FIG. 2, or anywhere along the front wall 12E, e.g., such as the alternate portion 12K″ of the front wall 12E adjacent to the side wall 12C, the alternate portion 12K′″ adjacent to the side wall 12D or the alternate portion 12K^{IV} of the front wall 12E centrally between the side walls 12C, 12D each as illustrated by dashed-line configuration in FIG. 2. In any such alternate positioning of the sensor triggering portion 12K′, 12K″, 12K′″, 12K^{IV} of the grip cover 12, it will be further understood that the sensor cartridge 50 and sensor 60 assembly will be suitably mounted to the grip cover 12 to position the sensing surface of the sensor 62 so as to be operatively spaced apart from the wall portion 12K′, 12K″, 12K′″, 12K^{IV}. In some embodiments, as will be described below, the sensor triggering portion 12K, 12K′, 12K″, 12K′″, 12K^{IV} is made to be at least partially flexible so as to deflect inwardly upon application of external pressure, although in other embodiments the sensor triggering portion 12K, 12K′, 12K″, 12K′″, 12K^{IV} may be made substantially rigid. In any case, the sensor trigger portion 12K, 12K′, 12K″, 12K′″, 12K^{IV} may be made to be visually distinguishable from adjacent areas of the grip cover 12 by embossing, etching, e.g., laser etching, molding, machining or otherwise altering the physical appearance of the sensor trigger portion 12K, 12K′, 12K″, 12K′″, 12K^{IV} relative to adjacent areas of the grip cover 12, and/or by configuring the sensor trigger portion 12K, 12K′, 12K″, 12K′″, 12K^{IV} such that it is at least partially light-transmissive so that visible radiation emitted by one or more illumination sources carried within the grip cover 12 can be seen on and/or externally to the sensor trigger portion 12K, 12K′, 12K″, 12K′″, 12K′v.

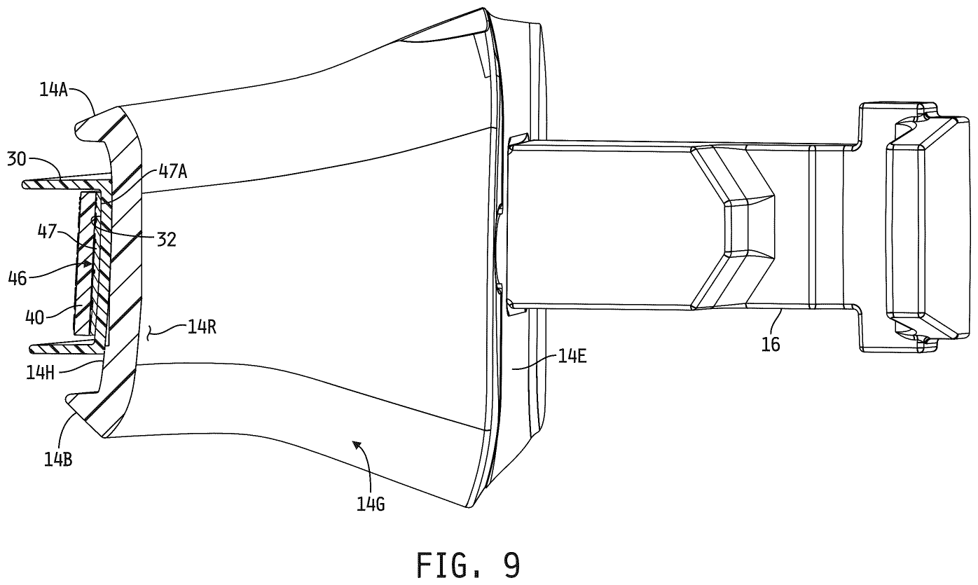

The circuit board 40 illustratively has a number of electronic circuit components mounted thereto. Such electronic circuit components illustratively include another sensor (one example 46 of which is illustrated in FIG. 9), sensor signal conditioning circuitry in the form of at least one conventional sensor signal processing circuit 45 configured to process sensor signals produced by at least one of the sensors 46, 62 and, in some embodiments, one or more supporting electronic circuits. In some embodiments, another such electronic circuit component that may be mounted to the circuit board 40 may be or include a conventional processor configured to execute instructions stored in an on-board and/or externally connected memory unit. In embodiments which include such a processor, the on-board and/or externally connected memory unit illustratively has instructions stored therein which, when executed by the processor, cause it to produce control signals to control one or more features associated with the door handle assembly 10. In other embodiments, e.g., as illustrated by example in FIG. 10, such a processor 104 and memory 106 may both be located outside of the door handle assembly 10, e.g., within the door 100 or other area of a motor vehicle, and electrically connected to the circuit board 40 via suitable wiring 44. In either case, such features may include, but are not necessarily limited to, locking and unlocking of the door handle assembly 10. Alternatively or additionally, such features may include unlatching of the door handle assembly 10, i.e., controlling the latch actuator 16 and/or a door latch assembly 102 of the motor vehicle to automatically uncouple the latch actuator 16 from the door latch assembly 102, latching of the door handle assembly 10, i.e., controlling the latch actuator 16 and/or a door latch assembly 102 of the motor vehicle to automatically couple the latch actuator 16 to the door latch assembly 102, activating and/or deactivating the door latch assembly 102 to automatically close and/or open the motor vehicle door in embodiments in which the door latch assembly 102 is or includes an automatic door opening/closing/assist apparatus and the motor vehicle door is provided in the form of an access closure with power open/close assist features, e.g., such as a power lift gate, a power rear door, a power side door, a power sliding door or the like. Alternatively or additionally still, in embodiments in which one or more illumination sources is/are mounted to the circuit board 40 and/or elsewhere on or within the door handle assembly 10, such features may include selectively illuminating one or more portions of the door handle assembly 10 and/or one or more portions of the motor vehicle door 100 to which the door handle assembly 10 is mounted. Alternatively or additionally still, such one or more features may include processing a sequence of detectable changes in signals produced by either or both of the sensors, e.g., the sensors 46, 62, and/or other or additional sensors carried by the assembly 10, and comparing such a sequence to a predefined or pre-set sequence for the purpose of determining whether to lock, unlock, latch, unlatch, close and/or open the door handle assembly 10. Alternatively or additionally still, such one or more features may include processing a sequence of detectable changes in signals produced by either or both of the sensors, e.g., the sensors 46, 62, and/or other or additional sensors carried by the assembly 10, to selectively control, i.e., activate, deactivate, select and/or position, one or more driver and/or passenger settings within motor vehicle, e.g., one or more interior light settings, one or more entertainment system settings, one or more climate control settings, one or more seat position settings, one or more steering wheel position settings, one or more rear view mirror position settings, one or more side mirror position settings, one or more window and/or sunroof position settings, and/or the like. Alternatively or additionally still, such one or more features may include processing a sequence of detectable changes in signals produced by either or both of the sensors, e.g., the sensors 46, 62, and/or other or additional sensors carried by the assembly 10, to selectively control, i.e., activate, deactivate, select and/or position, one or more exterior structures and/or features of motor vehicle when the vehicle is parked/stationary, e.g., a position of one or more of motor vehicle side mirrors, e.g., folded against the motor vehicle or unfolded to an operative position, one or more window and/or sunroof position settings, one or more external motor vehicle lights, or the like.

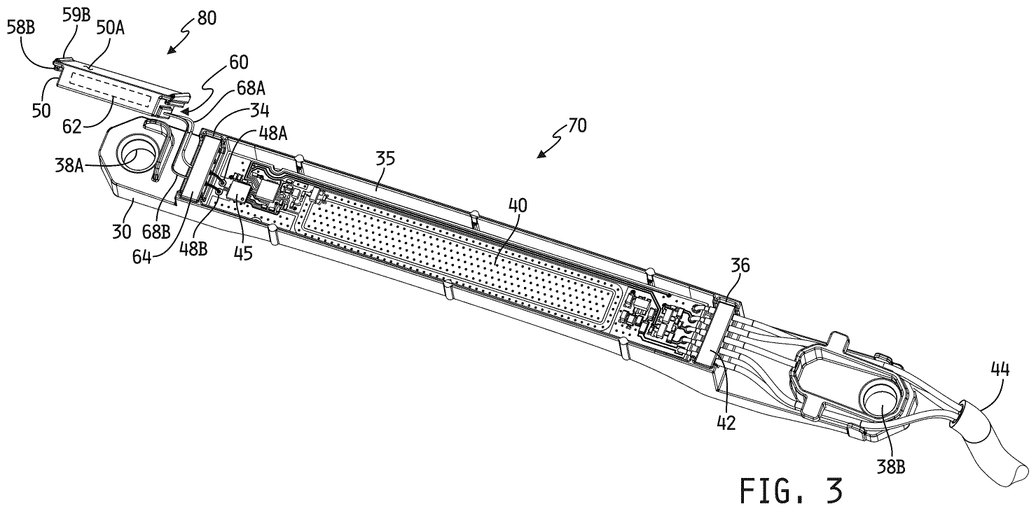

The circuit board carrier 30 illustratively has a rear wall 32 from which top and bottom frames forwardly extend to form a pocket 35 sized and configured to receive the circuit board 40 therein as depicted in FIG. 3. At one end of the pocket 35, the circuit board carrier 30 defines a slot 34 sized and configured to receive therein a wiring block 64 associated with the sensor assembly 60 (see FIG. 4), and at an opposite end of the pocket 35 the circuit board carrier 30 defines another slot 36 sized and configured to receive therein another wiring block 42 which supports and isolates the wiring 44 electrically connected to the electronic circuitry carried by the circuit board 40. The wiring 44 is illustratively fed externally from the door handle assembly 10 through an opening 25 defined through the handle base 14. A bore 38A is formed through the circuit board carrier 30 between the slot 34 and one end thereof, and another bore 38B is formed through the circuit board carrier 30 between the slot 36 and an opposite end thereof. The bores 38A, 38B align with the bores 20A, 20B of the handle base 40, and conventional fixation members 22A, 22B, e.g., screws, are sized to extend through the aligned bores 20A, 38A, 20B, 38B (see also FIG. 1) to mount the circuit board carrier 30 to the handle base 14.

Referring now to FIG. 3, the circuit board 40 is shown mounted to the circuit board carrier 30 to form a circuit board subassembly 70. In the illustrated embodiment, the circuit board 40 is received within the pocket 35 of the circuit board carrier 30 with the wiring block 42 electrically connected to the circuit board 40 and to the wiring 44 received within the slot 36. Also shown in FIG. 3 is the sensor 62 of the sensor assembly 60 mounted to and within the sensor cartridge 50 to form a sensor cartridge assembly 80, and the wiring block 64 associated with the sensor assembly 62 received within the slot 34 of the circuit board carrier.

As illustrated by example in FIG. 4, the sensor assembly 60 includes a sensor 62 in the form of an inductive sensor. The sensor 62 includes a planar substrate 63 having a planar sensor surface 63A upon which a sensor coil 65 is disposed and electrically connected to two wires 68A, 68B. Each of the wires 68A, 68B connected to the sensor coil 65 passes successively through a pair of wiring blocks 66 and 64 respectively configured to support the wires 68A, 68B in a conventional manner. An example embodiment of the sensor carrier 50 is illustrated in FIG. 5 and includes a planar member 52 defining a planar top surface 50A (see FIG. 1) and a bottom planar surface 50B, opposite the top planar surface 50A, from which surrounding sidewalls 55A-55D extend normally away. A pair of spaced apart interior sidewalls 56A, 56B extend normally away from the bottom planar surface 50B of the planar member 52 adjacent to the sidewall 55D which is also formed of spaced apart walls to form a slot 54 through the walls 55D, 56A, 56B sized to receive the wiring block 66 therein. A frame 57A extends away from one side of the planar member 52 adjacent and generally normal to the sidewall 55B, and another frame 57B extends away from an opposite side of the planar member 52 adjacent and generally normal to the sidewall 55D. The frames 57A, 57B are generally parallel with the planar top and bottom surfaces 50A, 50B of the planar member 52. A pair of protrusions 58A and 59A extend generally perpendicularly away from the bottom and top surfaces respectively of the frame 57A, and a pair of protrusions 58B and 59B likewise extend generally perpendicularly away from the bottom and top surfaces respectively of the frame 57B.

As illustrated in FIG. 3, the sensor 62 is received and mounted within the pocket formed between the planar member 52 and the sidewalls 55A-55D of the sensor cartridge 50 such that the sensor surface 63A of the sensor substrate 63 faces the bottom planar surface 50B of the planar member 52. The wiring block 66 is received within the slot 54 formed between the sidewalls 55D, 56A, 56B with the wires 68A, 68B extending through the gaps formed between the sidewalls 56A, 56B and the spaced apart portions of the sidewall 55D. In some embodiments, a suitable mounting compound may be disposed in the pocket of the sensor carrier 50 to secure the sensor 62 therein. In any case, the sensor 62 is carried within the pocket of the sensor cartridge with the planar sensor surface 63A of the sensor substrate 63 spaced apart from and generally parallel with the planar top surface 50A of the sensor cartridge 50.

With the sensor 62 positioned within the sensor cartridge 50 as illustrated in FIG. 3, the wiring block 64 of the sensor assembly 60 is positioned in the slot 34 defined by the circuit board carrier 30, and the wires 68A, 68B extending from the wiring block 64 are electrically connected to corresponding electrical terminals 48A, 48B mounted to the circuit board 40 and electrically coupled to one or more electronic components carried by the circuit board 40. The wiring blocks 64, 66 support the sensor wires 68A, 68B and isolate the wires 68A, 68B from the sensor circuit board carrier 30 and the sensor cartridge 50 respectively.

Referring now to FIG. 6, the back or rear side of the grip cover 12 is shown in which the rear surface 12J of the front wall 12E defines a pair of spaced apart receptacles 12M, 12N each sized and configured to receive and engage a respective one of the fixation members 22A, 22B illustrated in FIG. 1. As illustrated by example in FIG. 7, the spaced apart receptacles 12M, 12N align with the bores 38A, 38B of the circuit board carrier 30 such that the fixation members 22A, 22B secure the circuit board assembly 70 to the grip cover 12. It will be understood that the fixation members 22A, 22B further secure the handle base 14 to the grip cover 12 with the circuit board subassembly 70 mounted therebetween in the space defined by the interior spaces 12S, 14S of the two components, and that the handle base 14 is omitted in FIG. 7 to illustrate attachment of the circuit board assembly 70 to the grip cover 12.

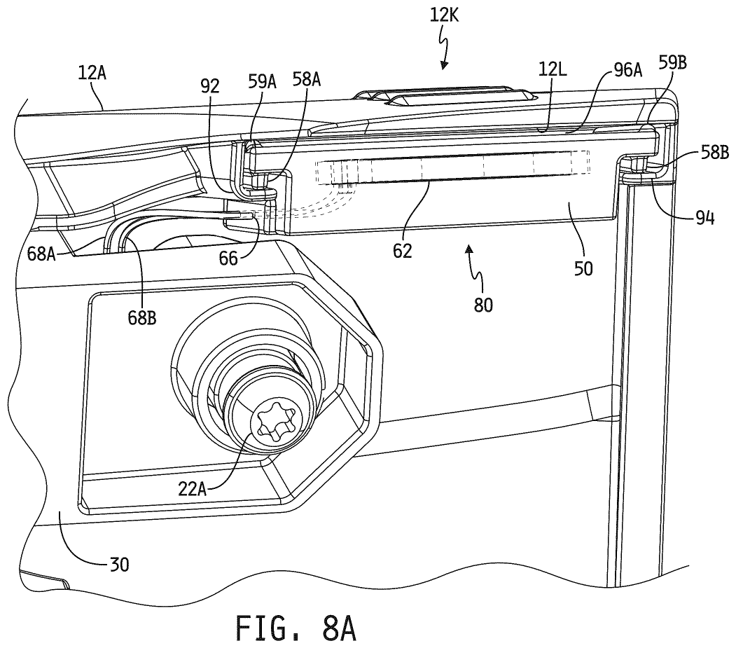

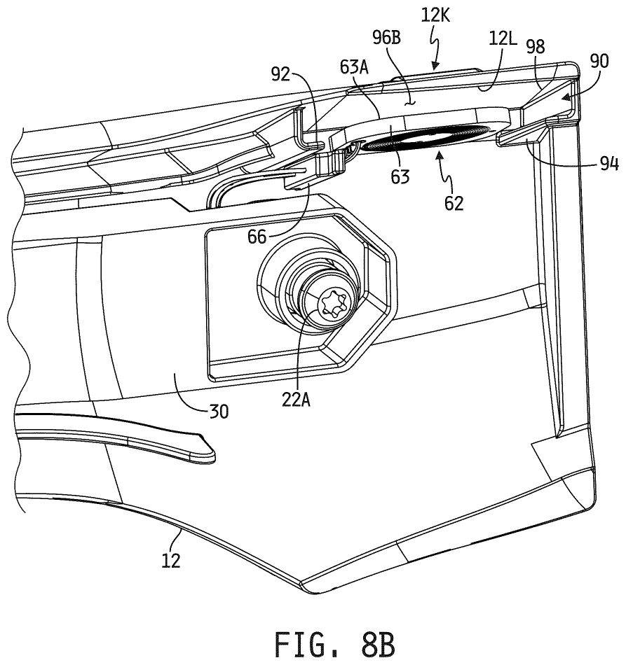

As further illustrated in FIGS. 6-8B, the interior space 12S of the grip cover 12 defines a slot 90 sized and configured to receive the sensor cartridge 50 of the sensor cartridge assembly 80 therein. The slot 90 is illustratively defined adjacent to the side wall 12C of the grip cover 12 and is bordered along its top by a generally planar portion 12L of the inner surface of the top wall 12A of the grip cover 12. The portion 12L of the inner surface of the top wall 12A is defined opposite the sensor triggering portion 12K between opposing ears 92, 94 projecting downwardly from the inner surface of the top wall 12A of the grip cover 12 into the space 12S. The slot 90 defined between the inner surface 12L of the grip cover 12 and the opposing ears 92, 94 is sized to receive the sensor cartridge 50 therein with the slot 54 of the sensor cartridge 50 and the wiring block 64 received therein facing away from the side wall 12C so as to direct the wires 68A, 68B inwardly toward the circuit board 40. As most clearly illustrated in FIGS. 8A and 8B, the projections 58A, 58B and 59A, 59B operate to position the top planar surface 50A of the sensor cartridge 50, and thus the planar sensing surface 63A of the sensor substrate 63, spaced apart from and generally parallel with the planar portion 12L of the inner surface of the top wall 12A of the grip cover 12. As illustrated in FIG. 8A, with the sensor cartridge 50 positioned in the slot 90, a space 96A is defined between the portion 12L of the inner surface of the top wall 12A and the top planar surface 50A of the sensor cartridge 50 which, in turn, defines a space 96B between the portion 12L of the inner surface of the top wall 12A and the planar sensing surface 63A of the sensor substrate 63 on which the sensor coil 65 is disposed as illustrated in FIG. 8B.

As further illustrated in FIG. 8B, an electrically conductive film, layer or plate 98 is secured to the portion 12L of the inner surface of the top wall 12A so as to be positioned opposite and spaced apart from the sensor coil 65 disposed on the planar sensing surface 63A of the sensor substrate 63 when the sensor cartridge 50 carrying the sensor 62 is received within the slot 90. Examples of the conductive film, layer or plate 98 may include, but are not limited to, any metallic or other electrically conductive film, e.g., chrome or other material(s), painted, deposited or otherwise formed on the portion 12L of the inner surface of the top wall 12A of the grip cover 12, a tape having one or more electrically conductive layers and/or particles affixed thereto or embedded therein and one or more bonding media, e.g., adhesive or other bonding media, applied thereto for affixing the tape to the portion 12L of the inner surface of the top wall 12A, one or more rigid or semi-rigid electrically conductive sheets or plates affixed in any manner to the portion 12L of the inner surface of the top wall 12A, or the like.

In the illustrated embodiment, at least the portion of the top wall 12A defining the sensor triggering portion 12K is made to be at least partially flexible such that the portion 12L of the inner surface of the top wall 12A is displaced inwardly toward the sensor coil 65 in response to pressure or force applied to the sensor triggering portion 12K of the top wall 12A by, e.g., a digit of a human hand. Operation of the inductive sensor 62 is conventional in that the sensor coil 65 is energized by circuitry on the circuit board 40 to create a sensor output signal in the form of an electromagnetic field adjacent to the planar sensing surface 63A of the sensor substrate 63. In one example embodiment, circuitry on the circuit board 40 includes a capacitive component electrically connected to the sensor coil 65 through the wires 68A, 68B such that the capacitive component and the sensor coil 65 together form a resonant circuit. In some embodiments, the resonant circuit may include at least one or more additional passive components such as one or more resistive elements, although in other embodiments the resistive element of the resonant circuit may be provided in the form of inherent resistance in either or both of the capacitive component and the sensor coil 65. In any case, a time-varying signal is applied to the resonant circuit to produce a time-varying electromagnetic field. The size of the sensor coil 65 and the strength of the electromagnetic field established by the energized sensor coil 65 are selected such that the time-varying electromagnetic field extends across the space 96B to the electrically conductive film or plate 98. When the portion 12L of the inner surface of the top wall 12A of the grip cover 12 deflects inwardly a sufficient distance relative to the surrounding portions of the grip cover 12 in response to corresponding external pressure or force applied to the portion 12L of the top wall 12A, the electrically conductive film or plate 98 is displaced to within a detection proximity of the sensor coil 65. This results in a measurable loss in the resonant circuit which can be measured as a detectable change in the output signal of the sensor 62. In one embodiment, this detectable change in the output signal of the sensor 62 is measured as a change in frequency over time, although in alternate embodiments the detectable change in the output signal of the sensor 62 may be measured as a change over time in capacitance, inductance and/or resistance, e.g., relative to reference components onboard the circuit board 40. In some alternate embodiments, the sensor 62 may illustratively be affixed to or formed on, e.g., printed on, the portion 12L of the top wall 12A of the grip cover 12, and the electrically conductive film, layer or plate 98 may be affixed to or formed on the carrier 50. In any case, the sensor 62 may, in some embodiments, be configured to be responsive to different magnitudes or levels of pressure applied to the portion 12K, 12K′, 12K″, 12K′″, 12K^{IV} of the grip cover 12 to produce distinguishably different sensor output signal magnitudes, and in some such embodiments different pressure(s) applied to the portion 12K, 12K′, 12K″, 12K′″, 12K^{IV} of the grip cover 12 may result in different functions carried out by the door handle assembly 10 and/or by one or more actuators or systems of the motor vehicle.

The mounting arrangement of the sensor cartridge 50 to and within the grip cover 12 as just described is illustratively implemented in some embodiments to minimize or at least reduce the possibility of unintended or “false” triggering of the sensor 62 due to movement of the grip cover 12 relative to the structure(s) to which the sensor 62 may otherwise be mounted. In particular, mounting the sensor cartridge 50 carrying the sensor 62 to the grip cover 12 as just described causes the sensor cartridge 50, and thus the sensor 62, to move along with any movement generally of the grip cover 12. As long as any such movement of the grip cover 12 does not cause deflection of the sensor triggering portion 12L relative to surrounding portions of the grip cover 12, no detectable change in the output signal of the sensor coil 65 will occur. It is only when the sensor triggering portion 12L deflects inwardly relative to the surrounding portions of the grip cover 12 by an amount sufficient to cause a detectable change in the output signal of the sensor coil 65 that triggering of the sensor 62 will occur as described above. If the sensor 62 is otherwise mounted to the handle base 14, the circuit board carrier 30 or the circuit board 40 and the electrically conductive film or plate 98 is secured to a portion of the grip cover 12 opposite the sensor 62, any movement of any portion of the grip cover 12 that causes the film or plate 98 to move sufficiently toward or away from the sensor 62 may result in unintended and thus “false” triggering of the sensor 62. Although such “false” triggering of the sensor 62 may be more likely if the sensor 62 is not mounted to the grip cover 12 as described above, this disclosure contemplates embodiments in which the sensor 62 is mounted to one or any combination of the handle base 14, the circuit board carrier 30 and the circuit board 40.

Referring now to FIG. 9, another sensor 46 is illustratively carried by the door handle assembly 10 and is configured to detect objects proximate to or in contact with the rear surface 14R of the arcuate rear wall 14G of the handle base 14. In the illustrated embodiment, such a sensor 46 is illustratively provided in the form of an electrically conductive film, coating or plate 47 facing the front surface 14H of the rear wall 14G of the handle base 14 and electrically connected to circuitry carried by the circuit board 40. In the illustrated embodiment, the film, coating or plate 47 is affixed to the bottom surface of the circuit board 40, although in alternate embodiments the film, coating or plate 47 may be or be affixed to the front or rear surface of the rear wall 32 of the circuit board carrier 30, and in still other embodiments the film, coating or plate 47 may be or be affixed to the front surface 14H of the handle base 14 or otherwise disposed so as to be suitably spaced apart from the rear surface 14R of the handle base 14. In any case, the film, coating or plate 47 may be provided in any of the forms described by example above with respect to the electrically conductive film, layer or plate 98, wherein any such film, coating, layer or plate material is electrically connected to circuitry carried by the circuit board 40 as described below.

The film, coating or plate 47 electrically connected to circuitry carried by the circuit board 40 forms one electrode of a conventional capacitive sensor 46. In the illustrated embodiment, portions of the rear wall 32 of the circuit board carrier 30 and the rear wall 14G of the handle base 14 aligned with outwardly facing surface 47A of the film, coating or plate 47 together form a dielectric of the capacitive sensor, and circuitry on-board the circuit board 40 applies a time-varying, e.g., AC signal, to the film, coating or plate 47 which causes the film, coating or plate 47 to create a time-varying electric field. As long as no object is placed sufficiently close to the rear surface 14R of the rear wall 14G of the handle base 14, the time-varying electric field will not measurably change. Placing an object sufficiently close to the rear surface 14R of the rear wall 14G will induce a change the electric field produced by the film, coating or plate 47 which can be measured as a detectable change in the output signal of the sensor 46. In one embodiment, this detectable change in the output signal of the sensor 46 is measured as a change in voltage over time, although in alternate embodiments the detectable change in the output signal of the sensor 46 may be measured as a change over time in current or as a change over time in capacitance, e.g., relative to a reference capacitor onboard the circuit board 40. In one embodiment, the size of the film, coating or plate 47, the amplitude of the time-varying applied thereto, the thickness of the dielectric materials and the dielectric constant of the combined dielectric materials are illustratively selected so that at least a portion of a human hand, e.g., one or more fingers, within a detection proximity of the rear surface 14R of the rear wall 14G of the handle base 14 will trigger the sensor 46. In alternate embodiments, such parameters may be selected so that at least a portion of a human hand must be in contact with the rear surface 14R of the rear wall 14G in order to trigger the sensor 46. In any case, the sensor 46 may, in some embodiments, be configured to be responsive to different distances of the object, e.g., fingers and/or hand, from the rear surface 14R of the rear wall 14G of the handle base 14 to produce distinguishably different sensor output signal magnitudes, and in some such embodiments such different distances of the object from the rear surface 14R of the handle base 14 may result in different functions carried out by the door handle assembly 10 and/or by one or more actuators or systems of the motor vehicle.

Referring now to FIG. 10, the door handle assembly 10 is shown mounted to an entry door 100 of a motor vehicle. In the illustrated embodiment, the latch actuator 16 extends through the outer skin 100A of the vehicle door 100 and is mechanically linked via a linkage L to a conventional door latch 102 of the vehicle door 100. A door lock and unlock (and/or door latch/unlatch) actuator 105 is coupled to the door latch 102. The door lock and unlock actuator 105 is responsive to a lock signal to lock the door latch 102 and to an unlock signal to unlock the door latch 102 (and/or to a latch signal to latch the door latch 102 and/or to an unlatch signal to unlatch the door latch 102). In the embodiment illustrated in FIG. 10, the wiring 44 connected to the circuit board 40 of the door handle assembly 10 is electrically connected to a processor 104 located within the motor vehicle, e.g., as part of a motor vehicle controller or control unit, and the processor 104 illustratively includes or is electrically connected to a memory unit 106. In such embodiments, the circuitry onboard the circuit board 40 of the door handle assembly 10 may or may not include a processor and a memory. In embodiments in which the door handle assembly 10 does not include a processor and a memory, the memory unit 106 illustratively has stored therein instructions which, when executed by the processor 104, cause the processor 104 to solely control operation of the door handle assembly 10 and the door latch 102. In embodiments in which the door handle assembly 10 includes a processor and a memory, such a memory may include instructions stored therein which, when executed by the onboard processor, cause the on-board processor to control operation of the door handle assembly 10 and the memory unit 106 illustratively has stored therein instructions, which when executed by the processor 104, cause the processor 104 to control operation of the door latch 102. In still other embodiments in which the door handle assembly 10 includes a processor and a memory, the processor 104 and memory 106 may be omitted and the memory onboard the circuit board 40 illustratively has stored therein instructions which, when executed by the processor onboard the circuit board 40, cause the onboard processor to solely control operation of the door handle assembly 10 and the door latch 102. The locking and unlocking actuator 105 will be described below as being controlled solely by the processor 104, under the control of instructions stored in the memory 106, although it will be understood that such control may alternatively be carried out by a combination of the processor 104 and a processor onboard the circuit board 40 of the door handle assembly 10 or solely by a processor onboard the circuit board 40 of the door handle assembly 10. In some embodiments, the processor 104 and/or a processor on-board the circuit board 40 of the door handle assembly may be operatively coupled, e.g., electrically connected, to one or more motor vehicle actuators, devices or systems 107 in embodiments in which signals produced by the sensor 46 and/or the sensor 62 are used to control one or more structures and/or features of the motor vehicle as briefly described above. In any case, in the illustrated embodiment a bezel 108 is mounted to the vehicle door 100, and the door handle assembly 10 is mounted to the vehicle door 100 adjacent to the bezel 108 such that a space or gap 110 is formed between a portion 115 of the outer surface of the outer skin 100A of the door 100 and the rear surface 14R of the arcuate rear wall 14G of the handle base 14.

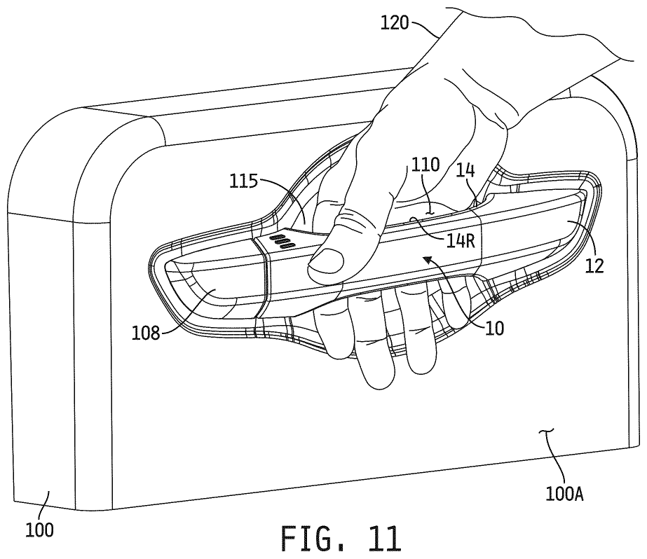

Referring now to FIGS. 11-13, operation of the door handle assembly 10 will be described. In the illustrated embodiment, the door latch 102 has a conventional latched condition in which the door latch 102 engages the latch actuator 16 to maintain the vehicle door 100 closed and which prevents the door 100 from opening on its own, and an unlatched condition in which the door latch 102 releases the latch actuator 16 to allow the vehicle door 100 to be opened for vehicle ingress and egress. The door latch 102 illustratively has a locked state and an unlocked state as is also conventional, which are controlled by the actuator 105. In the unlocked and latched state of the door latch 102, the door 100 is closed and a user may grasp and pull the combination of the handle base 14 and the grip cover 12 outwardly away from the door 100 to cause the latch actuator 16 to unlatch the door latch 102 so that the user may open the door 100, e.g., by continuing to pull outwardly on the combination of the handle base 14 and grip cover 12. In the locked and latched state of the door latch 102, the latch actuator 16 is prevented from unlatching the door latch 102, thereby preventing the door 100 from being opened. Such operation of the latch actuator 16 and the door latch 102 is conventional.

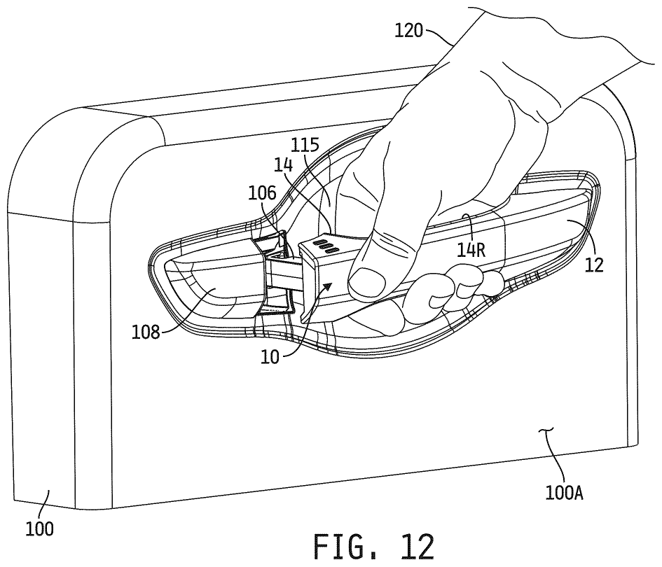

The sensors 46, 62 carried by the door handle assembly 10 illustratively provide for controlled locking and unlocking of the door latch 102 as just described. In the illustrated embodiment, the sensor 46 illustratively provides for controlled unlocking of the door latch 102 and the sensor 62 illustratively provides for controlled locking of the door latch 102, although in alternate embodiments the foregoing functions of the sensors 46, 62 may be reversed. As illustrated in FIG. 11, the door latch 102 in its locked state may be unlocked by extending at least a portion of a hand 120 into the space 110 between the rear surface 14R of the rear wall 14G of the handle base 14 and the portion 115 of the outer skin 100A of the door 100. In one embodiment, the sensor 46 is illustratively configured to be triggered when the portion of the hand 120 is within a designed distance of, but not in contact with, the rear surface 14R. In alternate embodiments, the sensor 46 may be configured to be triggered when the portion of the hand 120 is in contact with the rear surface 14R of the rear wall 14G of the handle base 14. In any case, the output signal of the sensor 46 is monitored by the processor 104, under control of instructions stored in the memory 106, and such triggering of the sensor 46 creates a detectable change in the output signal of the sensor 46 to which the processor 104 is responsive to control the door latch 102 to its unlocked state. Thereafter, the door handle assembly 10 may be actuated as illustrated in FIG. 12 and as described above to cause the latch actuator 16 to unlatch the door latch 102 so that the door 10 may be opened for ingress or egress. In some embodiments, the processor 104 may be additionally or alternatively responsive to triggering of the sensor 46 to control the door latch 102 to its unlatched state. Alternatively or additionally, in embodiments in which the door latch assembly 102 is or includes an automatic door opening/closing/assist apparatus and the motor vehicle door is provided in the form of an access closure with power open/close assist features, e.g., such as a power lift gate, a power rear door, a power side door, a power sliding door or the like, the processor 104 may be additionally or alternatively responsive to triggering of the sensor 46 to control the door latch 102 to activate the door latch assembly 102 to automatically open the motor vehicle door.

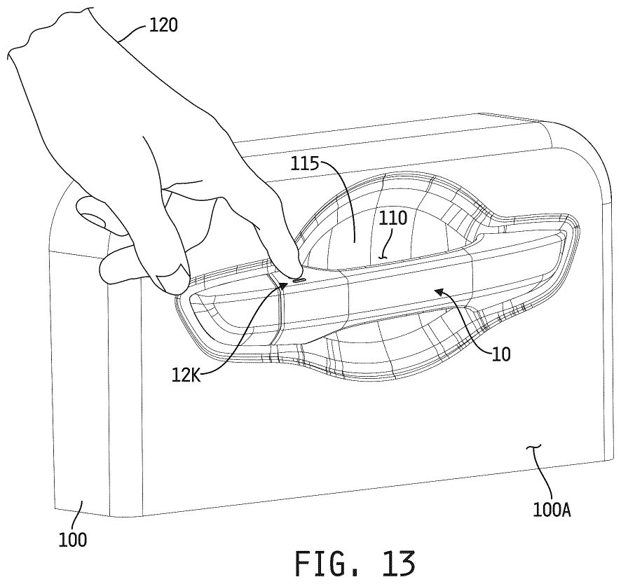

As illustrated by example in FIG. 13, the door latch 102 in its unlocked state may be locked by applying a force or pressure, e.g., by a digit of a user's hand 120, to the portion 12K of the grip cover 12 sufficiently to cause the sensor 62 to be triggered as described above. The output signal of the sensor 62 is monitored by the processor 104, under control of instructions stored in the memory 106, and such triggering of the sensor 62 creates a detectable change in the output signal of the sensor 62 to which the processor 104 is responsive to control the door latch 102 to its locked state. Thereafter, the door latch 102 will prevent actuation of the door handle assembly 10 from causing the latch actuator 16 to unlatch the door latch 102. In some embodiments, the processor 104 may be additionally or alternatively responsive to triggering of the sensor 62 to control the door latch 102 to its latched state. Alternatively or additionally, in embodiments in which the door latch assembly 102 is or includes an automatic door opening/closing/assist apparatus and the motor vehicle door is provided in the form of an access closure with power open/close assist features, e.g., such as a power lift gate, a power rear door, a power side door, a power sliding door or the like, the processor 104 may be additionally or alternatively responsive to triggering of the sensor 62 to control the door latch 102 to activate the door latch assembly 102 to automatically close the motor vehicle door.

In some embodiments, triggering of at least one of the sensors 46, 62 may cause the processor 104 to control other aspects of the door handle assembly 10. For example, in some embodiments, the circuit board 40, the circuit board carrier 30, the handle base 14 and/or the grip cover 12 may have one or more illumination sources mounted thereto, and in such embodiments the instructions stored in the memory 106 may include instructions which, when executed by the processor 104, cause the processor 104 to activate one or more such illumination sources in response to detected trigger of either or both of the sensors 46, 62.

Alternatively or additionally, the processor 104 may be programmed to control the state of the door latch 12 based on sequential triggering of at least one of the sensors 46, 62 according to a predefined or programmable triggering sequence. As one specific example, if triggering of the sensor 46=1 and triggering of the sensor 62=2, the instructions stored in the memory 106 may include instructions which, when executed by the processor 104, cause the processor 104 to control the door latch 102 from its locked state to its unlocked state (and/or to control the door latch 102 from its latched state to its unlatched state and/or to control the door latch 102 to automatically open the vehicle door) upon detection of the sensor triggering sequence 2212. In some embodiments, the sensor triggering sequence may be a predefined sequence, and in other embodiments the instructions stored in the memory 106 may include instructions which, when executed by the processor 104, cause the processor 104 to execute a programming mode in which a “private” triggering sequence may be programmed by a user. In some such embodiments, different users of the vehicle may program different private triggering sequences and in such embodiments the processor 104 may be configured to control the door latch 102 from its locked state to its unlocked state upon detection of any such programmed triggering sequence. In any case, the processor 104 may be programmed in some such embodiments to control the door latch 102 from its unlocked state to its locked state (and/or to control the door latch 102 from its unlatched state to its latched state and/or to control the door latch 102 to automatically close the vehicle door) upon detection of a single triggering of the sensor 62 as described above, or upon detection of a predefined or programmed sequence of sensor trigger events of either one or both of the sensors 46, 62 as just described.

In some embodiments, triggering of at least one of the sensors 46, 62, either singly or sequentially, may cause the processor 104 to control other aspects of the motor vehicle as described briefly above. In such cases, the processor 104 (and/or the processor carried on the circuit board 40, if any) may be configured to process a single trigger signal or a sequence of trigger signals produced by either or both of the sensors, e.g., the sensors 46, 62, and/or other or additional sensors carried by the assembly 10, to selectively control, i.e., activate, deactivate, select or control one or more actuators, devices or systems 107 to thereby activate, deactivate, select, control and/or position one or more driver and/or passenger settings of the motor vehicle. Examples of such one or more inter-vehicle driver and/or passenger settings of the motor vehicle may include, but are not limited to, one or more interior light settings, one or more entertainment system settings, one or more climate control settings, one or more seat position settings, one or more steering wheel position settings, one or more rear view mirror position settings, one or more side mirror position settings, one or more window and/or sunroof position settings, and/or the like. Examples of such one or more external vehicle driver and/or passenger settings of the motor vehicle may include, but are not limited to, one or more exterior structures and/or features of motor vehicle when the vehicle is parked/stationary such as a position of one or more of motor vehicle side mirrors, e.g., folded against the motor vehicle or unfolded to an operative position, one or more window and/or sunroof position settings, one or more external motor vehicle lights, or the like.

While the disclosure has been illustrated and described in detail in the drawings and foregoing description, such an illustration and description is to be considered as exemplary and not restrictive in character, it being understood that only illustrative embodiments have been shown and described and that all changes and modifications consistent with the disclosure and recited claims are desired to be protected. For example, while the door handle assembly 10 illustrated in the attached figures is depicted, and has been described, as having a capacitive sensor 46 positioned adjacent to the rear surface 14R of the wall 14G of the handle base 14 and an inductive sensor positioned adjacent to a portion of a wall of the grip cover 12, it will be understood that embodiments in which both sensors 46, 62 are capacitive sensors, in which both sensors 46, 62 are inductive sensors, and/or in which the sensor positioned adjacent to the rear surface 14R of the rear wall 14G of the handle base 14 is an inductive sensor and the sensor positioned adjacent to a portion of a wall of the grip cover 12 is a capacitive sensor, are all contemplated by this disclosure. As another example, while the door handle assembly 10 has been described as having a sensor positioned adjacent to the rear surface 14R of the rear wall 14G of the handle base 14 which may be triggered to control the door latch 102 from its locked state to its unlocked state, this disclosure contemplates embodiments in which such a sensor may be triggered to control the door latch 102 from its unlocked state to its locked state. Likewise, while the door handle assembly 10 has been described as having a sensor positioned adjacent to a portion of a wall of the grip cover 12 which may be triggered to control the door latch 102 from its unlocked state to its locked state, this disclosure contemplates embodiments in which such a sensor may be triggered to control the door latch 102 from its locked state to its unlocked state. As still another example, while the door handle assembly 10 has been described as including two sensors mounted separately from one another, this disclosure contemplates embodiments in which both sensors are mounted together, e.g., on one or more substrates mounted to a sensor cartridge received in a slot formed in the grip cover 12 which extends the length, or at least part of the length, of the internal space 12S thereof, on one or more substrates mounted directly to the grip cover 12, or on one or more substrates mounted to the handle base 14. As yet a further example, while the door handle assembly 10 is illustrated in FIGS. 10-13 and described as being operatively mounted to a motor vehicle door 100, it will be understood that the door handle assembly may alternatively be mounted, in whole or in part, to other structures of the motor vehicle including, for example, but not limited to, a sliding motor vehicle door, a rear hatch, trunk or swinging door of the motor vehicle or a stationary portion of the motor vehicle such as, any of the so-called “A,” “B” or “C” pillars of the motor vehicle.

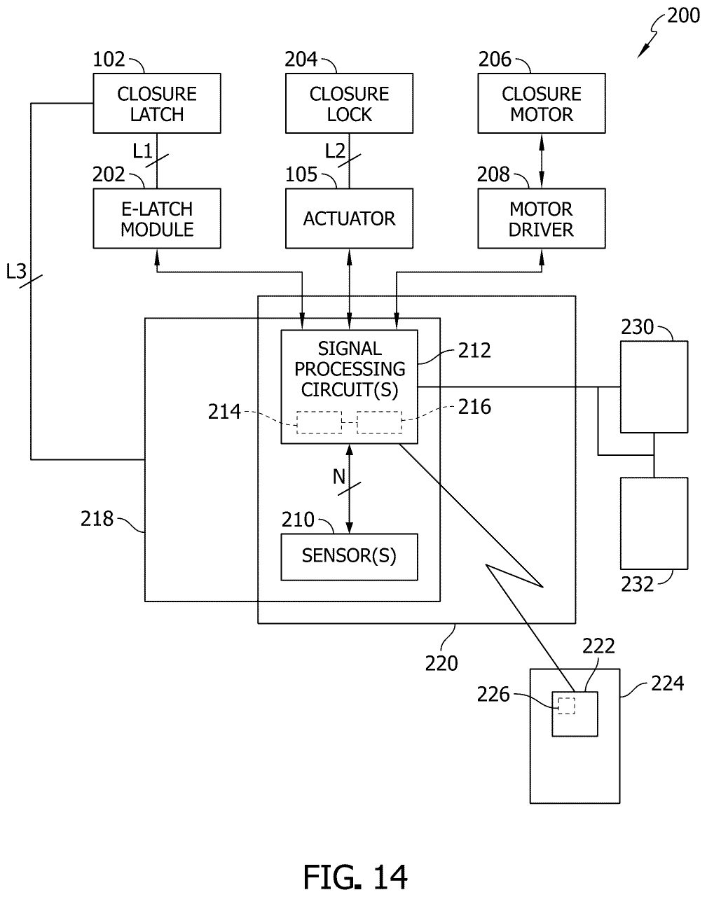

It will be understood that the embodiment of the door handle assembly 10 illustrated in FIGS. 1-13 is provided only by way of example, and that this disclosure contemplates variants of the types, number, location(s) and functionality of sensor(s) with which one or more motor vehicle closure-related operations and, in some embodiments, in which one or more features of the motor vehicle, may be controlled. In this regard, a simplified diagram is shown in FIG. 14 of a motor vehicle access closure control system 200. The term “access closure,” as used herein, refers to a closure for an access opening of a motor vehicle or compartment or other area of the motor vehicle in which the access closure has a closed position which forms a closure over the access opening, and in which the access closure has an open position which allows access to the motor vehicle or compartment or other area of the motor vehicle via the associated access opening, wherein the access closure is movable between the closed and the open position. Examples of such an access closure may include, but are not limited to, a conventional motor vehicle door, which may be side-opening, bottom opening, slide-to-open, etc., a tailgate, a hatch door or gate, a trunk lid, a so-called frunk lid (frunk is a conventional trunk area located at the front of the motor vehicle), or the like.

In the embodiment illustrated in FIG. 14, the access closure control system 200 illustratively includes a conventional mechanical closure latch 102 also illustrated in FIG. 10. In some embodiments, the latch 102 may be as described above with respect to FIGS. 10-13. In some embodiments the closure latch 102 may be coupled, via at least one mechanical linkage, L1, to an E-latch module 202. In some such embodiments, the closure latch 202 may likewise be as described above, although in other such embodiments the closure latch 102 may include only some those latch components of the closure latch 202 needed to latch the access closure in the closed position. In any case, the E-latch module 202 is illustratively conventional and is configured to be responsive to one or more control signals to control operation of the closure latch 202, i.e., to control the closure latch 102 between the latched and unlatched states as described above. In some embodiments, the access closure control system 200 may include a closure lock or lock assembly 204 mechanically coupled to a conventional lock actuator 105, also illustrated in FIGS. 10, via a mechanical linkage L2. In such embodiments, the actuator 105 is conventional and is configured to be responsive to one or more control signals to control operation of the closure lock 204, which may also be conventional, between locked and unlocked states. In some embodiments of the system 200 which include the E-latch module 202, the closure lock/unlock functions may be controlled by the E-latch module 202 and the actuator 105 and/or closure lock 204 may be incorporated, in structure and/or function, into the E-latch module 202 and/or into the closure latch 102.

In some embodiments, the motor vehicle access closure may be manually movable between open and closed positions, e.g., by an operator or passenger of the motor vehicle. In other embodiments, the motor vehicle access closure may be a so-called power closure or powered closure, i.e., in which the access closure is automatically controlled between open and closed positions so as to not require manual movement thereof. In such embodiments, the access closure control system 200 illustratively includes a conventional closure motor or other actuator 206 electrically coupled to a conventional motor driver 208 which is configured to be responsive to one or more control signals to drive the motor or other actuator 206 in a direction which closes or opens the access closure of the motor vehicle. In some embodiments of the system 200 which include the motor driver 208 and the closure motor 206, the closure latch/unlatch and/or lock/unlock functions may be controlled by the closure motor 206 and the actuator 105, closure lock 204 and/or closure latch 102 may be incorporated, in structure and/or function, into the closure motor 206 or operatively coupled thereto.

The access closure control system 200 further illustratively includes one or more sensors 210 which may be electrically coupled to signal processing circuitry 212 via a number, N, of signal paths, wherein N may be any positive integer. In alternate embodiments the sensor(s) 210 may be wirelessly coupled to the signal processing circuitry 212 so as to supply sensor signals wirelessly to the signal processing circuitry 212. The signal processing circuitry 212 is illustratively configured to process signals produced by the sensor(s) 210, and to produce one or more corresponding control signals for controlling operation of the access closure. In embodiments of the system 200 that include the E-latch module 202, the signal processing circuitry 212 is electrically (or wirelessly) coupled to the E-latch module 202, and is configured to supply control signals to the E-latch module 202 to cause the E-latch module 202 to control the closure latch 102 between latched and unlatched states and/or to control the closure latch 102 between locked and unlocked states. In embodiments which include the actuator 105 and the closure lock 204, the signal processing circuitry 212 is electrically (or wirelessly) coupled to the actuator 105, and is configured to supply control signals to the actuator 105 to cause the actuator 105 to control the closure lock 204 between locked and unlocked states. In embodiments which include the closure motor 206 and the motor driver 208, the signal processing circuitry 212 is electrically (or wirelessly) coupled to the motor driver 208, and is configured to supply control signals to the motor driver 208 to cause the motor driver 208 to control the closure motor 206 in a manner which locks/unlocks, latches/unlatches and moves the access closure between closed and open positions thereof. In some embodiments, a conventional speed and/or position sensor may be operatively coupled to the closure motor 206 and configured to produce sensor signals corresponding to closure motor speed and/or position relative to a reference position. In such embodiments, the closure motor speed/position sensor signals may be provided to the signal processing circuitry 212, and the signal processing circuitry 212 may be configured to be responsive to the closure motor speed and/or position to control operation of the motor driver in a manner which controls the speed at which the access closure is opened or closed and/or which controls the position of the access closure relative to a reference position.

The signal processing circuitry 212 may be conventional, and illustratively includes conventional electrical circuitry and/or electrical circuit components configured to process sensor signals produced by the one or more sensors 210 and to produce corresponding control signals for controlling operation of one or more of the E-latch module 202, the actuator 105 and/or the motor driver 208 in embodiments which include them. In some embodiments, as illustrated by dashed-line representation in FIG. 14, the signal processing circuitry 212 may be or include at least one conventional control circuit 214, e.g., in the form of one or more microprocessors and/or microcontrollers, including at least one conventional memory unit having instructions stored therein that are executable by the at least one control circuit to control the E-latch module 202, the actuator 105 and/or the motor driver 208. In some embodiments, as also shown by dashed-line representation in FIG. 14, the signal processing circuitry 212 may include at least one wireless communication circuit or module 216 configured to receive, or to transmit and receive, wireless communication signals, according to one or more conventional wireless signal communication protocols.

In some embodiments, at least one of the one or more sensors 210 may be mounted to or within an access closure handle 218 as illustrated by example in FIG. 14. In some embodiments in which the access closure handle 218 is configured to manually unlatch the closure latch 102 via manual movement of the access closure handle 218, the access closure handle 218 may be mechanically coupled to the closure latch 102 via a mechanical linkage L3 as illustrated by example in FIG. 14. In other embodiments in which the system 200 includes the E-latch module 202, the E-latch module 202 is configured to manually unlatch the closure latch 102 as is conventional, and sensor signals produced by the at least one of the one or more sensors 210 mounted to or within the access closure handle 218 in such embodiments may be used to unlatch the closure latch 102 and/or lock and/or unlock the closure latch 102 or the closure lock 204 depending upon the configuration of the system 200.

In some embodiments, at least one of the one or more sensors 210 may be mounted to or within a component 220 of the motor vehicle as illustrated by example in FIG. 14. Examples of the component 220 of the motor vehicle to or within which at least one of the one or more sensors 210 may be mounted may include, but are not limited to, an access closure of the motor vehicle, e.g., a door, lid or gate, a front or rear panel of the motor vehicle, a headlight assembly, tail light assembly or other lighting assembly mounted to the motor vehicle, a front grill or bumper of the motor vehicle, a rear bumper of the motor vehicle, a spoiler mounted to the motor vehicle, a roof of the motor vehicle, a window or windshield of the motor vehicle, an A-pillar, B-pillar, C-pillar or D-pillar of the motor vehicle, an under-surface of the motor vehicle (e.g., so as to be detectable by a foot or other object passed under the motor vehicle within an object detection range of the sensor), or other structure forming part of, or an accessory to, the motor vehicle or within a compartment, section or portion of the motor vehicle, e.g., engine compartment, storage compartment, portion of an access closure defined between inner and outer panels thereof, etc.

As further illustrated by example in FIG. 14, the signal processing circuitry 212 may, in some embodiments, be mounted solely to or within the access closure handle 218, e.g., within the housing of the access closure handle 218, and in other embodiments the signal processing circuitry 212 may be mounted solely to or within a component 220 of the motor vehicle or within two or more components 220 of the motor vehicle. In still other embodiments, at least a portion of the signal processing circuitry 212 may be mounted to or within the access closure handle 218, and at least another portion of the signal processing circuitry 212 may be mounted to or within a component 220 or within two or more of the components 220 of the motor vehicle. It will be understood that in embodiments in which the signal processing circuitry 212 is mounted, in whole or in part, to or within at least one component 220 of the motor vehicle, such component(s) 220 may or may not be the same component(s) 220 to or within which a sensor or sensors 210 is/are mounted.

In some embodiments, the at least one sensor 210 may include a single sensor mounted to or within the access closure handle 218 or mounted to or within the component 220 of the motor vehicle. In some such embodiments, for example, the single sensor may be used to control locking and unlocking of the access closure, wherein the signal processing circuit 212 may be operable to monitor the status or state of the E-latch module 202 or of the closure lock 204, and to be responsive to a detectable change in the signal produced by the single sensor, as described herein, to change the status or state from lock to unlock or from unlock to lock.

In embodiments in which the at least one sensor 210 includes multiple sensors, all of the multiple sensors 210 may be mounted to or within the access closure handle 218. The door handle assembly 10 illustrated in FIGS. 1-13 and described above is an example of such an embodiment which includes at least two sensors 210; one mounted along an inwardly-facing surface of the housing of the door handle assembly 10, i.e., so as to face the outer surface of the motor vehicle door, and another mounted along an outwardly-facing surface of the housing of the door handle assembly 10. In the embodiment illustrated in FIGS. 1-13, the door handle assembly 10 is mechanically coupled to the closure latch 102 via a mechanical linkage, although persons skilled in the art will recognize that the E-latch module 202 represents a technological advancement, and thus an equivalent, of the mechanical latch system. In embodiments of the system 200 which include the E-latch module 202, the access closure handle 218 may be mounted to, or form part of, one or more components of the access closure of the motor vehicle, and be used solely as a contact or grab mechanism for manually opening and/or closing the access closure. In any case, in such embodiments in which each of the multiple sensors 210 is mounted to or within the access closure handle 218, it will be understood that each of the multiple sensors 210 may be mounted to or along any surface of the housing of the access closure handle 218.

In other embodiments in which the at least one sensor 210 includes multiple sensors, all of the multiple sensors 210 may be mounted to or within at least one motor vehicle component 220, some examples of which are described hereinabove. In some such embodiments, each of the multiple sensors 210 may be mounted to or within a single motor vehicle component 220, although in other such embodiments the multiple sensors 210 may be distributed among, i.e., mounted to or within, two or more motor vehicle components 220. In any case, the access closure handle 218 may, in some such embodiments, be mechanically coupled to the closure latch 102 via a mechanical linkage L3 as illustrated by example in FIG. 14. In other such embodiments, the access closure handle 218 may be mounted to, or form part of, one or more components of the access closure of the motor vehicle, and be used solely as a contact or grab mechanism for manually opening and/or closing the access closure. In still other such embodiments of the system 200 which include the closure motor 206 and associated motor drive 208, the access closure handle 218 may be omitted.

In still other embodiments in which the at least one sensor 210 includes multiple sensors, one or more of the multiple sensors 210 may be mounted to or within the access closure handle 218 and another one or more of the multiple sensors 210 may be mounted to or within at least one component 220 of the motor vehicle. The access closure handle 218 may, in some such embodiments, be mechanically coupled to the closure latch 102 via a mechanical linkage L3 as illustrated by example in FIG. 14, although in alternate embodiments the access closure handle 218 may be mounted to, or form part of, one or more components of the access closure of the motor vehicle, and be used solely as a contact or grab mechanism for manually opening and/or closing the access closure. In any case, the signal processing circuitry 212 may, in some such embodiments, be mounted solely to or within the access closure handle 218, e.g., within the housing of the access closure handle 218, or may be mounted solely to or within one or more components 220 of the motor vehicle. In still other embodiments, at least a portion of the signal processing circuitry 212 may be mounted to or within the access closure handle 218, and at least another portion of the signal processing circuitry 212 may be mounted to or within one or more components 220 of the motor vehicle. It will be understood that in embodiments in which the signal processing circuitry 212 is mounted, in whole or in part, to or within one or more components 220 of the motor vehicle, such component(s) 220 may or may not be the same component(s) 220 to or within which a sensor or sensors 210 is/are mounted.

In some embodiments of the system 200, the signal processing circuit(s) 212 may include at least one wireless communication module 216 as briefly described above. In such embodiments, the wireless communication module 216 may be configured to communicate wirelessly with a wireless communication module 226 mounted in a conventional mobile communication device 222, carried by a person 224, e.g., operator or occupant of the motor vehicle, according to one or more conventional wireless communication protocols. Examples of the mobile communication device 222 may include, but are not limited to, a wireless key fob, a smart phone, or the like, and examples of the wireless communications conducted between the wireless communication modules 216 and 226 may include, but are not limited to, WiFi®, Bluetooth®, Zigbee®, LoRa®, NB-lot, Thread®, UWB®, and the like. In any case, at least one of the one or more sensors 210 may, in some such embodiments, be configured to produce sensor signals corresponding position of the person 224 and/or mobile communication device 222 relative to such a sensor 210, e.g., whether the person 224 and/or mobile communication device 22 has crossed a boundary defined relative to the sensor 210. In other such embodiments, at least one of the one or more sensors 210 may be provided in the form of at least one antenna or other such communication facilitating structure and configured to receive identification information from the mobile communication device 222 within a defined proximity thereof or upon contact therewith, and to provide such identification information to the wireless communication module 212 for use by the signal processing circuit(s) 212 to control the state of the closure latch 102, the closure lock 204 and/or closure motor 206. In some such embodiments, for example, the identification information may be stored in a memory of the mobile communication device 222 and in a memory of the signal processing circuit(s) 212, e.g., such as via a conventional electronic device pairing process or other process, and the signal processing circuit(s) 212 may be configured to control the state of the closure latch 102, the closure lock 204 and/or operation of the closure motor 206 based on match between such stored identification information. In some embodiments, the signal processing circuit(s) 212 may be configured to automatically control the closure motor 206 to close an open access closure and/or to automatically lock an unlocked closure lock 104 (or latch 102) upon detection of the mobile communication device 222 crossing a distance threshold from the signal processing circuit(s) 212, e.g., a predefined distance or a distance beyond which communication between the mobile communication device 222 and the signal processing circuit(s) 212 is not possible or reliable, and/or upon detection of the mobile communication device 222 moving away from the signal processing circuit(s) 212 with a velocity greater than a threshold velocity.

The number and type(s) of sensor(s) 210 used in any particular application of the system 200 may typically depend, at least in part, on the type or style of the access closure, the type or style of the closure assembly handle 218, if any, and which, or which combination, of the access closure control actuator(s) 102, 105, 202, 204, 206 and 208 are included in the access closure control system 200 just described. By way of example, which should not be considered to be limiting in any way, such sensors generally fall into three categories or types: (1) non-contacting proximity sensors, (2) contact or “touch” sensors, and (3) all other sensor types, and some examples of each are described below.

For purposes of this disclosure, non-contacting proximity sensors generally fall into the sub-classes of short range and long range sensors, wherein “short range” is defined to be in the range of within approximately 20 centimeters from the sensor, and “long range” is defined to be in the range of within approximately several hundred meters from the sensor. In either case, the “active range” of a non-contacting proximity sensor is defined as the range of distances between the sensor and an object within which the sensor will be responsive to the object to produce a detectable change in the sensor signal(s) produced thereby. Examples of short range, non-contacting proximity sensors may include, but are not limited to, capacitive sensors which include two opposed plates or which include only a single plate, such as the capacitive sensor 46 described above, optical proximity sensors, near-field communication (NFC) antennas, inductive proximity sensors, magnetic proximity sensors (e.g., Hall effect sensors), and the like. Examples of long-range, non-contacting proximity sensors may include, but are not limited to, radar transceivers or radar transmitter/receiver pairs, antennas for wireless communication protocols such as Bluetooth®, ultra-wide band (UWB®), low-frequency (LF), WiFi®, Zigbee® LoRa®, NB-lot, Thread® etc., and the like.

It will be understood that with some short range, non-contacting proximity sensors, the object to be sensed may be a portion of a human body, such as a hand, a foot, one or more fingers, etc., whereas with some other short range proximity sensors the object to be sensed may be a metal object or film (e.g., inductive), a magnet (e.g., Hall effect), an antenna (e.g., NFC) or other such structure attached to or otherwise forming part of a mobile object carried by an operator or passenger of the motor vehicle, such as the mobile communication device 222 illustrated by example in FIG. 14. In the case of NFC, the sensor 210 may be an NFC antenna and the wireless communication circuit or module 216 may be a conventional wireless communication module configured for wireless communication according to an NFC communication protocol, and the mobile object will be likewise equipped with an NFC antenna and NFC-configured communication circuit or module. Object detection in the NFC example will occur when the NFC antenna 210 and the NFC antenna of the mobile object carried by the operator or passenger of the motor vehicle are in-range with respect to one another, i.e., close enough to become inductively coupled, such that the NFC communication circuits or modules can exchange identification information with one another. In some specific embodiments in which the access closure handle 218 is to be used to manually open the associated access closure of the motor vehicle, a capacitive sensor positioned along the portion of the access closure handle 218 that is to be contacted by a person's hand or fingers, as illustrated by example in FIGS. 1-13, may be particularly useful for triggering the unlock feature as the person's hand or fingers will typically be already moving toward the sensor for the purpose of opening the access closure, and the unlock operation will thus be triggered prior to contact between the person's hand or fingers and the access closure handle 218.

Likewise with some long range, non-contacting proximity sensors, e.g., radar, the object to be sensed may be a human body or portion thereof, whereas with some other long range, non-contacting proximity sensors the object to be sensed may be an antenna mounted to or otherwise forming part of a mobile object carried by an operator or passenger of the motor vehicle, such as the mobile communication device 222 illustrated by example in FIG. 14. In the former case, the radar transceiver or radar transmitter/receiver pair 210 operates in a conventional manner to detect a person or persons within a conventional detection proximity of the sensor 210. In the latter case, the sensor 210 may be or include one or more antennas and the wireless communication circuit or module 216 may be a conventional wireless communication module configured for wireless communication according to a suitable communication protocol, e.g., Bluetooth®, ultra-wide band (UWB®), low-frequency (LF), WiFi®, Zigbee® LoRa®, NB-lot, Thread® etc., or the like, and the object to be detected will be a mobile object likewise equipped with one or more corresponding antennas and at least one communication circuit or module configured for wireless communication according to a corresponding communication protocol. Object detection in such a case may generally be carried out when the antenna of the mobile object carried by the operator or passenger of the motor vehicle is close enough to the antenna 210 such that the respective communication circuits or modules can communicate with one another and exchange identification information with one another.

For purposes of this disclosure, sensors 210 in the form of contact or “touch” sensors generally fall into the sub-classes of non-defective and deflective sensors. Both non-deflective and deflective touch sensors require an object, such as a finger, hand, or other object, to come into contact with a surface of an access closure handle 218 or a component 220 of the motor vehicle on or along which the touch sensor is mounted. Deflective touch sensors generally require deflection of at least a portion of a structure which extends over a sensing surface of the touch sensor, whereas non-deflective touch sensors generally do not require such deflection. One example of such a deflective touch sensor, in the form of an inductive touch sensor 60, is described above with respect to FIGS. 1-13. Another example of a deflective sensor is a capacitive touch sensor. A third example is a magnetic touch sensor. In each of these examples, an electrically conductive member, such as a film, is positioned on the surface of the deflectable structure opposite the sensing surface of the sensor, and upon deflection of the deflectable structure the electrically conductive member is displaced toward the sensing surface of the sensor, thereby changing the electrical characteristics of the sensor and causing a detectable change in the sensor signal(s) produced by the sensor. In the case of an inductive touch sensor, deflection of the electrically conductive member toward one or more coils results in a measurable change of inductance of the sensor as described above. In the case of a capacitive touch sensor, the electrically conductive member defines one plate of the capacitor and deflection of the electrically conductive member toward an opposite electrically conductive member results in a measurable change of capacitance of the sensor. In the case of a magnetic touch sensor, the electrically conductive member is magnetic, and the sensor may be, for example, a Hall effect sensor or other magnetic sensor such that deflection of the magnetic member toward the magnetic sensor results in a measurable change in the magnetic flux or field detected by the magnetic sensor.

Other examples of deflective touch sensors may include, but are not limited to, photoelectric, e.g., infrared light-based, distance sensors, piezoelectric sensors, and the like, wherein the piezoelectric sensor(s) may include one or more electrical components carried by or embedded in the deflectable structure, wherein the sensor is configured to produce a detectable change in the sensor signal(s) produced thereby based on a change in pressure, strain, force or acceleration resulting from the deflection. Examples of non-deflective touch sensors may include, but are not limited to, finger print sensors, tactile switches, non-deflecting pressure sensors, non-deflecting strain sensors, non-deflecting force sensors, and the like.

Other forms of sensors or sensing devices usable as, or as part of, the one or more sensors 210 may be or include, one or more cameras, one or more microphones, one or more optical sensors, or the like. It will be understood that any of the non-contacting proximity sensors, touch sensors or other sensors used as, or as part of, the one or more sensors 210 may be conventional in structure and operation.

For purposes of this disclosure, a “sensor activation event,” for any of the one or more sensors 210, is defined as an event which produces a detectable change in the sensor signal(s) produced by the respective sensor 210. For the non-contacting proximity sensors described above, a sensor activation event will generally occur when an object, e.g., a hand, finger(s) or other portion of a person, or a specifically-configured device carried by a person, e.g., a mobile object such as (but not limited to) a mobile communication device, is moved to within a detection proximity of the respective sensor 210. For the short range, non-contacting proximity sensors described above, the detection proximity of the respective sensor will typically, although not exclusively, be defined by the detection range of the respective sensor. For the long-range, non-contacting proximity sensors described above, the detection proximity of the respective sensor will typically, although not exclusively, be defined as a specified distance from, e.g., a perimeter about, the respective sensor. In the case of radar transceivers or radar transmitter/receiver pairs, the specified distance may be arbitrary, a non-limiting example of which may be 5-30 feet. The same may be the case for some embodiments of short range, non-contacting proximity sensors. In the case of long-range, non-contacting proximity sensors 210 in the form of one or more antennas, wherein the wireless communication circuit or module 216 is configured for wireless communication according to a suitable communication protocol, and wherein the object to be detected will be a mobile object, e.g., mobile communication device, likewise equipped with a corresponding antenna and communication circuit or module configured for wireless communication according to a corresponding communication protocol, the signal processing circuit(s) 212 will typically include one or more circuits configured to process communication signals produced and detected by the wireless communication circuit or module 216 to continually determine a distance between the two antennas. The detection proximity of such sensors 210 will then typically be defined as a specified distance from, e.g., a perimeter about, the respective antenna, one non-limiting example of which may be 5-30 feet.

For the deflective touch sensors described above, a sensor activation event which produces a detectable change in the sensor signal(s) produced by the respective sensor 210 will generally occur when the deflectable structure is measured by the sensor 210 as being deflected a predetermined distance from its pre-deflected position, or has been deflected to within a detection proximity of a sensing surface of the sensor 210. For the non-deflective touch sensors described above, a sensor activation event which produces a detectable change in the sensor signal(s) produced by the respective sensor 210 will generally occur when a physical attribute measured by the sensor 210, e.g., pressure, strain, force, acceleration, etc., in response to contact with a structure which extends at least partially over the sensor 210 or which at least partially incorporates the sensor 210 therein, exceeds (or drops below) a specified threshold value. In some embodiments, the signal processing circuit(s) 212 may be configured to compare the measured physical attribute with two or more stored or dynamic threshold values such that a single sensor 210 may be used to control two or more respective operational states of the motor vehicle access closure depending upon the magnitude of the measured physical attribute. In some embodiments, the threshold(s) may be programmable. In some embodiments, one or more touch sensors may require multiple consecutive touches for sensor activation. In some embodiments which include multiple touch sensors, a predetermined or programmable sequence of sensor touches may be required for sensor activation.

For the “other” sensor described above, a sensor activation event which produces a detectable change in the sensor signal(s) produced by the respective sensor 210 will generally depend on the type of sensor. With the sensor in the form of a camera, for example, the activation event may correspond to one or more recognizable objects detected with the field of view of the camera. With the sensor 210 in the form of a microphone, as another example, the activation event may be a specified word or phrase spoken and detected by the microphone. Other types of sensors, which will have one or more specific activation events associated therewith, will occur to those skilled in the art, and it will be understood that such other types of sensors are intended to fall within the scope of this disclosure.

As described above, any one or combination of the one or more sensors 210, in the form of one or any combination of the different types and/or specific examples of sensors just described, may be implemented in the system 200 for controlling the operating state of an access closure of the motor vehicle. As further described above, the sensor(s) 210 may be mounted solely to or within the access closure handle 218, solely to or within a component 220 of the motor vehicle, or distributed between the two with at least one sensor 210 mounted to or within the access closure handle 218 and at least another sensor 210 mounted to or within a component 220 of the motor vehicle. It will be understood that whereas this disclosure has thus far referred to control of the operating state of a single access closure, it will be understood that the motor vehicle may be outfitted with suitable controls for controlling the operating states of two or more access closures of a motor vehicle, wherein the two or more access closures may be identical or similar to one another or may instead be different from one another in structure and/or operation. In some embodiments, one or some of the access closures may have identical access closure control actuators (e.g., any one or combination of 102, 105, 202, 204, 206 and/or 208), and another or others of the access closures may have different access closure control actuators. In some embodiments, each access closure may have a specific one or set of sensors 210 associated therewith, although in alternate embodiments one or more access closure may have a different one or set of sensors 210 associated therewith. In still other embodiments, sensor signals produced by one or more of the sensors 210 of the system 200 may be used to control at least one operating state of two or more access closures of the motor vehicle.

In any case, control in the system 200 of the operating state of any particular motor vehicle access closure, e.g., between locked/unlocked states, latched/unlatched states and/or power open/closed, will depend on the makeup of the associated access closure control actuators implemented in the system 200, wherein the access closure control actuators in any particular embodiment will be understood to be or include one or various combinations of the lock actuator 105, the closure lock 204, the E-latch module 202, the closure latch 102, the closure motor 206 and the motor driver 208. Example combinations of such access closure control actuators may include, but are not limited to, (i) the lock actuator 105 and the closure lock 204, (ii) the lock actuator 105 and closure latch 102 (in embodiments in which the closure lock 204 is integrated into or is otherwise a part of the closure latch 102), (iii) the E-latch module 202, the closure latch 102, the actuator 105 and the closure lock 204, (iv) the E-latch module 202, the closure latch 102 and the actuator 105 (in embodiments in which the closure lock 204 is integrated into or is otherwise a part of the closure latch 102), (v) the E-latch 202, the closure latch 102, the actuator 105, the closure lock 204, the motor driver 208 and the closure motor 206, (vi) the E-latch module 202, the closure latch 102, the actuator 105 (in embodiments in which the closure lock 204 is integrated into or is otherwise a part of the closure latch 102), the motor driver 208 and the closure motor 206, (vii) the actuator 105, the closure lock 204, the motor driver 208 and the closure motor 206 (in embodiments in which the closure latch 102 is integrated into or is otherwise part of the closure motor 206, (viii) the E-latch module 202, the closure latch 102, the motor driver 208 and the closure motor 206 (in embodiments in which the closure lock 204 is integrated into or is otherwise part of the closure motor 206), and (ix) the closure motor 206 and the motor driver 208 (in embodiments in which the closure lock 204 and the closure latch 102 are integrated into or are otherwise part of the closure motor 206).

In some example embodiments which include the actuator 105 but do not include the E-latch module 202 or the closure motor 206 and driver 208, the signal processing circuit(s) 212 of the system 200 may be configured to control, based on signals produced by one or more of the sensors 210, the actuator 105 to control the closure lock 204 (or to control the closure latch 102 in embodiments in which the lock/unlock feature is incorporated therein) between locked and unlocked states. In some embodiments, a single sensor 210 may be used for both functions, wherein the signal processing circuit(s) monitors and tracks the current locked/unlocked state so that each detection by the single sensor 210 of a sensor activating event will result in a corresponding change from the unlocked state to the locked state or from the locked state to the unlocked state. In alternate embodiments, the at least one sensor 210 may include two sensors; one to control locking and the other to control unlocking.

In other example embodiments which include the actuator 105 and the E-latch module 202 but which do not include the closure motor 206 and driver 208, the signal processing circuit(s) 212 of the system 200 may be configured to control, based on signals produced by one or more of the sensors 210, the actuator 105 to control the closure lock 204 (or to control the closure latch 102 in embodiments in which the lock/unlock feature is incorporated therein) between locked and unlocked states, and to control, based on signals produced by one or more of the sensors 210, the E-latch module 202 to control the closure latch 102 from a latched state to an unlatched state. In some embodiments, one of the sensors 210 may be used to control the lock/unlock state of the closure lock 204 (or to control the lock/unlock state of the closure latch 102 in embodiments in which the lock/unlock feature is incorporated therein) as described above, and another one of the sensors 210 may be used to control the E-latch module 202 to cause the closure latch 102 to change from a latched state to an unlatched state. In alternate embodiments, three sensors 210 may be used; one to control locking, another to control unlocking and a third to control unlatching of the access closure. In other alternate embodiments, one or more touch sensors 210 may be used with at least one of the sensors 210 having multiple touch thresholds, or a specified or programmable activation sequence of two or more touch and/or non-contacting proximity sensors may be used. In still other alternate embodiments, in which the actuator 105 is integrated into or otherwise forms part of the closure latch 102, the signal processing circuit(s) 212 of the system 200 may be configured to control locking, unlocking and unlatching of the access closure solely via control of the E-latch module.

In still other example embodiments which include the closure motor 206 and driver 208, the signal processing circuit(s) 212 of the system 200 may be configured to control, based on signals produced by one or more of the sensors 210, the motor driver 208 to cause the closure motor 206 to move the access closure between closed and open positions. In some embodiments, a single one of the sensors 210 may be used to control the open/closed state of the access closure, e.g., as described above with a single-sensor control of the closure lock 204, and in other embodiments one of the sensors 210 may be used to control opening of the access closure, and another one of the sensors 210 may be used to control closing of the access closure. In some embodiment, another (or others) of the sensors 210 may be used to control locking/unlocking of the access closure. In some embodiments, another of the sensors 210 may be used to control unlatching of the access closure.

In some embodiments, control by the signal processing circuit(s) 212 of the operating state of a motor vehicle access closure, e.g., between locked/unlocked states, latched/unlatched states and/or power opened/closed, in response to a sensor activation event, as described above, may be carried out only after the signal processing circuit(s) 212 is/are enabled to do so. In one embodiment, for example, the mobile communication device 222 illustrated by example in FIG. 14 and the signal processing circuit(s) 212 may be configured to automatically communicate wirelessly with one another for the purpose of sharing identification information and, upon confirmation that the shared identification information identifies the mobile communication device 222 as a previously authorized electronic device, the signal processing circuit(s) 212 will be enabled to control the operating state of the motor vehicle access closure in response to sensor activation event(s) as described above. In such embodiments, without such enablement of the signal processing circuit(s) 212, the signal processing circuit(s) 212 will not be responsive to sensor activation events to control the operating state(s) of the access closure(s). In some such embodiments, wireless communication circuit 216 of the signal processing circuit(s) 212 is configured to periodically transmit wireless communication signals or signal pulses. In other embodiments, the wireless communication circuit 226 of the mobile communication device 222 is configured to periodically transmit wireless communication signals or signal pulses, and in still other embodiments both of the wireless communication circuits 216, 226 may be configured to periodically transmit wireless communication signals or signal pulses. In any case, upon detection by one and/or the other of the wireless communication circuits 216, 226 of such wireless communication signals or signal pulses, a conventional communication exchange between the wireless communication circuits 216, 226 in which identification information is communication to the wireless communication circuit 216 which relates to the identity of the wireless communication circuit 226 and/or of the mobile communication device 222 generally.

In some embodiments, such identification information may be stored in a memory of the mobile communication device 222, and in other embodiments at least a portion of the identification information may be generated dynamically. Such identification information may be transmitted in any portion of the wireless signal(s) produced by the mobile communication device 22, one non-limiting example of which may be in the header(s) of the wireless signal(s). Corresponding identification information may be stored in a memory device of the signal processing circuit(s) 212, and the signal processing circuit(s) 212 is illustratively operable to confirm that the identification information transmitted by the mobile communication device 222 identifies the mobile communication device 222 as a previously authorized electronic device, so as to enable the signal processing circuit(s) 212 to control at least one operating state of the access closure based on at least one sensor activation event, based matching identification information. In some embodiments, the identification information associated with the wireless communication circuit 216 and/or the signal processing circuit(s) 212 generally, and the identification information associated with the wireless communication circuit 226 and/or the mobile communication device 222 generally, may be pre-authorized according to a conventional pairing process conducted between the mobile communication device 222 and the signal processing circuit(s) 212. In alternate embodiments, other conventional processes may be used to pre-authorize or authenticate the mobile communication device 222 as one which will enable the signal processing circuit(s) 212 to control at least one operating state of the access closure based on at least one sensor activation event.

The wireless communication circuits 216 and 226 will generally begin the pre-authorization (or authentication or identification) process when the mobile communication device 222 is within communication range of the wireless communication circuit 216 of the signal processing circuit(s) 212 defined by perimeter about the wireless communication circuit 216. In some embodiments, such a communication range perimeter may be defined by a maximum wireless signal transmission range of the wireless communication circuit 226 and/or the wireless communication circuit 216. In other embodiments, the wireless communication circuit(s) 212 and/or the mobile communication device 222 may be configured in a conventional manner such that the communication range perimeter may be or correspond to a predefined perimeter which is less than the maximum wireless signal transmission range of the wireless communication circuit 226 and/or the wireless communication circuit 216. An example communication range perimeter may be in the range of 10-50 feet, although it will be understood that greater or lesser communication range perimeters may alternatively be used.

It will be understood that in addition to controlling any of the operating states of the access closure as just described, any of the vehicle access closure control signals described above may also be used to control one or more accessories of the motor vehicle in which the vehicle access closure control system 200 is mounted. In such embodiments, the vehicle access closure control signal(s) may be communicated, wirelessly or with one or more wires, to one or more control modules or circuits 230 of the motor vehicle as illustrated by example in FIG. 14, and the signal processing circuit(s) 212 and/or one or more control modules or circuits 230 may be configured to be responsive to one or more of the vehicle access closure control signals (e.g., lock/unlock, unlatch, open/close) to activate, deactivate and/or otherwise control, in a conventional manner, the one or more internal (i.e., operator and/or passenger compartment) and/or external (i.e., mounted to or otherwise part of an exterior) accessories 232 of the motor vehicle in accordance with one or more preset or programmable instructions. Examples of such one or more accessories of the motor vehicle may include, but are not limited to, one or more internal and/or external lamps/lights, one more power windows (e.g., controlling at least partially up or down), one or more power seats (e.g., controlling the seat(s) to any position), one or more seat heaters and/or coolers, one more occupant support/comfort devices associated with a vehicle seat, one or more internal and/or external haptic feedback devices, internal climate control system (e.g., HVAC), entertainment system (e.g., radio, magnetic tape, compact disc and/or streaming audio), an exterior color (e.g., chromatic paint) of one or more exterior and/or interior surfaces of the motor vehicle, retractable roof and/or sunroof, rearview and/or side mirror position, steering wheel position, or any motor vehicle personalization device, assembly or system. With respect to accessories 232 in the form of one or more external lamps or lights, examples of such external lamps or lights may be or include, but are not limited to, one or any combination of conventional external lights or lamps such as a headlamp, a tail lamp, a turn signal lamp, a fog light, a reverse or back-up light, a brake light, a license plate lamp, and a badge light and/or may further include at least one light or lamp associated with one or more sensor(s) 210 for purposes of illuminating the sensor(s) 210, e.g., via backlighting of at least one sensor 210, lighting over at least one sensor 210, lighting integrated into a housing or badge in which at least one sensor 210 is mounted, or lighting integrated into a component of the motor vehicle adjacent to at least one sensor 210, so that at least one sensor 210 is identifiable by a user. In some embodiments, one or more such lights or lamps may be suitably mounted to the motor vehicle or to a structure of the motor vehicle, and in other embodiments one or more such lights or lamps may be integral with the motor vehicle or a component thereof. In some embodiments, detection or determination by the sensor processing circuit(s) 212 of a closed access closure, e.g., latching after an unlatched state and/or closing of the access closure after opening by the access closure motor 206, may trigger different and/or additional control of one or more accessories. Examples may include, but are not limited to, activating or deactivating one or more internal and/or external lights, controlling the position of one or more windows, controlling the position of one or more power seats, e.g., to a pre-programmed position, controlling one or more seat support/comfort devices to one or more respective states or positions, activating one or more seat heating or cooling devices, controlling the position of the steering wheel to a pre-programmed drive position, etc.

In addition to controlling any of the operating states of the access closure and/or controlling one or more accessories of the motor vehicle, signals produced by one or more of the sensors 210 may also be used by the signal processing circuit(s) 212 and/or by one or more control modules or circuit 230 to perform one or more other functions depending upon the type of sensor(s) 210 used. As one example, in embodiments which include in the one or more sensors 210 at least one radar transceiver or radar transmitter/receiver pair, corresponding sensor signals produced by the radar transceiver or radar transmitter/receiver pair may be used to detect objects other than an approaching motor vehicle operator or passenger for the purpose of avoiding impact of the motor vehicle with such an object. As an example, the sensor signals produced by a radar transceiver or radar transmitter/receiver pair 210 may be used when the vehicle is stationary to control operation of an access closure of the motor vehicle upon detection of an approaching motor vehicle operator as described above, and may additionally be used when the vehicle is moving to activate or control one or more motor vehicle safety features upon detection of an impending impact of the motor vehicle with the object. Examples of such one or more motor vehicle safety features may include, but are not limited to, a braking system of the motor vehicle, one or more occupant restraint devices (e.g., one or more airbags or seat belt tensioning systems, etc.), or the like. Other and/or additional functions to be performed by the signal processing circuit(s) 212 and/or by one or more control modules or circuit 230, based on signal produced by one or more of the sensors 210, will occur to those skilled in the art, and it will be understood that any such other and/or additional functions are intended to fall within the scope of this disclosure.

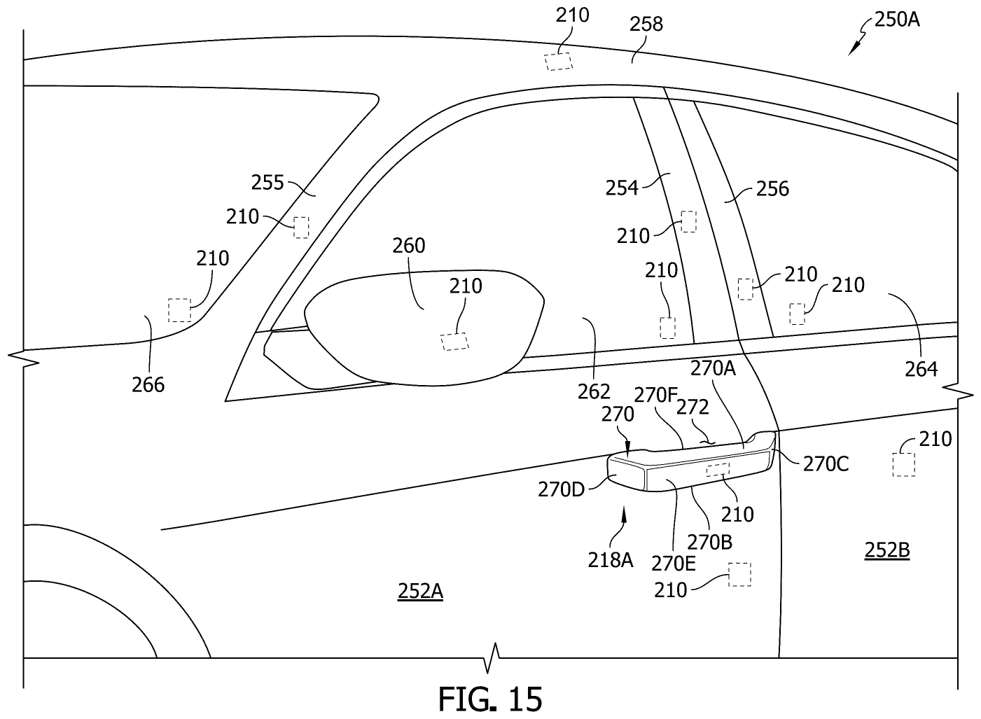

As described above, the sensor(s) 210 may be or include one or more sensors placed in any of various locations on or in the motor vehicle, such as, but not limited to, on or within the access closure handle 218, on or in at least one component 220 of the motor vehicle, to an underside of the motor vehicle, or the like. Non-limiting examples of the at least one component 220 are given above. As also described above, the access closure handle 218 may be mechanically coupled to the closure latch 102 so as to be manually actuated in a conventional fashion to unlatch the closure latch 102 and open/close the access closure 218. Alternatively, in embodiments which include the E-latch module 202, the closure access handle 218 may be used only to manually open and/or close the access closure. Alternatively still, in embodiments which include the closure motor 206 and motor driver 208, the closure access handle may be omitted. In this regard, FIGS. 15-29 show a number of non-limiting examples of access closures, some with various different implementations of access closure handles 218 and others with no access closure handles 218. It will be understood that whereas some of these illustrated examples may show one or more example mounting locations of one or more respective sensors 210, a sensor 210, or any of multiple sensors 210, in whole or in part, may alternatively or additionally be mounted to or within any portion of the illustrated access closure handles 218 and/or to or within any component 220 of the motor vehicle, some examples of which are described herein.

Referring now to FIG. 15, an example motor vehicle 250A is shown depicting front 252A and rear 252B access closures along a so-called driver's side of the motor vehicle 250A, and an embodiment of an access closure handle 218A mounted to the front access closure 252A. In the illustrated embodiment, the access closure handle 218A is mounted to the front access closure 252A and is coupled via the mechanical linkage L3 to a closure latch 102 (see FIG. 14), such that the access closure handle 218A is configured, in a conventional manner, to manually actuate the latch 102 and to manually open/close the access closure 252A. In the illustrated embodiment, the access closure handle 218A includes a housing 270 having a top surface 270A, a bottom surface 270B opposite the top surface 270A, opposed rearward and forward surfaces 270C, 270D, a front surface 270E and a rear surface 270F opposite the front surface 270E. Generally, the surfaces 270C-270F are each bounded on top and bottom by respective ones of the top surface 270A, 270B, and the rearward and forward surfaces 270C, 270D are further bounded by the front surface 270E. The front surface 270E generally faces away from the external or outer surface of the access closure 252A, and the rear surface 270F generally faces the external or outer surface of the access closure 252A. A gap 272 is defined between the rear surface 270F and the external surface of the access closure 252A. The gap 272 is illustratively sized to allow a human hand or portion thereof to pass between the rear surface 270F and the external surface of the access closure 252A. In the embodiment depicted by example in FIG. 15, the motor vehicle 250 further illustratively includes a window frame 254, a B-pillar 256, a top 258, and a side-view mirror 260. A movable window 262, e.g., movable up and down) is operatively mounted to the front access closure 252A, and another movable window 264 is operatively coupled to the rear access closure 252B. A windshield 266 is mounted along a front of the motor vehicle 250 as is conventional. Although not specifically depicted in FIG. 15, it will be understood that the motor vehicle 250 includes all other conventional components.

In some embodiments in which one or more of the sensors 210 is/are mounted to the access closure handle 218A, any such sensor(s) 210 may be mounted to or within the access closure handle 218A along one or any combination of the surfaces 270A-270F so as to be activated as described above. In the embodiment illustrated in FIGS. 1-13, for example, two such sensors are mounted within the access closure handle of the type illustrated in FIG. 15, each along a respective surface 270A and 270F of the housing 270. In the example illustrated in FIG. 15, one or more sensors 210 may alternatively or additionally be mounted within the access closure handle 218A along the surface 270E of the housing 270. In embodiments in which one or more of the sensors 210 is/are alternatively or additionally mounted to the motor vehicle 250, any such sensor(s) 210 may be mounted to or within any one or more of the components 220 of the motor vehicle (see FIG. 14). In the depiction of the motor vehicle 250 depicted in FIG. 15, for example, one or more sensors 210 may be mounted to or within the motor vehicle 250A, on or behind, one or more externally-facing surface(s) of any one or combination of the front access closure 252A, the rear access closure 252B, the window frame 254, the B-pillar 256, the A-pillar 255, the top 258, the side-view mirror 260, e.g., on, behind and/or integrated into one or more surfaces of an external skin of any such component, and/or on, behind and/or integrated into any of the windows 262-266. It will be understood that one or more sensors 210 may likewise be alternatively or additionally mounted to one or more other components of the motor vehicle 250A not depicted in FIG. 15, as described above.

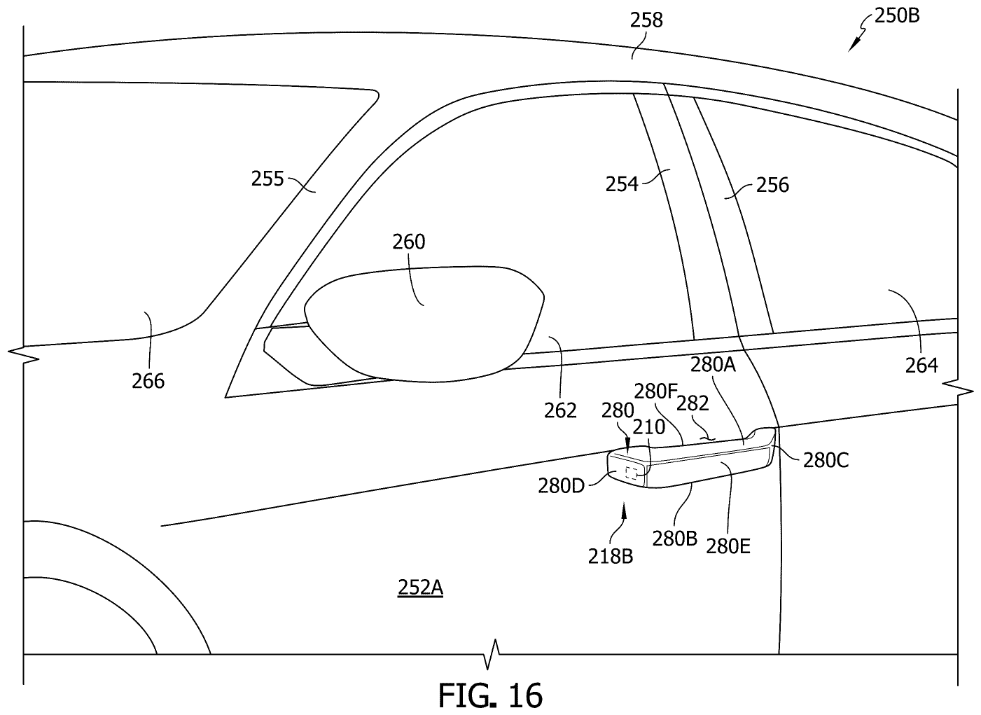

Referring now to FIG. 16, another example motor vehicle 250B is shown with another embodiment of an access closure handle 218B mounted to the front access closure 252A. The motor vehicle 250B is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15. In the embodiment illustrated in FIG. 16, the access closure handle 218B is mounted to the front access closure 252A but is not coupled via a mechanical linkage L3 to a closure latch 102 of the access closure 252A. Rather, in this embodiment, the access closure handle 218B is similar in shape and profile to the access closure handle 218A, but unlike the access closure handle 218A the access closure handle 218B is rigidly affixed to the front access closure 252A such that the access closure handle 218B does not move or articulate relative to the front access closure 252A. In this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218B may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14.

In the illustrated embodiment, the access closure handle 218B includes a housing 280 having a top surface 280A, a bottom surface 280B opposite the top surface 280A, opposed rearward and forward surfaces 280C, 280D, a front surface 280E and a rear surface 280F opposite the front surface 280E. Generally, the surfaces 280C-280F are each bounded on top and bottom by respective ones of the top surface 280A, 280B, and the rearward and forward surfaces 280C, 280D are further bounded by the front surface 280E. The front surface 280E generally faces away from the external or outer surface of the access closure 252A, and the rear surface 280F generally faces the external or outer surface of the access closure 252A. A gap 282 is defined between the rear surface 280F and the external surface of the access closure 252A. The gap 282 is illustratively sized to allow a human hand or portion thereof to pass between the rear surface 280F and the external surface of the access closure 252A.

In some embodiments in which one or more of the sensors 210 is/are mounted to the access closure handle 218B, any such sensor(s) 210 may be mounted to or within the access closure handle 218B along one or any combination of the surfaces 280A-280F so as to be activated as described above. In the embodiment illustrated in FIG. 16, for example, at least one such sensor 210 is shown mounted within the access closure handle 218B along the surface 280D of the housing 280. In some embodiments, one or more sensors 210 may alternatively or additionally be mounted to or within the access closure handle 218B along one or more other surfaces of the housing 280. In embodiments in which one or more of the sensors 210 is/are alternatively or additionally mounted to the motor vehicle 250B, any such sensor(s) 210 may be mounted to or within any one or more of the components 220 of the motor vehicle as depicted by example in FIG. 15, although it will be understood that one or more sensors 210 may be alternatively or additionally mounted to one or more other components of the motor vehicle 250B that is/are not depicted in FIG. 15, as described above.

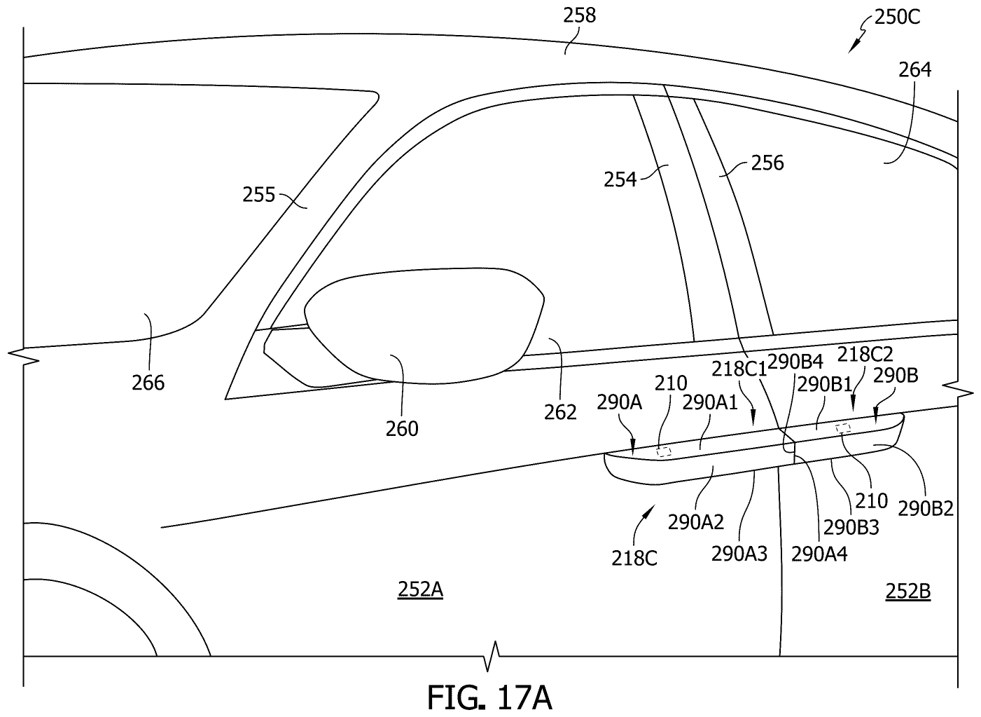

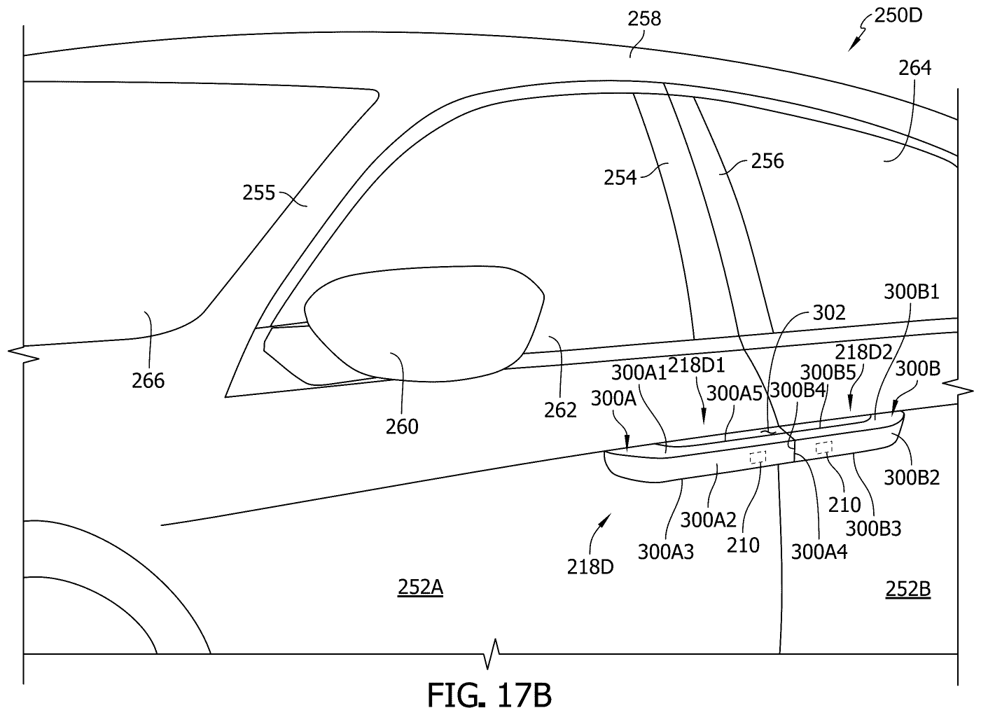

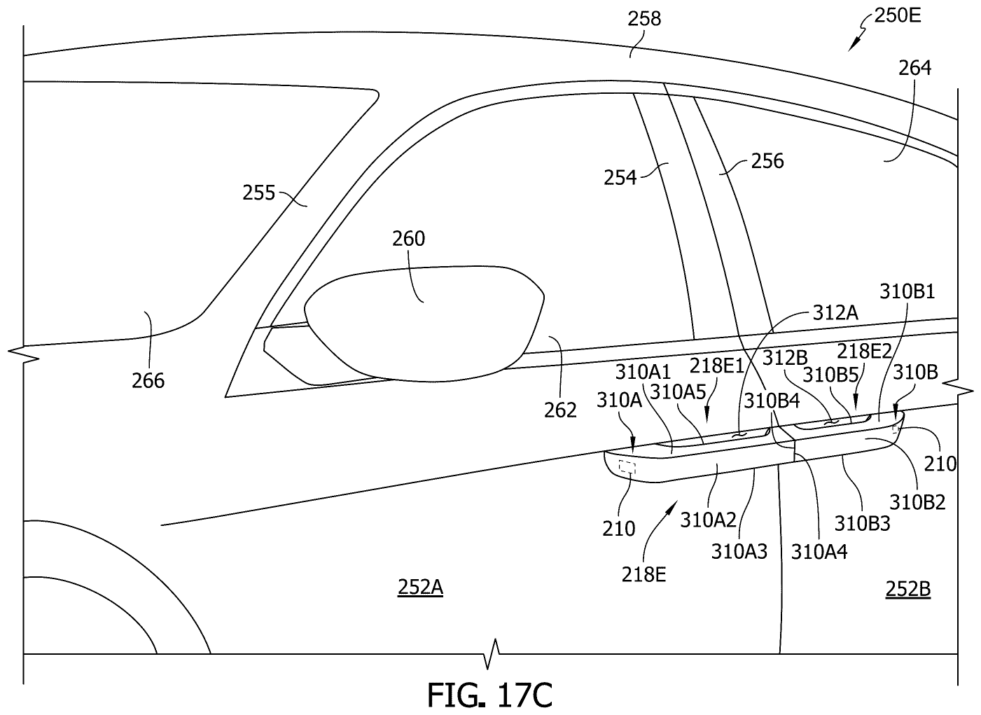

Referring now to FIG. 17A, another example motor vehicle 250C is shown with another embodiment of an access closure handle 218C mounted to the front and rear access closures 252A, 252B. The motor vehicle 250C is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15. In the embodiment illustrated in FIG. 17A, the access closure handle 218C includes a front access closure handle component 218C1 mounted to the front access closure 252A and a rear access closure handle component 218C2 mounted to the rear access closure 252B. In this embodiment, the front access closure handle component 218C1 is rigidly affixed to the front access closure 252A such that the front access closure handle component 218C1 does not move or articulate relative to the front access closure 252A, and the rear access closure handle component 218C2 is likewise rigidly affixed to the rear access closure 252B such that the rear access closure handle component 218C2 does not move or articulate relative to the rear access closure 252B. In the embodiment illustrated in FIG. 17A, neither access closure handle 218C1, 218C2 is coupled via a respective mechanical linkage L3 to a respective closure latch 102 associated with the respective access closure 252A, 252B. Rather, in this embodiment, signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202. Signal processing circuit(s) 212 is/are likewise electrically coupled to another E-latch module 202 associated with the access closure 252B, and signals produced by one or more of the sensor(s) 210 are used by such signal processing circuit(s) 212 to control unlatching of the closure latch 102 of the access closure 252B via control of the respective E-latch module 202. In some embodiments separate signal processing circuit(s) 212 may be used; one for each access closure 252A, 252B, although in alternate embodiments the two E-latch modules 202 may share one signal processing circuit(s) 212. In some embodiments which include such E-latch modules 202, the access closure handle 218C1 and/or the access closure handle 218C2 may also be mechanically coupled via a respective mechanical linkage L3 to a closure latch 102 of a respective one of the access closures 252A, 252B, or separate “emergency” handles may be coupled via mechanical linkages L3 to respective ones of the closure latches 102, any of which and may be configured to move or articulate relative to the respective access closure 252A, 252B to provide for a mechanical failsafe mechanism for unlatching the respective access closure 252A, 252B in the event of a failure of the electrical system illustrated by example in FIG. 14.

In the illustrated embodiment, the front access closure handle component 218C1 includes a housing 290A having a top surface 290A1, a bottom surface 290A3 opposite the top surface 290A1, a front surface 290A2 and a rearward surface 290A4, wherein the front surface 290A2 is bounded on top and bottom by respective ones of the top and bottom surfaces 290A1, 290A3 and at one end by the rearward surface 290A4, and the rearward surface 290A4 is similarly bounded by the top, bottom and front surfaces 290A1, 290A3 and 290A2 respectively. The rear access closure handle component 218C2 likewise includes a housing 290B having a top surface 290B1, a bottom surface 290B3 opposite the top surface 290B1, a front surface 290B2 and a forward surface 290B4, wherein the front surface 290B2 is bounded on top and bottom by respective ones of the top and bottom surfaces 290B1 290B3 and at one end by the forward surface 290B4, and the forward surface 290B4 is similarly bounded by the top, bottom and front surfaces 290B1, 290B3 and 290B2 respectively. The front surfaces 290A2, 290B2 of the housings 290A, 290B generally face away from the external or outer surface of the access closure 252A, and the access closure handle components 218C1, 218C2 are positioned relative to the respective front and rear access closures 252A, 252B such that, with both access closures 252A, 252B closed, the rearward surface 290A4 of the housing 290A and the forward surface 290B4 of the housing 290B face one another as illustrated by example in FIG. 17A. In some embodiments, the rearward surface 290A4 and the forward surface 290B4 abut one another with the access closures 252A, 252B closed, although in other embodiments the rearward surface 290A4 and the forward surface 290B4 may be spaced apart from one another when the access closures 252A, 252B are closed.

In some embodiments in which one or more of the sensors 210 is/are mounted to the access closure handle 218C, any such sensor(s) 210 may be mounted to or within either or both of the access closure handle components 218C1, 218C2 along one or any combination of the surfaces 290A1-290A3, 290B1-290B3 so as to be activated as described above. In the embodiment illustrated in FIG. 17A, for example, at least one such sensor 210 is shown mounted within the access closure handle component 218C1 along the surface 290A2 of the housing 290A and at least one such sensor 210 is shown mounted within the access closure handle component 218C2 along the surface 290B2 of the housing 290B. In other examples, at least one sensor 210 may be mounted within only one of the access closure handle components 218C1, 218C2. In some embodiments, one or more sensors 210 may alternatively or additionally be mounted to or within the access closure handle 218C1 along one or more other surfaces of the housing 290A and/or mounted to or within the access closure handle component 218C2 along one or more other surfaces of the housing 290B. In embodiments in which one or more of the sensors 210 is/are alternatively or additionally mounted to the motor vehicle 250C, any such sensor(s) 210 may be mounted to or within any one or more of the components 220 of the motor vehicle as depicted by example in FIG. 15, although it will be understood that one or more sensors 210 may be alternatively or additionally mounted to one or more other components of the motor vehicle 250C that is/are not depicted in FIG. 15, as described above.

Referring now to FIG. 17B, another example motor vehicle 250D is shown with another embodiment of an access closure handle 218D mounted to the front and rear access closures 252A, 252B. The motor vehicle 250D is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15. In the embodiment illustrated in FIG. 17B, the access closure handle 218D includes a front access closure handle component 218D1 mounted to the front access closure 252A and a rear access closure handle component 218D2 mounted to the rear access closure 252B. In this embodiment, the front access closure handle component 218D1 is rigidly affixed to the front access closure 252A such that the front access closure handle component 218D1 does not move or articulate relative to the front access closure 252A, and the rear access closure handle component 218D2 is likewise rigidly affixed to the rear access closure 252B such that the rear access closure handle component 218D2 does not move or articulate relative to the rear access closure 252B. In the embodiment illustrated in FIG. 17B, neither access closure handle 218D1, 218D2 is coupled via a respective mechanical linkage L3 to a respective closure latch 102 associated with the respective access closure 252A, 252B. Rather, in this embodiment, signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202. Signal processing circuit(s) 212 is/are likewise electrically coupled to another E-latch module 202 associated with the access closure 252B, and signals produced by one or more of the sensor(s) 210 are used by such signal processing circuit(s) 212 to control unlatching of the closure latch 102 of the access closure 252B via control of the respective E-latch module 202. In some embodiments separate signal processing circuit(s) 212 may be used; one for each access closure 252A, 252B, although in alternate embodiments the two E-latch modules 202 may share one signal processing circuit(s) 212. In some embodiments which include such E-latch modules 202, the access closure handle 218D1 and/or the access closure handle 218D2 may also be mechanically coupled via a respective mechanical linkage L3 to a closure latch 102 of a respective one of the access closures 252A, 252B, or separate “emergency” handles may be coupled via mechanical linkages L3 to the respective closure latches 102, any of which and may be configured to move or articulate relative to the respective access closure 252A, 252B to provide for a mechanical failsafe mechanism for unlatching the respective access closure 252A, 252B in the event of a failure of the electrical system illustrated by example in FIG. 14.

In the illustrated embodiment, the front access closure handle component 218D1 includes a housing 300A having a top surface 300A1, a bottom surface 300A3 opposite the top surface 300A1, a front surface 300A2, a rear surface 300A5 opposite the front surface 300A2, and a rearward surface 300A4, wherein the front surface 300A2 and the rear surface 300A5 are each bounded on top and bottom by respective ones of the top and bottom surfaces 300A1, 300A3 and at one end by the rearward surface 300A4, and the rearward surface 300A4 is similarly bounded by the top, bottom, front and rear surfaces 300A1, 300A3, 300A2 and 300A5 respectively. The rear access closure handle component 218D2 likewise includes a housing 300B having a top surface 300B1, a bottom surface 300B3 opposite the top surface 300B1, a front surface 300B2, a rear surface 300B5 opposite the front surface 300B2, and a forward surface 300B4, wherein the front surface 300B2 and the rear surface 300B5 are each bounded on top and bottom by respective ones of the top and bottom surfaces 300B1, 300B3 and at one end by the rearward surface 300B4, and the forward surface 300B4 is similarly bounded by the top, bottom, front and rear surfaces 300B1, 300B3, 300B2 and 300B5 respectively. The front surfaces 300A2, 300B2 of the housings 300A, 300B generally face away from the external or outer surface of the access closure 252A, and the access closure handle components 218D1, 218D2 are positioned relative to the respective front and rear access closures 252A, 252B such that, with both access closures 252A, 252B closed, the rearward surface 300A4 of the housing 300A and the forward surface 300B4 of the housing 300B face one another as illustrated by example in FIG. 17B. In some embodiments, the rearward surface 300A4 and the forward surface 300B4 abut one another with the access closures 252A, 252B closed, although in other embodiments the rearward surface 300A4 and the forward surface 300B4 may be spaced apart from one another when the access closures 252A, 252B are closed. In any case, with the access closures 252A, 252B closed as illustrated by example in FIG. 17B, the housings 300A, 300B together define a gap 302 between rear surfaces 300A5, 300B5 of the housings 300A, 300B and the external surfaces of the access closures 252A, 252B respectively, wherein a forward portion of the gap 302 is defined between the rear surface 300A5 of the housing 300A and the external surface of the access closure 252A, and a rearward portion of the gap 302 is defined between the rear surface 300B5 of the housing 300B and the external surface of the access closure 252B. The gap 302, and each of the forward and rearward portions of the gap 302, is/are illustratively sized to allow a human hand or portion thereof to pass between the rear surfaces 300A5, 300B5 and the external surfaces of the respective access closures 252A, 252B.

In some embodiments in which one or more of the sensors 210 is/are mounted to the access closure handle 218D, any such sensor(s) 210 may be mounted to or within either or both of the access closure handle components 218D1, 218D2 along one or any combination of the surfaces 300A1-300A3 and 300A5, 300B1-300B3 and 300B5 so as to be activated as described above. In the embodiment illustrated in FIG. 17B, for example, at least one such sensor 210 is shown mounted within the access closure handle component 218D1 along the front surface 300A2 of the housing 300A and at least one such sensor 210 is shown mounted within the access closure handle component 218D2 along the front surface 300B2 of the housing 300B. In other examples, at least one sensor 210 may be mounted within only one of the access closure handle components 218D1, 218D2. In some embodiments, one or more sensors 210 may alternatively or additionally be mounted to or within the access closure handle 218D1 along one or more other surfaces of the housing 300A and/or mounted to or within the access closure handle component 218D2 along one or more other surfaces of the housing 300B. In embodiments in which one or more of the sensors 210 is/are alternatively or additionally mounted to the motor vehicle 250D, any such sensor(s) 210 may be mounted to or within any one or more of the components 220 of the motor vehicle as depicted by example in FIG. 15, although it will be understood that one or more sensors 210 may be alternatively or additionally mounted to one or more other components of the motor vehicle 250D that is/are not depicted in FIG. 15, as described above.

Referring now to FIG. 17C, another example motor vehicle 250E is shown with another embodiment of an access closure handle 218E mounted to the front and rear access closures 252A, 252B. The motor vehicle 250E is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15. In the embodiment illustrated in FIG. 17C, the access closure handle 218E includes a front access closure handle component 218E1 mounted to the front access closure 252A and a rear access closure handle component 218E2 mounted to the rear access closure 252B. In this embodiment, the front access closure handle component 218E1 is rigidly affixed to the front access closure 252A such that the front access closure handle component 218E1 does not move or articulate relative to the front access closure 252A, and the rear access closure handle component 218E2 is likewise rigidly affixed to the rear access closure 252B such that the rear access closure handle component 218E2 does not move or articulate relative to the rear access closure 252B. In the embodiment illustrated in FIG. 17C, neither access closure handle 218E1, 218E2 is coupled via a respective mechanical linkage L3 to a respective closure latch 102 associated with the respective access closure 252A, 252B. Rather, in this embodiment, signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202. Signal processing circuit(s) 212 is/are likewise electrically coupled to another E-latch module 202 associated with the access closure 252B, and signals produced by one or more of the sensor(s) 210 are used by such signal processing circuit(s) 212 to control unlatching of the closure latch 102 of the access closure 252B via control of the respective E-latch module 202. In some embodiments separate signal processing circuit(s) 212 may be used; one for each access closure 252A, 252B, although in alternate embodiments the two E-latch modules 202 may share one signal processing circuit(s) 212. In some embodiments which include such E-latch modules 202, the access closure handle 218E1 and/or the access closure handle 218E2 may also be mechanically coupled via a respective mechanical linkage L3 to a closure latch 102 of a respective one of the access closures 252A, 252B, or separate “emergency” handles may be coupled via mechanical linkages L3 to respective ones of the closure latches 102, any of which and may be configured to move or articulate relative to the respective access closure 252A, 252B to provide for a mechanical failsafe mechanism for unlatching the respective access closure 252A, 252B in the event of a failure of the electrical system illustrated by example in FIG. 14.

In the illustrated embodiment, the front access closure handle component 218E1 includes a housing 310A having a top surface 310A1, a bottom surface 310A3 opposite the top surface 310A1, a front surface 310A2, a rear surface 310A5 opposite the front surface 310A2, and a rearward surface 310A4, wherein the front surface 310A2 and the rear surface 310A5 are each bounded on top and bottom by respective ones of the top surface 310A1, 310A3 and at one end by the rearward surface 310A4, and the rearward surface 310A4 is similarly bounded by the top, bottom, front and rear surfaces 310A1, 310A3, 310A2 and 310A5 respectively. The housing 310A is generally arcuate shaped and is attached to the access closure 252A at front and rear ends of the housing 310A so as to define a gap 312A between the rear surface 310A5 of the housing 310A and the external surface of the access closure 252A. The gap 312A is illustratively sized to allow a human hand or portion thereof to pass between the rear surface 310A5 and the external surface of the access closure 252A.

The rear access closure handle component 218E2 likewise includes a housing 310B having a top surface 310B1, a bottom surface 310B3 opposite the top surface 310B1, a front surface 310B2, a rear surface 310B5 opposite the front surface 310B2, and a forward surface 310B4, wherein the front surface 310B2 and the rear surface 310B5 are each bounded on top and bottom by respective ones of the top surface 310B1, 310B3 and at one end by the rearward surface 310B4, and the forward surface 310B4 is similarly bounded by the top, bottom, front and rear surfaces 310B1, 310B3, 310B2 and 310B5 respectively. The front surfaces 310A2, 310B2 of the housings 310A, 310B generally face away from the external or outer surface of the access closure 252A. The housing 310B, like the housing 310A, is generally arcuate shaped and is attached to the access closure 252B at front and rear ends of the housing 310B so as to define a gap 312B between the rear surface 310B5 of the housing 310B and the external surface of the access closure 252B. The gap 312B is illustratively sized to allow a human hand or portion thereof to pass between the rear surface 310B5 and the external surface of the access closure 252B.

The rearward surface 310A4 is illustratively position rearward of the rear attachment of the access closure handle component 218E1 to the access closure 252A, and the forward surface 310B4 is illustratively position forward of the front attachment of the access closure handle component 218E2 to the access closure 252B. The access closure handle components 218E1, 218E2 are positioned relative to the respective front and rear access closures 252A, 252B such that, with both access closures 252A, 252B closed, the rearward surface 310A4 of the housing 310A and the forward surface 310B4 of the housing 310B face one another as illustrated by example in FIG. 17C. In some embodiments, the rearward surface 310A4 and the forward surface 310B4 abut one another with the access closures 252A, 252B closed, although in other embodiments the rearward surface 310A4 and the forward surface 310B4 may be spaced apart from one another when the access closures 252A, 252B are closed.

In some embodiments in which one or more of the sensors 210 is/are mounted to the access closure handle 218E, any such sensor(s) 210 may be mounted to or within either or both of the access closure handle components 218E1, 218E2 along one or any combination of the surfaces 310A1-310A3 and 310A5, 310B1-310B3 and 310B5 so as to be activated as described above. In the embodiment illustrated in FIG. 17C, for example, at least one such sensor 210 is shown mounted within the access closure handle component 218E1 along the forwardly-facing portion of the front surface 310A2 of the housing 310A and at least one such sensor 210 is shown mounted within the access closure handle component 218E2 along the a rearwardly-facing portion of the front surface 310B2 of the housing 310B. In other examples, at least one sensor 210 may be mounted within only one of the access closure handle components 218E1, 218E2. In some embodiments, one or more sensors 210 may alternatively or additionally be mounted to or within the access closure handle 218E1 along one or more other surfaces of the housing 310A and/or mounted to or within the access closure handle component 218E2 along one or more other surfaces of the housing 310B. In embodiments in which one or more of the sensors 210 is/are alternatively or additionally mounted to the motor vehicle 250E, any such sensor(s) 210 may be mounted to or within any one or more of the components 220 of the motor vehicle as depicted by example in FIG. 15, although it will be understood that one or more sensors 210 may be alternatively or additionally mounted to one or more other components of the motor vehicle 250E that is/are not depicted in FIG. 15, as described above.

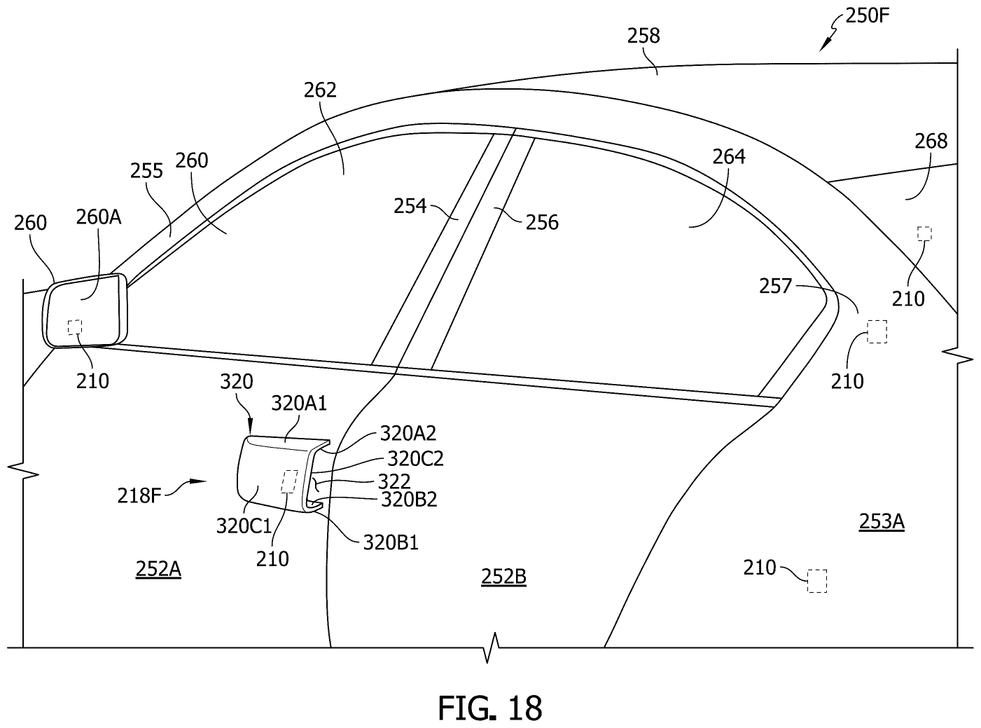

Referring now to FIG. 18, another example motor vehicle 250F is shown with another embodiment of an access closure handle 218F shown mounted to the front access closure 252A. The motor vehicle 250F is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15. In addition to, or alternatively to, the example mounting locations of the sensor(s) 210 illustrated by example, one or more sensors 210 may illustratively be mounted to or within any of a mirror 260A of the side-view mirror 260, a C-pillar 257 of the motor vehicle 250F, a rear side panel or so-called quarter panel 253A of the motor vehicle 250F, and/or a rear window 268 of the motor vehicle 250F, e.g., on, behind and/or integrated into one or more surfaces of an external skin of any such component, and/or on, behind and/or integrated into the mirror 260A and/or rear window 268, as depicted by example in FIG. 18. In the embodiment illustrated in FIG. 18, the access closure handle 218B is rigidly affixed to the front access closure 252A such that the access closure handle 218F does not move or articulate relative to the front access closure 252A. In this embodiment, the access closure handle 218F is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218F may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14.

In the illustrated embodiment, the access closure handle 218F is illustratively provided in the form of a side pocket handle including a housing 320 having an upwardly-facing outer top surface 320A1 and an opposite, downwardly-facing inner top surface 320A2, a downwardly-facing outer bottom surface 320B1 and an opposite upwardly-facing inner bottom surface 320B2, and an outwardly-facing front surface 320C1 and an opposite, inwardly-facing front surface 320C2, wherein the front surfaces 320C1, 320C2 join the top and bottom surfaces 320A1, 320A2 and 320B1, 320B2 respectively. The access closure handle 218F is mounted to the access closure 252A along inwardly-facing edges of the top and bottom surfaces 320A1, 320A2 and 320B1, 320B2 respectively, and along a front edge of the front surfaces 320C1, 320C2. The housing 320 is open along an opposite rear end of the surfaces 320A1-320C2 and forms a rearwardly-facing pocket 322 between the inwardly-facing surfaces 320A2, 320B2, 320C2 and the exterior surface of the access closure 252A. In alternate embodiments, the pocket 322 may be forwardly-facing. In any case, the pocket 322 is illustratively sized to allow a human hand or portion thereof to pass between the inwardly-facing surfaces 320A2, 320B2, 320C2 of the housing 320 and the external surface of the access closure 252A.

In some embodiments in which one or more of the sensors 210 is/are mounted to the access closure handle 218F, any such sensor(s) 210 may be mounted to or within the access closure handle 218F along one or any combination of the surfaces 320A1-320C1 and/or to or within a portion of the exterior surface of the access closure 252A forming part of the pocket 322, so as to be activated as described above. In the embodiment illustrated in FIG. 18, for example, at least one such sensor 210 is shown mounted within the access closure handle 218F along the outwardly-facing front surface 320C1 of the housing 320. In some embodiments, one or more sensors 210 may alternatively or additionally be mounted to or within the access closure handle 218F along one or more other surfaces of the housing 280F. In embodiments in which one or more of the sensors 210 is/are alternatively or additionally mounted to the motor vehicle 250F, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250F that is/are not depicted in FIG. 15 or in FIG. 18, as described above.

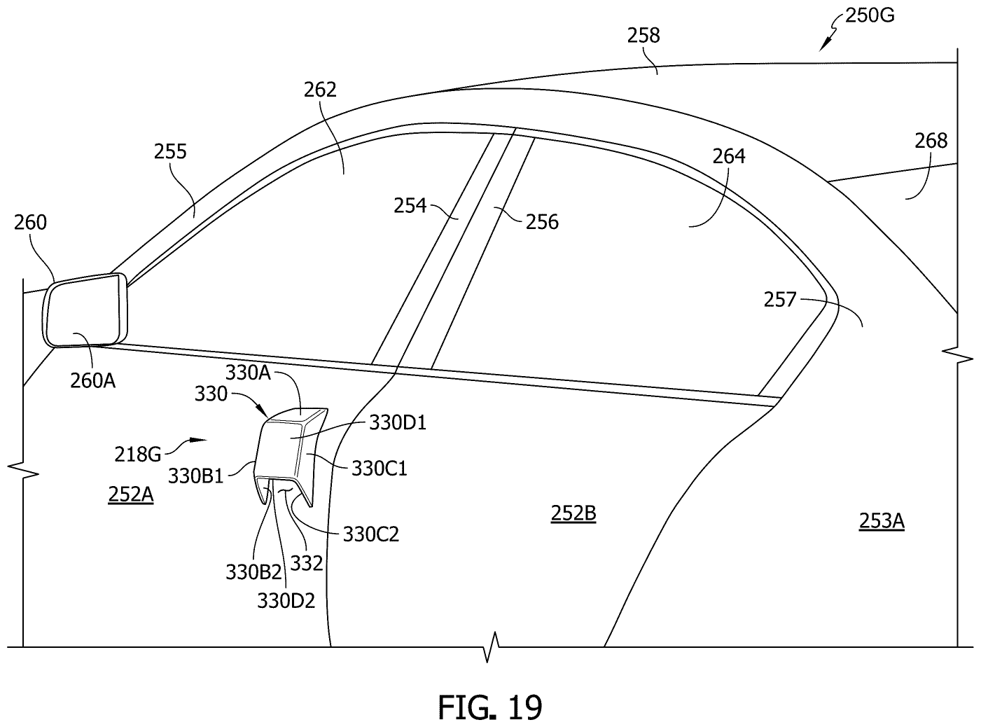

Referring now to FIG. 19, another example motor vehicle 250G is shown with another embodiment of an access closure handle 218G shown mounted to the front access closure 252A. The motor vehicle 250G is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the embodiment illustrated in FIG. 19, the access closure handle 218G is rigidly affixed to the front access closure 252A such that the access closure handle 218G does not move or articulate relative to the front access closure 252A. In this embodiment, the access closure handle 218G is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218G may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14

In the illustrated embodiment, the access closure handle 218G is illustratively provided in the form of a bottom pocket handle including a housing 330 having an upwardly-facing outer top surface 330A and an opposite, downwardly-facing inner top surface (not shown in FIG. 19), a forward outer side surface 330B1 and an opposite, inwardly-facing forward inner side surface 330B2, a rearward outer side surface 330C1 and an opposite, inwardly-facing rearward inner side surface 330C2, and an outwardly-facing front surface 330D1 and an opposite, inwardly-facing front surface 330D2, wherein the front surfaces 330D1, 330D2 join the top and side surfaces 330A, 330B1, 330B2 and 330C1, 330C2 respectively. The access closure handle 218G is mounted to the access closure 252A along inwardly-facing edges of the top and side surfaces 330A, 330B1, 330B2 and 330C1, 330C2 respectively, the housing 330 is open along a bottom end of the surfaces 330B1-330D2 to form a pocket 332 between the inwardly-facing surfaces 330B2, 330C2, 330D2 and the exterior surface of the access closure 252A. The pocket 332 is illustratively sized to allow a human hand or portion thereof to pass between the inwardly-facing surfaces 330B2, 330C2, 330D2 of the housing 330 and the external surface of the access closure 252A.

In some embodiments in which one or more of the sensors 210 is/are mounted to the access closure handle 218G, any such sensor(s) 210 may be mounted to or within the access closure handle 218G along one or any combination of the surfaces 330A, 330B1-320D2 and/or to or within a portion of the exterior surface of the access closure 252A forming part of the pocket 332, so as to be activated as described above. In the embodiment illustrated in FIG. 19, for example, at least one such sensor 210 is shown mounted within the access closure handle 218G along the outwardly-facing front surface 330D1 of the housing 330. In some embodiments, one or more sensors 210 may alternatively or additionally be mounted to or within the access closure handle 218G along one or more other surfaces of the housing 280G. In embodiments in which one or more of the sensors 210 is/are alternatively or additionally mounted to the motor vehicle 250G, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250G that is/are not depicted in FIG. 15 or in FIG. 18, as described above.

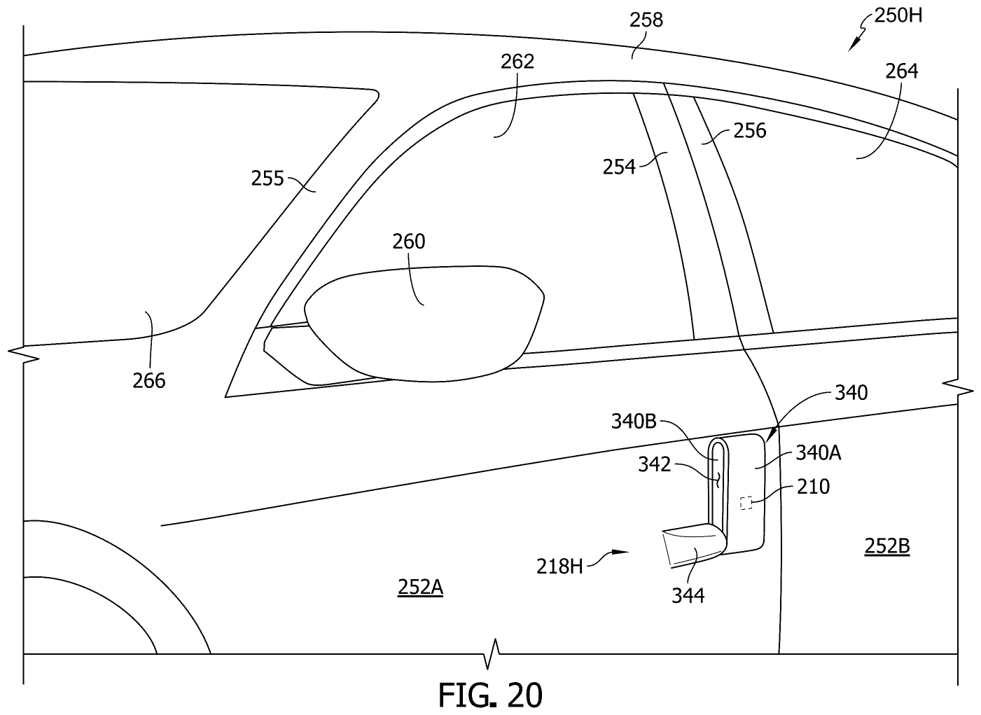

Referring now to FIG. 20, another example motor vehicle 250H is shown with another embodiment of an access closure handle 218H shown mounted to the front access closure 252A. The motor vehicle 250H is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In one embodiment, the access closure handle 218H is rigidly mounted via a handle mount 344 to the front access closure 252A such that the access closure handle 218H does not move or articulate relative to the access closure 252A, and in this embodiment the access closure handle 218H is not coupled via a mechanical linkage L3 to a closure latch 102 of the access closure 252A. In alternate embodiments, the access closure handle 218H may be rigidly mounted directly to the access closure 252A without the use of a handle mount 344. In any case, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218H may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14. In some alternate embodiments, the handle mount 344 may be or include a pivot mechanism coupled via a mechanical linkage L3 to a respective closure latch 102 of the access closure 252A (see FIG. 14), and in such embodiments the access closure handle 218H may be pivotably attached to the pivot mount 344 such that the access closure handle 218H is configured, in a conventional manner, to manually actuate the latch 102 and to manually open/close the access closure 252A as described above with respect to the embodiment depicted in FIG. 15.

In the illustrated embodiment, the access closure handle 218H is illustratively provided in the form of another side pocket handle including a housing 340, illustratively of uniform construction, having an outer surface 340A and an opposite inner surface 340B with a forwardly-facing pocket 342 defined into the housing 340. In alternate embodiments, the pocket 342 may be rearwardly-facing or downwardly-facing. In alternate embodiments, the housing 340 may be non-unitary, and may include two or more housing components affixed together in a conventional manner. In any case, the pocket 342 is illustratively sized to allow a human hand or portion thereof to pass into the pocket 342.

In some embodiments in which one or more of the sensors 210 is/are mounted to the access closure handle 218H, any such sensor(s) 210 may be mounted to or within the access closure handle 218H along a portion of the outer surface 340A of the housing 340, as illustrated by example in FIG. 20, although in alternate embodiments one or more sensors 210 may alternatively or additionally be mounted along any portion of the outer surface 340A and/or the inner surface 340B of the housing 340, and/or on or within the pivot mount 344 in embodiments which include it. In embodiments in which one or more of the sensors 210 is/are alternatively or additionally mounted to the motor vehicle 250H, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250H that is/are not depicted in FIG. 15 or in FIG. 18, as described above.

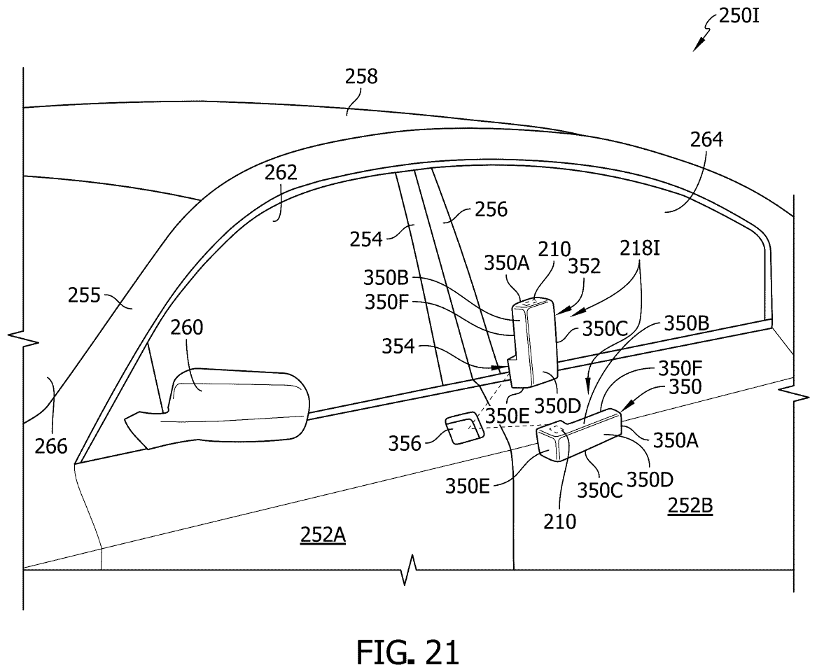

Referring now to FIG. 21, another example motor vehicle 250I is shown with another embodiment of an access closure handle 218I shown mounted to the front access closure 252A. The motor vehicle 250I is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the illustrated embodiment, the access closure handle 218I and the access panel 252A of the motor vehicle 250I are together configured such that the access closure handle 218I may be mounted to the front access closure 252A in any of multiple different orientations of the handle 218I relative to the access closure 252A. In one embodiment, the access closure handle 218I is rigidly mounted to the front access closure 252A but is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218I may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14. In some alternate embodiments, the access closure handle 218I may be coupled via a mechanical linkage L3 to a respective closure latch 102 of the access closure 252A (see FIG. 14), and in such embodiments the access closure handle 218I may be pivotably attached to the access closure 252A such that the access closure handle 218I is configured, in a conventional manner, to manually actuate the latch 102 and to manually open/close the access closure 252A.

In the embodiment illustrated in FIG. 21, the access closure handle 218I includes a housing 350, and is shaped to have a gripping portion 352 and a mounting portion 354. The housing 350 illustratively has opposing end surfaces 350A, 350E, opposing side surfaces 350B, 350C, and front and opposing rear surfaces 350D, 350F bounded by three or more of the end and side surfaces 350A-350C and 350E. The end surfaces 350A, 350E are illustratively square or rectangular in shape, the front and rear surfaces 350D, 350E are illustratively rectangular in shape, and the side surfaces 350B, 350C are illustratively L-shaped, although in alternate embodiments any one or more of the surfaces 350A-350F may be non-square or non-rectangular.

In the illustrated embodiment, the mounting portion 354 of the access closure handle 218I extends away from the gripping portion 352 at an angle of approximately 90 degrees, although in alternate embodiments the access closure handle 218I may be configured such that the mounting portion 354 extends away from the gripping portion 352 at an angle of less than 90 degrees, at an angle of greater than 90 degrees, or at no angle (e.g., zero degrees). In any case, the access closure 252A of the motor vehicle 250I defines an access closure receiving pocket 356, wherein the mounting portion 354 of the access closure handle 218I and the access closure receiving pocket 356 are together shaped configured complementarily to one another such that the mounting portion 354 of the access closure handle 218I may be mounted to and within the access closure receiving pocket 356 at any of four different orientations of the access closure handle 218I.

As illustrated in FIG. 21, for example, the mounting portion 354 may be mounted to and within the access closure receiving pocket 356 such that the surfaces 350B, 350C define respective top and bottom surfaces of the handle 218I, and the surfaces 350E, 350A define respective forwardly-facing and rearwardly-facing surfaces of the handle 218I. Alternatively, the mounting portion 354 may be mounted such that the surfaces 350E, 350A define respective rearwardly-facing and forwardly-facing surfaces of the handle 218I. As also illustrated by example in FIG. 21, the mounting portion 354 may be mounted to and within the access closure receiving pocket 356 such that the surfaces 350A, 350E define respective and bottom surfaces of the handle 218I, and the surfaces 350B, 350C define respective forwardly-facing and rearwardly-facing surfaces of the handle 218I. Alternatively, the mounting portion 354 may be mounted such that the surfaces 350B, 350C define respective rearwardly-facing and forwardly-facing surfaces of the handle 218I. In any case, the surface 350D illustratively of the handle 218I will generally face away from the exterior surface of the access closure 252A, and the surface 350F will generally face the exterior surface of the access closure 252A so as to form a gap therebetween sized to allow a human hand or portion thereof to pass between the surface 350F and the external surface of the access closure 252A.

In some embodiments in which one or more of the sensors 210 is/are mounted to the access closure handle 218I, any such sensor(s) 210 may be mounted to or within the access closure handle 218I along a portion of the surface 350A and/or along a portion of the surface 350B of the housing 350, as illustrated by example in FIG. 21, although in alternate embodiments one or more sensors 210 may alternatively or additionally be mounted along any portion of any of the surfaces 350A-350F of the housing 350. In embodiments in which one or more of the sensors 210 is/are alternatively or additionally mounted to the motor vehicle 250I, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250I that is/are not depicted in FIG. 15 or in FIG. 18, as described above.

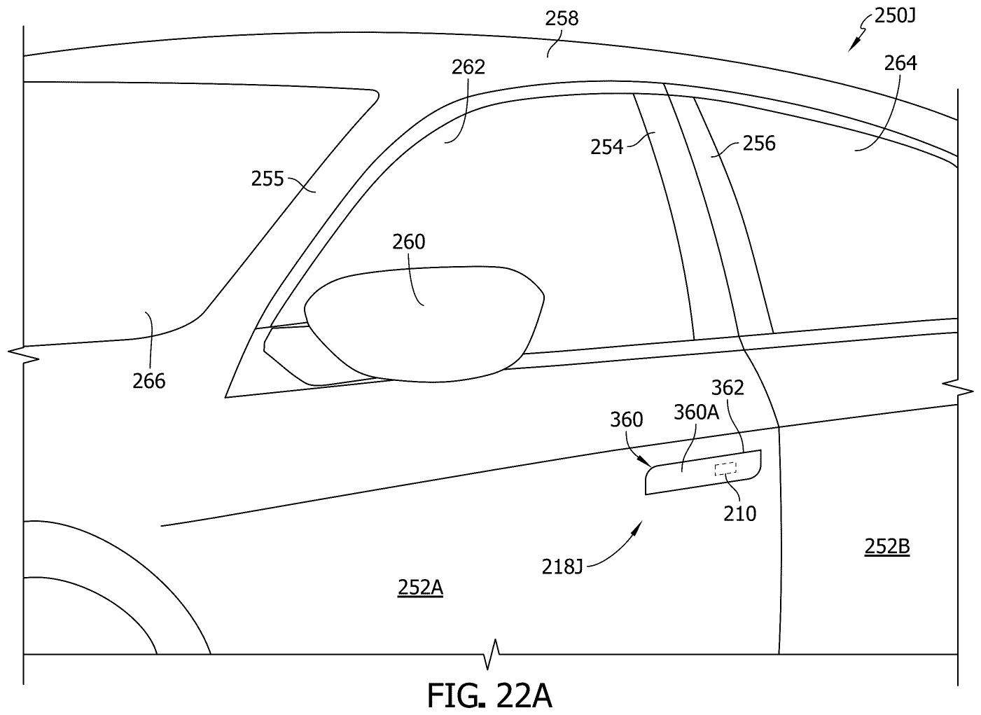

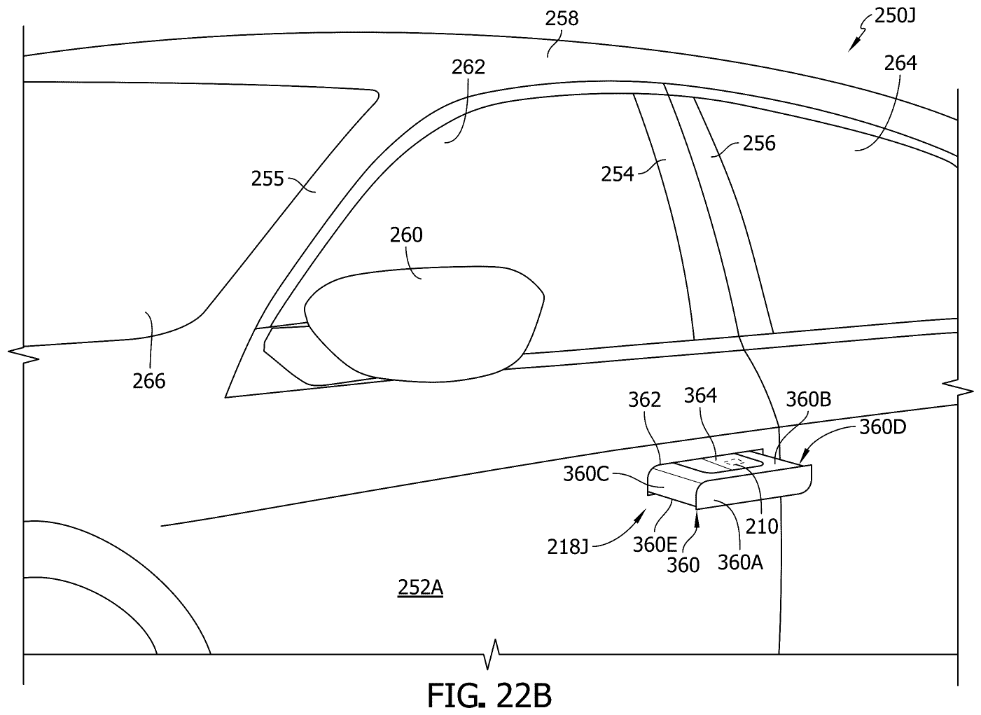

Referring now to FIGS. 22A and 22B, another example motor vehicle 250J is shown with another embodiment of an access closure handle 218J shown mounted to the front access closure 252A. The motor vehicle 250J is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the embodiment illustrated in FIGS. 22A and 22B, the access closure handle 218J is mounted to the front access closure 252A but is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218J may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14.

In the embodiment illustrated in FIGS. 22A and 22B, the access closure handle 218J includes a movable housing 360 received within an access closure handle receiving pocket 362 defined in the access closure 252A. In this embodiment, the housing 360 is configured to move, e.g., linearly (or not non-linearly) extend, from a closed position in which a front surface 360A of the housing 360 is flush, or substantially flush, with an adjacent exterior surface of the access closure 252A surrounding the pocket 362, as depicted by example in FIG. 22A, to an open position in which the housing 360 is extended outwardly away from the pocket 362 so as to expose a grip pocket 364 defined in a top surface 360B of the housing 360, as depicted by example in FIG. 22B. The grip pocket 364 is illustratively sized to receive one or more fingers therein to provide for gripping of the housing 360 by an operator or occupant of the motor vehicle 250J to allow for opening of the access closure 252A. In the illustrated embodiment, the housing 360 is generally rectangular with a bottom surface 360E opposite the top surface 360B and with opposite side surfaces 360C, 360D bounded by the top and bottom surfaces 360B, 360E. In some embodiments, the housing 360 is motor driven between the closed and open positions, although in alternate embodiments the housing 360 may be latched closed and biased to the open position, wherein one or more latches may be electrically controlled to release and such that one or more biasing members may then force the released housing 360 to the open position illustrated by example in FIG. 22B. In some such embodiments, the housing 360 may be configured to be manually closed by manually forcing the housing 360 from the open to the closed position.

In some embodiments in which one or more of the sensors 210 is/are mounted to the access closure handle 218J, any such sensor(s) 210 may be mounted to or within the access closure handle 218J along a portion of the front surface 360A of the housing 360 as illustrated by example in FIG. 22A. In some embodiments, signals produced by at least one of the one or more sensors 210 mounted along a portion of the front surface 360A of the housing 360 may be used not to control an operating state of the access closure 252A as described herein, but instead merely to cause the housing 360 to be controlled from the closed depicted in FIG. 22A to the open position depicted in FIG. 22B. In some embodiments, one or more sensors 210 may additionally be mounted and/or along a portion of the top surface 360B of the housing 360, such as within the pocket 364, as illustrated by example in FIG. 22B, although in alternate embodiments one or more sensors 210 may alternatively or additionally be mounted along any portion of any of the surfaces 360A-360E of the housing 360. In embodiments in which one or more of the sensors 210 is/are alternatively or additionally mounted to the motor vehicle 250J, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250J that is/are not depicted in FIG. 15 or in FIG. 18, as described above.

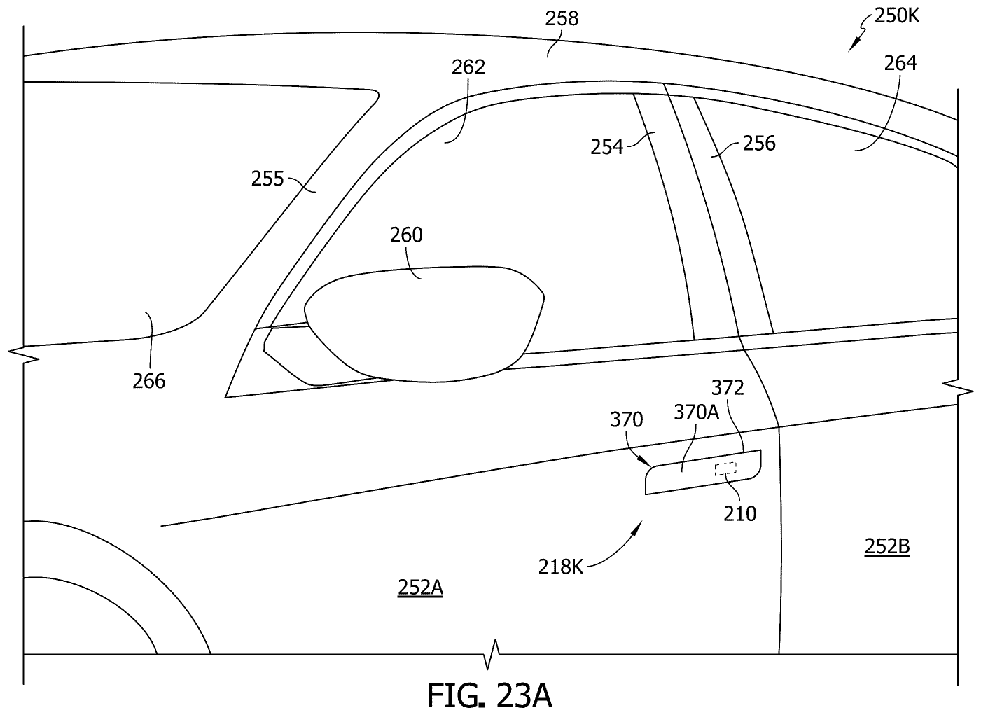

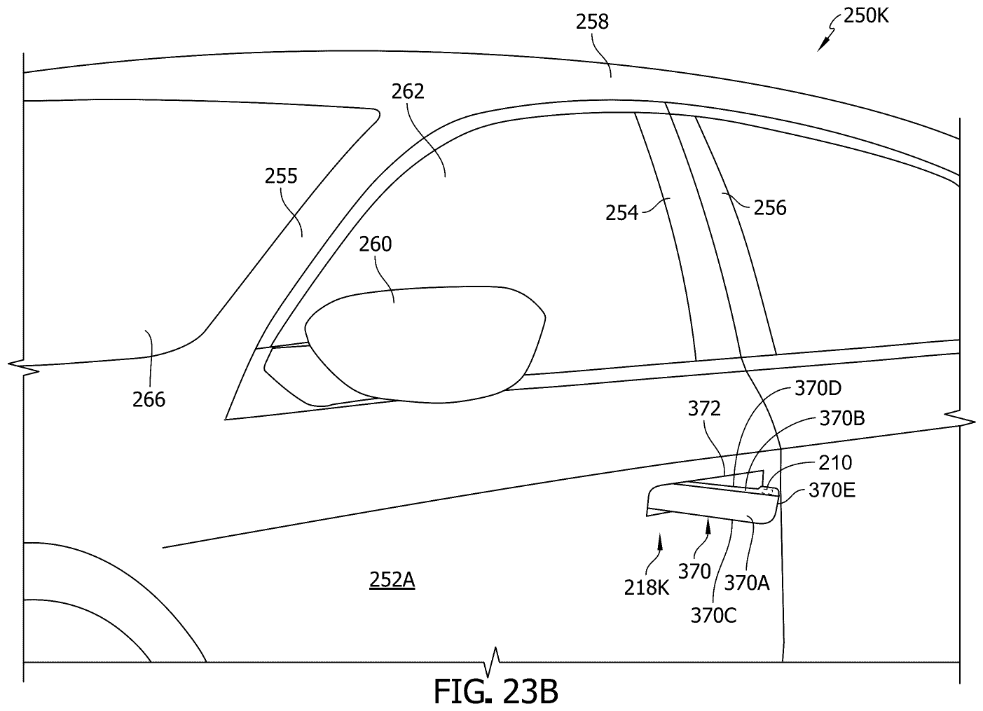

Referring now to FIGS. 23A and 23B, another example motor vehicle 250K is shown with another embodiment of an access closure handle 218K shown mounted to the front access closure 252A. The motor vehicle 250K is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the embodiment illustrated in FIGS. 23A and 23B, the access closure handle 218K is mounted to the front access closure 252A but is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218K may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14.

In the embodiment illustrated in FIGS. 23A and 23B, the access closure handle 218K includes a movable housing 370 received within an access closure handle receiving pocket 372 defined in the access closure 252A. In this embodiment, the housing 370 is configured to move, e.g., pivot, between a closed position in which a front surface 370A of the housing 370 is flush, or substantially flush, with an adjacent exterior surface of the access closure 252A surrounding the pocket 372, as depicted by example in FIG. 23A, and an open position in which one end of the housing 370 extends, e.g., is pivoted, outwardly away from the pocket 372 such that the housing forms a hand grip as depicted by example in FIG. 23B. The housing 370 is illustratively sized such that, when pivoted to the open position depicted in FIG. 23B, the housing 370 may be gripped by a hand or one or more fingers to allow for opening of the access closure 252A. In the illustrated embodiment, the housing 370 is generally rectangular with a back surface 370B opposite the front surface 370A, with opposed bottom and top surfaces 370C, 370D respectively and with an end surface 370E bounded by the front, rear, bottom and top surfaces 370A-370D. In some embodiments, the housing 370 may be motor driven between the closed and open positions, although in alternate embodiments the housing 370 may be latched closed and biased to the open position, wherein one or more latches may be electrically controlled to release such and such that one or more biasing members force the released housing 370 to the open position illustrated by example in FIG. 23B. In some such embodiments, the housing 370 may be configured to be manually closed by manually forcing the housing 370 from the open to the closed position.

In some embodiments in which one or more of the sensors 210 is/are mounted to the access closure handle 218K, any such sensor(s) 210 may be mounted to or within the access closure handle 218K along a portion of the front surface 370A of the housing 370 as illustrated by example in FIG. 23A. In some embodiments, signals produced by at least one of the one or more sensors 210 mounted along a portion of the front surface 370A of the housing 370 may be used not to control an operating state of the access closure 252A as described herein, but instead merely to cause the housing 370 to be controlled from the closed depicted in FIG. 23A to the open position depicted in FIG. 23B. In some embodiments, one or more sensors 210 may additionally be mounted and/or along a portion of the top surface 370B of the housing 370 as illustrated by example in FIG. 23B, although in alternate embodiments one or more sensors 210 may alternatively or additionally be mounted along any portion of any of the surfaces 370A-370E of the housing 370. In embodiments in which one or more of the sensors 210 is/are alternatively or additionally mounted to the motor vehicle 250K, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250K that is/are not depicted in FIG. 15 or in FIG. 18, as described above.

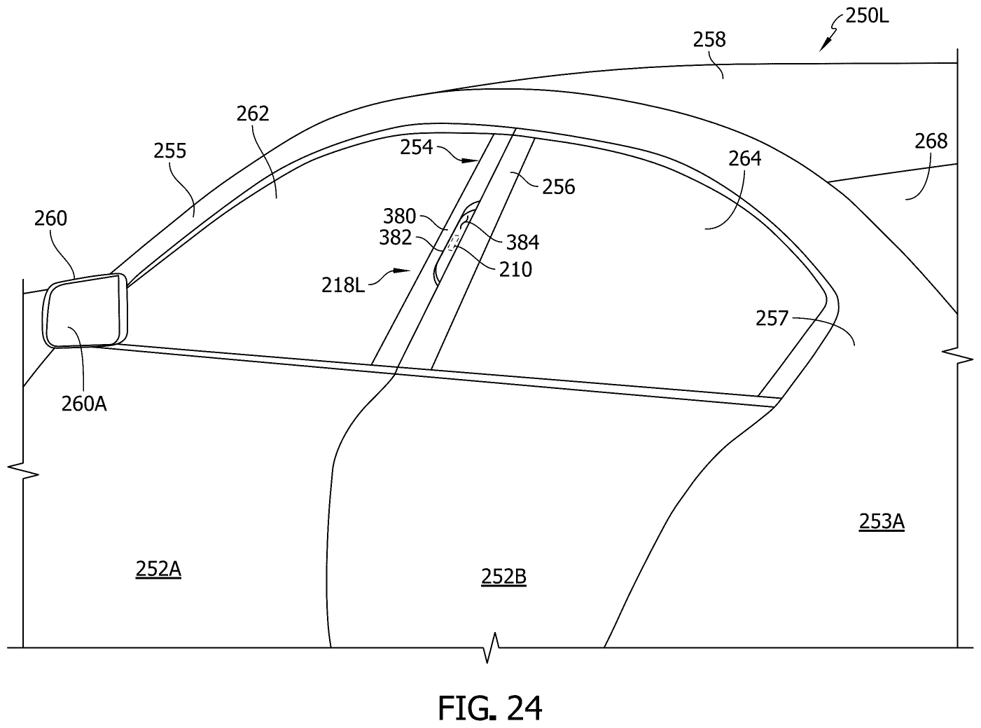

Referring now to FIG. 24, another example motor vehicle 250L is shown with another embodiment of an access closure handle 218L defined by the window frame 254 of the front access closure 252A. The motor vehicle 250L is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the embodiment illustrated in FIG. 24, the access closure handle 218L is defined by the window frame 254 of the front access closure 252A and is thereby rigidly attached to the access closure 252A generally. In this embodiment, the access closure handle 218L is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some embodiments which include such an E-latch module 202, the access closure handle 218L may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14.

In the illustrated embodiment, the access closure handle 218L is integrated into the window frame 254 in the form of a cutout 382 formed into a housing 380, e.g., formed into an exterior skin of the window frame 254 and, in some embodiments, into one or more other components of the window frame 254 including the window frame 254 itself. When the access door 252A is closed, the cutout 382 illustratively forms a pocket 384 adjacent to the B-pillar 256, which pocket 384 is sized to allow a human hand or portion thereof to pass therein to grip the cutout 382 to manually open the access closure 252A.

In some embodiments in which one or more of the sensors 210 is/are mounted to the access closure handle 218L, any such sensor(s) 210 may be mounted to or within the access closure handle 218L along any surface of the housing 380 and/or pocket 384 so as to be activated as described above. In the embodiment illustrated in FIG. 24, for example, at least one such sensor 210 is shown mounted within the access closure handle 218L along the exposed surface of the pocket 384. In some embodiments, one or more sensors 210 may alternatively or additionally be mounted to or within the access closure handle 218L along one or more non-exposed (e.g., hidden) surfaces of the cutout 382 and/or pocket 384. In embodiments in which one or more of the sensors 210 is/are alternatively or additionally mounted to the motor vehicle 250L, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250L that is/are not depicted in FIG. 15 or in FIG. 18, as described above.

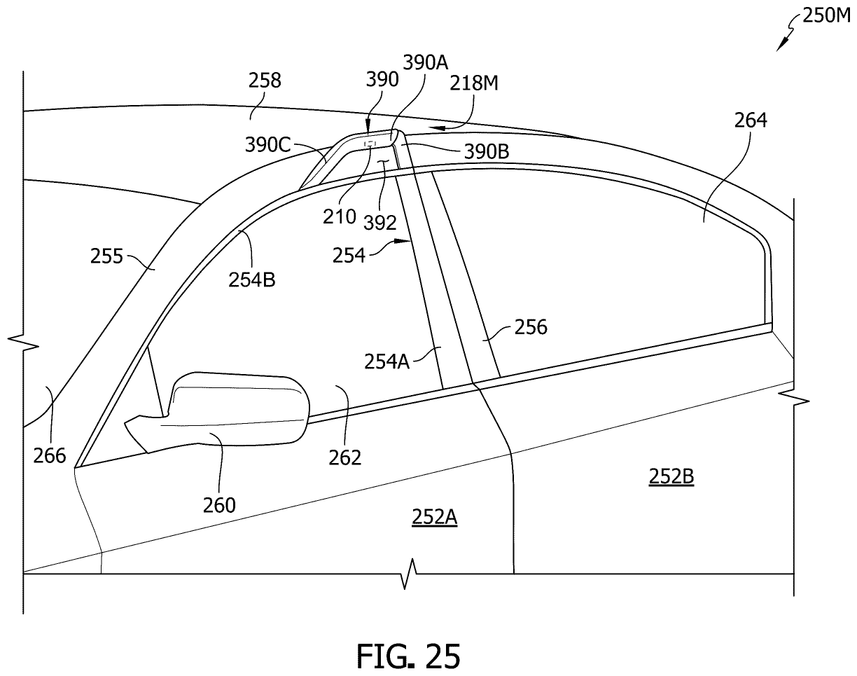

Referring now to FIG. 25, another example motor vehicle 250M is shown with another embodiment of an access closure handle 218M shown mounted to the front access closure 252A. The motor vehicle 250M is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the embodiment illustrated in FIG. 25, the window frame 254 is depicted as including a side frame component 254A adjacent to a side of the window 262, and a top frame component 254B adjacent to a top of the window 262, such that the top frame component 254B is positioned between the top of the window 262 and the roof 258 of the motor vehicle 250M when the access closure 252A is closed as depicted by example in FIG. 25. In this embodiment, the access closure handle 218M is rigidly attached to the top frame component 254B of the window frame 254, although in alternate embodiments the access closure handle 218M may be rigidly attached to the side frame component 254A. In any case, the access closure handle 218M is not coupled via a mechanical linkage L3 to a closure latch 102 of the access closure 252A. Rather, in this embodiment, the signal processing circuit(s) 212 is/are electrically coupled to an E-latch module 202 associated with the access closure 252A, and signals produced by one or more of the sensor(s) 210 are used by the signal processing circuit(s) 212 to control unlatching of the closure latch 102 of the access closure 252A via control of the respective E-latch module 202 as described above. In some alternate embodiments which include such an E-latch module 202, the access closure handle 218M may also be mechanically coupled via a mechanical linkage L3 to the closure latch 102, or a separate “emergency” handle may be coupled via the mechanical linkage L3 to the closure latch 102, either of which may be configured to move or articulate relative to the access closure 252A to provide for a mechanical failsafe mechanism for unlatching the closure latch 102 of the access closure 252A in the event of a failure of the electrical system illustrated by example in FIG. 14.

In the illustrated embodiment, the access closure handle 218M includes a housing 390 in the form of a grab handle having an elongated top component 390A and side components 390B, 390C coupled to opposite ends of the top component 390A, wherein free ends of the side components 390B, 390C are affixed to the top frame component 254B of the window frame 254. In some embodiments, the housing 390 may be supported internally by one or more conventional frame members. In some embodiments, the housing 390 may be of uniform construction, although in alternate embodiments the housing 390 may be provided in the form of two or more separate components attached together to form the housing 390. In the illustrated embodiment, the housing 390 is a closed circle or oval in transverse cross-section, although in alternate embodiments the transverse cross-section of the housing 390 may have any closed or open shape. In any case, a gap or channel 392 is defined between the housing components 390A-390C and the top frame component 254B of the window frame 254, and is illustratively sized to allow a human hand or portion thereof to grip at least a portion of one or more of the housing components 390A-390C for the purpose of opening and/or closing the access closure 252A.

In some embodiments in which one or more of the sensors 210 is/are mounted to the access closure handle 218M, any such sensor(s) 210 may be mounted to or within the access closure handle 218M along one or more surface(s) of any of the components 390A-390C of the housing 390 and/or on or within the portion of the top frame component 254A defining the gap or channel 392 so as to be activated as described above. In the embodiment illustrated in FIG. 25, for example, at least one such sensor 210 is shown mounted within the access closure handle 218M along a surface of the housing component 390A which faces generally opposite the exterior surface of the top frame component 254A. In some embodiments, one or more sensors 210 may alternatively or additionally be mounted to or within the access closure handle 218M along a surface of the housing component 390A which generally faces the exterior surface of the top frame component 254A and/or along one or more other surfaces of any of the housing components 390A-390C. In embodiments in which one or more of the sensors 210 is/are alternatively or additionally mounted to the motor vehicle 250M, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250M that is/are not depicted in FIG. 15 or in FIG. 18, as described above.

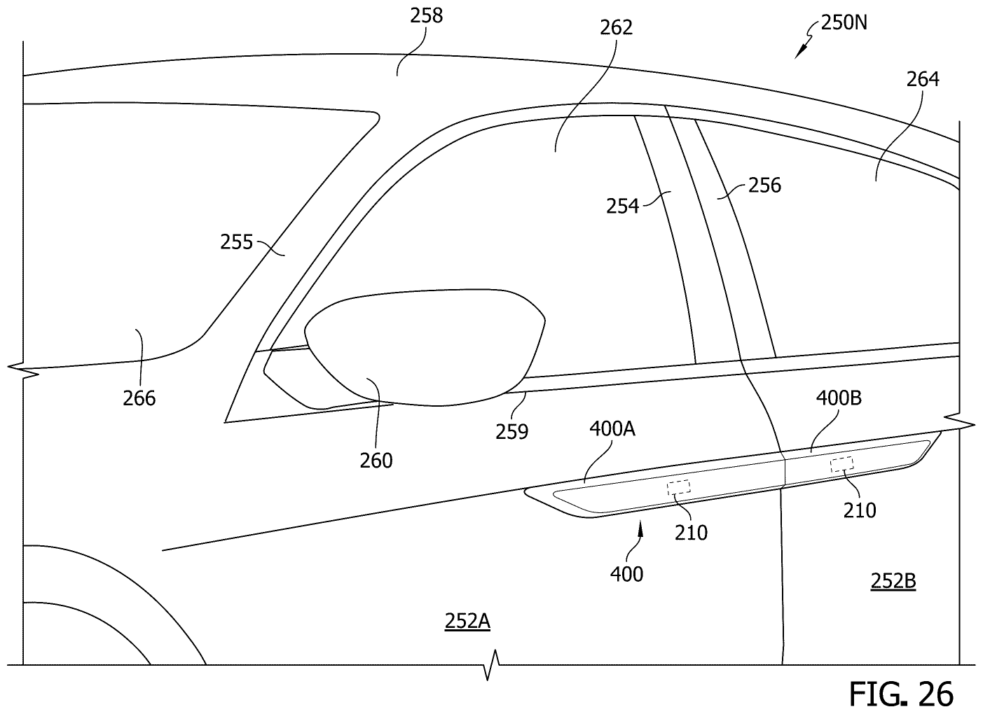

Referring now to FIG. 26, another example motor vehicle 250N is shown in which the motor vehicle access closure control system 200 illustrated in FIG. 14 includes the closure motor 206 and the motor driver 208, such that the signal processing circuit(s) 212 is/are operable to control the motor driver 208 to cause the closure motor 206, or other such drive mechanism, to open and close the access closure 252A. In some such embodiments, no access closure handle per se is mounted to the access closure 252A, and all locking/unlocking, unlatching, opening and closing of the access closure 252A is accomplished via control of the motor driver 208 and, in some embodiments, the actuator 102 and/or the E-latch module 102 in embodiments which include it/them, by the signal processing circuit(s) 212. It will be understood, however, that in some such embodiments an “emergency” closure handle may be mechanically coupled via a mechanical linkage L3 to the closure latch 102 of the access closure 252A, and such an “emergency” access closure handle may be configured to move or articulate relative to the access closure 252A to provide for a mechanical failsafe mechanism for unlatching the closure latch 102 of the access closure 252A in the event of a failure of one or more components of the system 200 illustrated by example in FIG. 14.

The motor vehicle 250N is otherwise as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In the embodiment illustrated by example in FIG. 26, the motor vehicle 250N further includes badge 400 affixed to both of the access closures 252A, 252B below a so-called beltline 259 defined by and substantially horizontally along an interface between the access closures 252A, 252B and respective side windows 262, 264. In the illustrated embodiment, the badge 400 includes a badge component 400A affixed to the exterior surface of the access closure 252A and a badge component 400B affixed to the exterior surface of the access closure 252B, wherein the badge components 400A, 400B are disposed adjacent to, and aligned with, one another, e.g., so as to be abutting or spaced apart from one another, to form the complete badge 400 when both of the access closures 252A, 252B are closed. As used herein, the term “badge” or “motor vehicle badge” shall be understood to mean an informational plate or assembly having a display surface bearing information of any type, without restriction, and a mounting surface, opposite the display surface, that is to be attached to an outer surface of one or more components 220 of the motor vehicle, e.g., to each of the access closures 252A, 252B in the example illustrated in FIG. 26, such that the display surface is exposed and faces generally away from the surface to which it is affixed. Examples of such motor vehicle badges may include, but are not limited to, one having a display surface bearing an emblem, e.g., in the form of a name, logo and/or other information relating to and/or characteristic, of the company which produced the motor vehicle to which the badge is to be attached, one having a display surface bearing information relating to a model, type or function/capability of the motor vehicle to which the badge is to be attached, e.g., “Mustang,” “Hybrid,” “4×4,” or the like, one having a display surface bearing other information relating to the owner and/or operator of the motor vehicle to which the badge is to be attached, e.g., “Sheriff,” Physician/Medical Doctor, Government Official, etc. or the like.

In some embodiments, the badge 400 may act as a surrogate to an access closure handle in that one or more sensors 210 may be mounted to or within the badge 400 and may be activated as described above to control an operational state of the access closure 252A. In the embodiment depicted in FIG. 26, for example, one or more sensors 210 is/are mounted to or within the badge component 400A and one or more other sensors 210 is/are mounted to or within the badge component 400B, although in alternate embodiments one or more sensors 210 may be mounted to or within only one of the badge components 400A, 400B. Although the sensor(s) 210 are depicted in FIG. 26 as being disposed along a portion of the outwardly-facing surface of the badge components 400A, 400B, it will be understood that the sensor(s) 210 may alternatively be disposed along any portion of any surface of the badge component 400A and/or of the badge component 400B. In any case, signals produced by the sensor(s) 210, upon activation thereof as described herein, may be used by the signal processing circuit(s) 212 to control one or more of locking/unlocking, unlatching and control, via the motor driver 208, of opening and/or closing of the access closure 252A. A non-limiting example of such one or more sensors 210 mounted to or within the badge 400 is disclosed in co-pending international patent application no. PCT/US2023/065275, published as WO 2023/196776, the disclosure of which is incorporated herein by reference in its entirety. In embodiments in which one or more of the sensors 210 is/are alternatively or additionally mounted to the motor vehicle 250N, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250M that is/are not depicted in FIG. 15 or in FIG. 18, as described above.

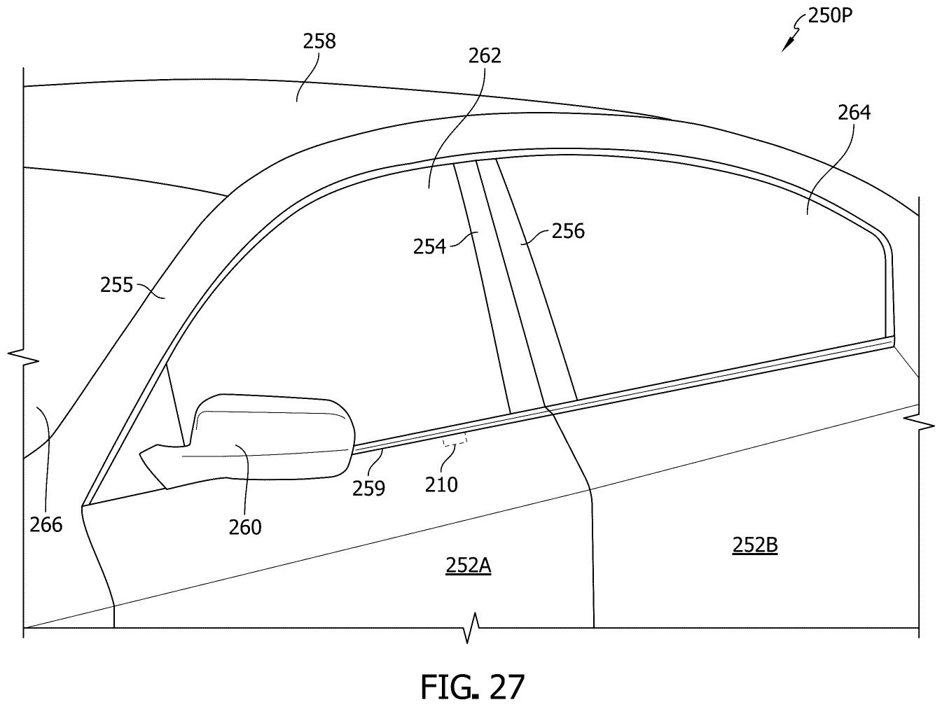

Referring now to FIG. 27, another example motor vehicle 250P is shown in which the motor vehicle access closure control system 200 illustrated in FIG. 14 includes the closure motor 206 and the motor driver 208, such that the signal processing circuit(s) 212 is/are operable to control the motor driver 208 to cause the closure motor 206, or other such drive mechanism, to open and close the access closure 252A. In some such embodiments, no access closure handle per se is mounted to the access closure 252A, and all locking/unlocking, unlatching, opening and closing of the access closure 252A is accomplished via control of the motor driver 208 and, in some embodiments, the actuator 102 and/or the E-latch module 102 in embodiments which include it/them, by the signal processing circuit(s) 212. It will be understood, however, that in some such embodiments an “emergency” closure handle may be mechanically coupled via a mechanical linkage L3 to the closure latch 102 of the access closure 252A, and such an “emergency” access closure handle may be configured to move or articulate relative to the access closure 252A to provide for a mechanical failsafe mechanism for unlatching the closure latch 102 of the access closure 252A in the event of a failure of one or more components of the system 200 illustrated by example in FIG. 14.

The motor vehicle 250P is illustratively as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In some embodiments, the beltline 259 may act as a surrogate to an access closure handle in that one or more sensors 210 may be mounted to or within the access closure 252A on or along the beltline 259 as depicted by example in FIG. 27, and may be activated as described above to control an operational state of the access closure 252A. Although the sensor(s) 210 are depicted in FIG. 27 as being disposed along a portion of the access closure 259 just below the beltline, it will be understood that the sensor(s) 210 may alternatively be disposed along any portion of any other portion of the access closure below, above or on the beltline 259. In any case, signals produced by the sensor(s) 210, upon activation thereof as described herein, may be used by the signal processing circuit(s) 212 to control one or more of locking/unlocking, unlatching and control, via the motor driver 208, of opening and/or closing of the access closure 252A. In embodiments in which one or more of the sensors 210 is/are alternatively or additionally mounted to the motor vehicle 250P, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250P that is/are not depicted in FIG. 15 or in FIG. 18, as described above.

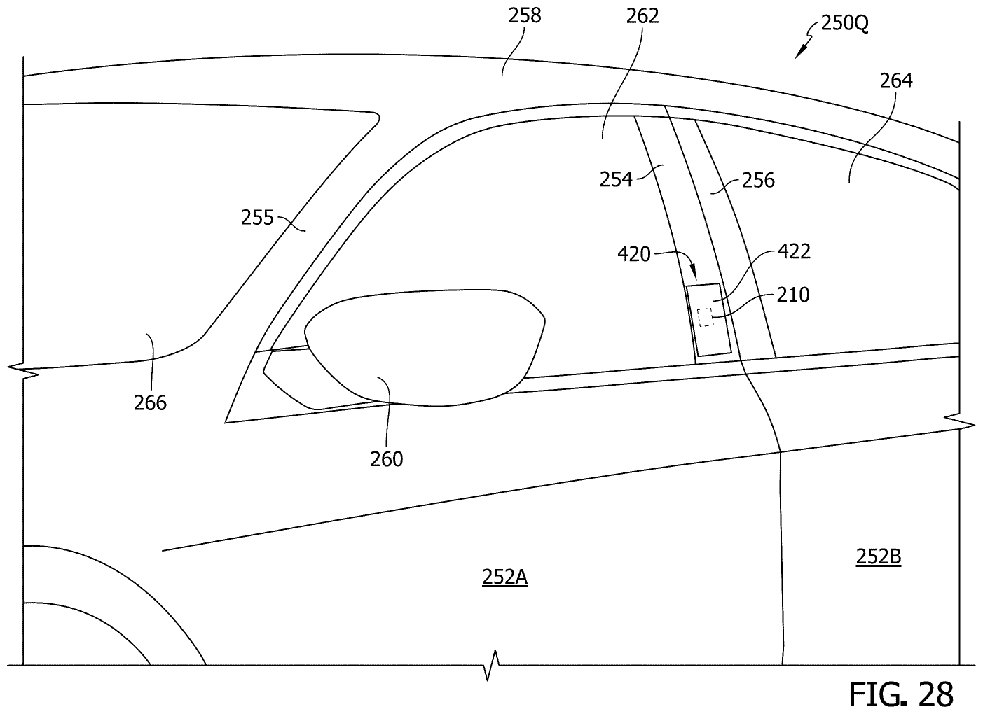

Referring now to FIG. 28, another example motor vehicle 250Q is shown in which the motor vehicle access closure control system 200 illustrated in FIG. 14 includes the closure motor 206 and the motor driver 208, such that the signal processing circuit(s) 212 is/are operable to control the motor driver 208 to cause the closure motor 206, or other such drive mechanism, to open and close the access closure 252A. In some such embodiments, no access closure handle per se is mounted to the access closure 252A, and all locking/unlocking, unlatching, opening and closing of the access closure 252A is accomplished via control of the motor driver 208 and, in some embodiments, the actuator 102 and/or the E-latch module 102 in embodiments which include it/them, by the signal processing circuit(s) 212. It will be understood, however, that in some such embodiments an “emergency” closure handle may be mechanically coupled via a mechanical linkage L3 to the closure latch 102 of the access closure 252A, and such an “emergency” access closure handle may be configured to move or articulate relative to the access closure 252A to provide for a mechanical failsafe mechanism for unlatching the closure latch 102 of the access closure 252A in the event of a failure of one or more components of the system 200 illustrated by example in FIG. 14.

The motor vehicle 250Q is illustratively as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In some embodiments, a display device, including at least one display screen, may be mounted to one or more of the components 220 of the motor vehicle 250Q, some non-limiting examples of which have just been described. In the embodiment illustrated in FIG. 28, for example, a display device 420, including a display screen 422, is shown mounted to the window frame 254, although in other embodiments a display device 420 may alternatively or additionally be mounted to the B-pillar 256 and/or to one or more other components 220. In some embodiments, the display screen 422 may be one of the accessories 232 controlled by the signal processing circuit(s) 212 and/or other control module(s) or circuit(s) 230, and may be used only for the purpose of communicating an operating status of the access closure 252A, e.g., locked, unlocked, latched, unlatched, open, closed, or an impending change in operating state, e.g., about to open, about to close, etc., although in other such embodiments the display screen 422 may be controlled to alternatively or additionally display other information about the motor vehicle 250Q or components 220 thereof and/or about an operator or passenger associated with a mobile communication device 222 detected by the signal processing circuit(s) 212 as described above.

In other embodiments, one or more sensors 210 may be mounted to or within the display device 420, as depicted by example in FIG. 28. In some such embodiments, the screen 422 may be a so-called “touch screen,” in which one or more sensors 210 mounted thereto, or mounted within the device 420 behind and along the screen 422, may be or include one or more touch sensors, some non-limiting examples of which are described above. In other embodiments, the one or more sensors 210 mounted to or within the display screen may alternatively or additionally be or include one or more proximity sensors or other sensors, some non-limiting examples of which are described above. In any such embodiment in which one or more sensors 210 is/are mounted to or within the display device 420, the display screen may additionally be controlled to display information as described in the previous paragraph. In embodiments in which one or more of the sensors 210 is/are alternatively or additionally mounted to the motor vehicle 250Q, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250Q that is/are not depicted in FIG. 15 or in FIG. 18, as described above.

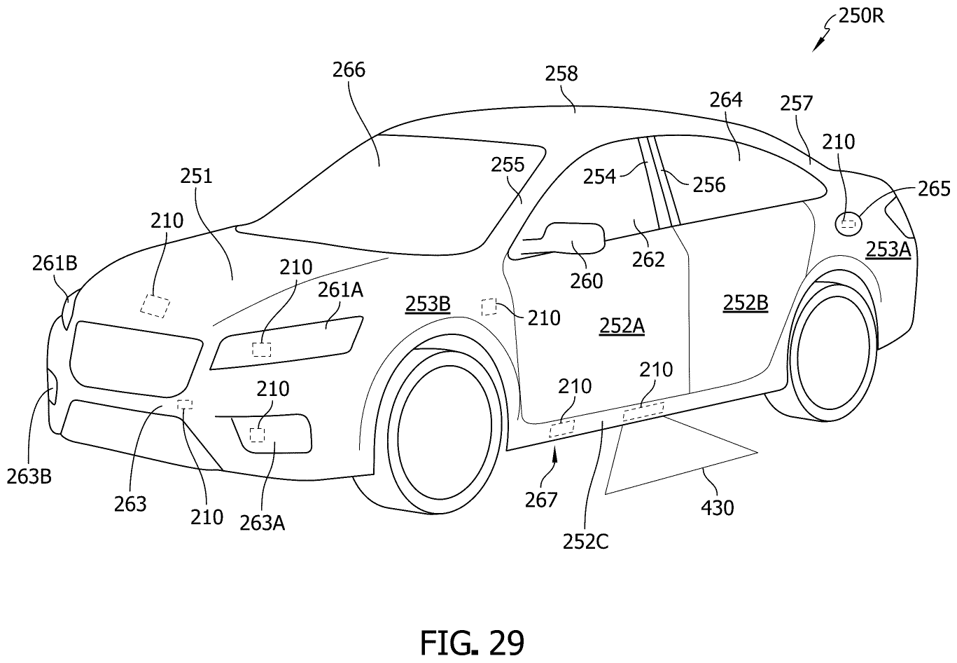

Referring now to FIG. 29, another example motor vehicle 250R is shown in which the motor vehicle access closure control system 200 depicted in FIG. 14 illustratively includes the closure motor 206 and the motor driver 208, such that the signal processing circuit(s) 212 is/are operable to control the motor driver 208 to cause the closure motor 206, or other such drive mechanism, to open and close the access closure 252A. In some such embodiments, no access closure handle per se is mounted to the access closure 252A, and all locking/unlocking, unlatching, opening and closing of the access closure 252A is accomplished via control of the motor driver 208 and, in some embodiments, the actuator 102 and/or the E-latch module 102 in embodiments which include it/them, by the signal processing circuit(s) 212. It will be understood, however, that in some such embodiments an “emergency” closure handle may be mechanically coupled via a mechanical linkage L3 to the closure latch 102 of the access closure 252A, and such an “emergency” access closure handle may be configured to move or articulate relative to the access closure 252A to provide for a mechanical failsafe mechanism for unlatching the closure latch 102 of the access closure 252A in the event of a failure of one or more components of the system 200 illustrated by example in FIG. 14.

The motor vehicle 250R is illustratively as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18. In addition to, or alternatively to, the example mounting locations of the sensor(s) 210 illustrated by example in FIGS. 15 and 18, one or more sensors 210 may illustratively be mounted to or within any of a hood or so-called “frunk” lid 251 of the motor vehicle 250R, a front side panel or so-called front quarter panel 253B of the motor vehicle 250R, a rocker panel 252C of the motor vehicle 250R, a front headlamp or lamp housing 261A (and/or 261B) of the motor vehicle 250R, a front running light or directional light or light housing 263A (and/or 263B), a front dam or skirt 263 of the motor vehicle, a charge port closure 265 of the motor vehicle 250R, and/or an underside 267, e.g., on, behind and/or integrated into one or more surfaces of an external skin of any such component, as depicted by example in FIG. 29.

In some embodiments, one or more sensors 210 may be mounted to the underside 267 of the motor vehicle 250R, as depicted by example in FIG. 29. In some such embodiments, the sensor(s) 210 may be or include at least one proximity sensor or other sensor, some non-limiting examples of which are described above, defining an object sensing zone 430 proximate thereto, as also illustrated by example in FIG. 29. In such embodiments, an object, e.g., all or part of a foot, leg or other object which passes into the zone 430 and is detectable by the sensor(s) 210 may be used by the system 200 as a sensor activation event, as this term is defined above. In other embodiments, the sensor(s) 210 may be or include at least one touch sensor, and in such embodiments an object coming into contact with an under-vehicle surface along which the sensor(s) 210 is/or mounted so as to be detectable such a sensor or sensor(s) 210 may be used by the system 200 as a sensor activation event. In some embodiments, the underside 267 of the motor vehicle 250R to or within which one or more sensor(s) 210 is/are mounted may act as a surrogate to an access closure handle in that such sensor(s) 210 may be activated as just described to control an operational state of the access closure 252A, wherein signals produced by the sensor(s) 210, upon activation thereof as described herein, may be used by the signal processing circuit(s) 212 to control one or more of locking/unlocking, unlatching and control, via the motor driver 208, of opening and/or closing of the access closure 252A. In other alternate embodiments of the embodiment illustrated in FIG. 29, any of the access closure handles illustrated in the attached figures or equivalents thereof may be mounted to the access closure 252A, activation of the one or more sensors 210 mounted within or to the underside 267 of the motor vehicle 250R may be used by the system 200 to unlock/lock or unlatch the access closure 252A to allow for manual opening/closing of the access closure 252A.

In embodiments in which one or more of the sensors 210 is/are alternatively or additionally mounted to the motor vehicle 250R, any such sensor(s) 210 may be mounted to or within any one or more of the components 220 of the motor vehicle as depicted by example in FIGS. 15 and 18, although it will be understood that one or more sensors 210 may be alternatively or additionally mounted to one or more other components of the motor vehicle 250R that is/are not depicted in FIG. 15 or in FIG. 18, as described above.

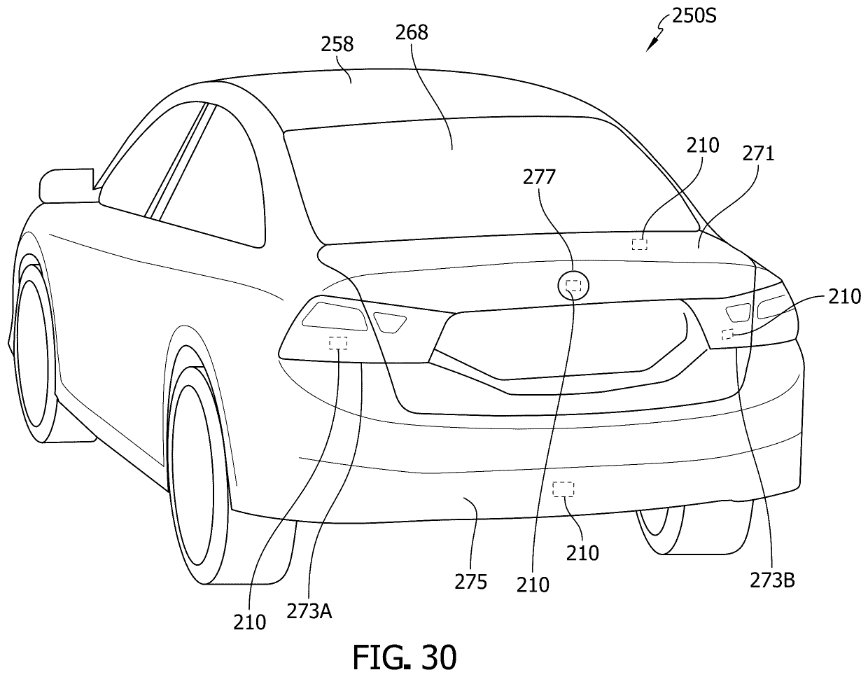

Referring now to FIG. 30, another example motor vehicle 250S is shown in which the motor vehicle access closure control system 200 depicted in FIG. 14 illustratively includes the closure motor 206 and the motor driver 208, such that the signal processing circuit(s) 212 is/are operable to control the motor driver 208 to cause the closure motor 206, or other such drive mechanism, to open and close an access closure 271 in the form of a trunk lid. In some such embodiments, no access closure handle per se is mounted to the access closure 271, and all locking/unlocking, unlatching, opening and closing of the access closure 271 is accomplished via control of the motor driver 208 and, in some embodiments, the actuator 102 and/or the E-latch module 102 in embodiments which include it/them, by the signal processing circuit(s) 212. It will be understood, however, that in some such embodiments an “emergency” closure handle may be mechanically coupled via a mechanical linkage L3 to the closure latch 102 of the access closure 271, and such an “emergency” access closure handle may be configured to move or articulate relative to the access closure 271 to provide for a mechanical failsafe mechanism for unlatching the closure latch 102 of the access closure 271 in the event of a failure of one or more components of the system 200 illustrated by example in FIG. 14.

The motor vehicle 250S is illustratively as described above with respect to the motor vehicle 250A of FIG. 15, and one or more sensors 210 may be mounted to one or any combination of the front access closure 252A, the rear access closure 252B, the window frame 254, the A-pillar 255, the B-pillar 256, the top 258, the side-view mirror 260 and/or any of the windows 262-266 as depicted by example in FIG. 15 and/or to one or any combination of the mirror 260A of the side-view mirror 260, the C-pillar 257, the rear side panel or so-called quarter panel 253A, and/or the rear window 268 as depicted by example in FIG. 18 and/or to one or any combination of the hood or so-called “frunk” lid 251, the front side panel or so-called front quarter panel 253B, a rocker panel 252C, a front headlamp or lamp housing 261A (and/or 261B), a front running light or directional light or light housing 263A (and/or 263B), a front dam or skirt 263 and/or an underside 267 of the motor vehicle 250S, as depicted by example in FIG. 29. In addition to, or alternatively to, the example mounting locations of the sensor(s) 210 illustrated by example in FIGS. 15,18 and 29, one or more sensors 210 may illustratively be mounted to or within any of the trunk lid 271, a rear tail or turn signal lamp or lamp housing 273A (and/or 273B) of the motor vehicle 250S, a rear bumper or skirt 275 of the motor vehicle 250S, e.g., on, behind and/or integrated into one or more surfaces of an external skin of any such component, as depicted by example in FIG. 30.

In the embodiment illustrated by example in FIG. 30, the motor vehicle 250S further includes a badge 277 affixed to the access closure 271, e.g., to a rearwardly-facing surface of the trunk lid 271. The term “badge,” as used with respect to item 277 depicted in FIG. 30, illustratively carries the same meaning described above, i.e., an informational plate or assembly having a display surface bearing information of any type, without restriction, and a mounting surface, opposite the display surface, that is to be attached to an outer surface of the trunk lid 271 of the motor vehicle 250S, as depicted in the example illustrated in FIG. 30, such that the display surface is exposed and faces generally away from the outer surface of the trunk lid 271 to which it is affixed. In some embodiments, the badge 277 may act as a surrogate to an access closure handle in that one or more sensors 210 may be mounted to or within the badge 277 and may be activated as described above to control an operational state of the access closure 271. Although the sensor(s) 210 is/are depicted in FIG. 30 as being disposed along a portion of the outwardly-facing surface of the badge 277, it will be understood that the sensor(s) 210 may alternatively be disposed along any portion of any surface of the badge 277. In any case, signals produced by the sensor(s) 210, upon activation thereof as described herein, may be used by the signal processing circuit(s) 212 to control one or more of locking/unlocking, unlatching and control, via the motor driver 208 and motor 206 (or power unlatching driver), of opening and/or closing of the access closure 271. A non-limiting example of such one or more sensors 210 mounted to or within the badge 400 is disclosed in co-pending international patent application no. PCT/US2023/065275, published as WO 2023/196776, the disclosure of which has been incorporated herein by reference. In embodiments in which one or more of the sensors 210 is/are alternatively or additionally mounted to the motor vehicle 250R, any such sensor(s) 210 may be mounted to or within any one or more of the components 220 of the motor vehicle as depicted by example in FIGS. 15, 18 and 29, although it will be understood that one or more sensors 210 may be alternatively or additionally mounted to one or more other components of the motor vehicle 250S that is/are not depicted in FIG. 15, FIG. 18 or FIG. 29, as described above

It will be further understood that any of the mounting location(s) of the sensor(s) 210 illustrated in any of FIGS. 15, 18 and 30 may be used in any of the embodiments illustrated in the attached figures and described herein. In some embodiments, one or more such sensors 210 may be used in addition to the sensor(s) 210 depicted as being mounted to or within a respective access closure handle or other structure, and in other embodiments one or more such sensors 210 may be used instead of or in place of the sensor(s) 210 depicted as being mounted to or within a respective access closure handle or other structure.

What is claimed is:

1. A system for at least two of locking, unlocking, unlatching, opening or closing an access closure of a motor vehicle, the system comprising:
a plurality of sensors, each mounted to or within an access closure handle mounted to the access closure of the motor vehicle or to or within at least one component of the motor vehicle that is not an access closure handle, the plurality of sensors including first and second sensors configured to produce respective first and second sensor signals and to produce detectable changes in the respective first and second sensor signals upon detection of at least one respective sensor activation event,
one or more signal processing circuits configured to be responsive to the detectable changes in the first and second sensor signals to produce respective first and second control signals, and
means responsive to the first and second control signals to carry out at least two of locking, unlocking, unlatching, opening or closing of the access closure of the motor vehicle.

2. The system of claim 1, wherein the means responsive to the first and second control signals is responsive to one of the first and second control signals to at least one of lock or unlock the access closure and to the other of the first and second control signals to unlatch the access closure.

3. The system of claim 2, wherein the means responsive to the first and second control signals is responsive to the one of the first and second control signals to lock and unlock the access closure.

4. The system of claim 2, wherein the plurality of sensors includes a third sensor configured to produce a third sensor signal and to produce detectable change in the third sensor signal upon detection by the third sensor of at least one corresponding sensor activation event,
and wherein the means responsive to the first and second control signals is responsive to the one of the first and second control signals to one of lock or unlock the access closure and to the third control signal to the other of lock or unlock the access closure.

5. The system of claim 1, and wherein the means responsive to the first and second control signals is responsive to one of the first and second control signals to lock the access closure and to the other of the first and second control signals to unlock the access closure.

6. The system of claim 5, wherein the plurality of sensors includes a third sensor configured to produce a third sensor signal and to produce detectable change in the third sensor signal upon detection by the third sensor of at least one corresponding sensor activation event,
and wherein the one or more signal processing circuits is configured to be responsive to the detectable change in the third sensor signal to produce a third control signal,
and wherein the means responsive to the first and second control signals is responsive to the third control signal to unlatch the access closure after the access closure is unlocked.

7. The system of claim 1, wherein the means responsive to the first and second control signals is responsive to one of the first and second control signals to at least one of open or close the access closure and to the other of the first and second control signals to at least one of lock or unlock the access closure.

8. The system of claim 7, wherein the means responsive to the first and second control signals is responsive to the one of the first and second control signals to open and close the access closure.

9. The system of claim 8, wherein the means responsive to the first and second control signals is responsive to the other of the first and second control signals lock and unlock the access closure.

10. The system of claim 8, wherein the plurality of sensors includes a third sensor configured to produce a third sensor signal and to produce detectable change in the third sensor signal upon detection by the third sensor of at least one corresponding sensor activation event,
and wherein the one or more signal processing circuits is configured to be responsive to the detectable change in the third sensor signal to produce a third control signal,
and wherein the means responsive to the first and second control signals is responsive to the other of the first and second control signals to one of lock or unlock the access closure and to the third control signal to the other of lock or unlock the access closure.

11. The system of claim 7, wherein the plurality of sensors includes a third sensor configured to produce a third sensor signal and to produce detectable change in the third sensor signal upon detection by the third sensor of at least one corresponding sensor activation event,
and wherein the one or more signal processing circuits is configured to be responsive to the detectable change in the third sensor signal to produce a third control signal,
and wherein the means responsive to the first and second control signals is responsive to the one of the first and second control signals to one of open or close the access closure and to the third control signal to the other of open or close the access closure.

12. The system of claim 11, wherein the means responsive to the first and second control signals is responsive to the other of the first and second control signals lock and unlock the access closure.

13. The system of claim 11, wherein plurality of sensors includes a fourth sensor configured to produce a fourth sensor signal and to produce detectable change in the fourth sensor signal upon detection by the fourth sensor of at least one corresponding sensor activation event,
and wherein the one or more signal processing circuits is configured to be responsive to the detectable change in the fourth sensor signal to produce a fourth control signal,
and wherein the means responsive to the first and second control signals is responsive to the other of the first and second control signals to one of lock or unlock the access closure and to the fourth control signal to the other of lock or unlock the access closure.

14. The system of claim 1, wherein the at least one component of the motor vehicle comprises one or any combination of a front access closure, a rear access closure, a window frame, an A-pillar, a B-pillar, a C-pillar, a top, a housing of a side-view mirror, a mirror of a side-view mirror, one or more windows, a rear side panel, a front side panel, a hood, a frunk lid, a rocker panel, a headlamp, a headlamp housing, a front running lamp or housing, a turn signal lamp or housing, a front dam or skirt, an underside, a trunk lid, a tail lamp or housing, a rear bumper or skirt, a charge port closure or a badge of the motor vehicle.

15. The system of claim 1, wherein the plurality of sensors comprises any of one or more short range, non-contacting proximity sensors, one or more long range, non-contacting proximity sensors, one or more deflective touch sensors, one or more non-deflective touch sensors, or one or more other sensors, or any combination thereof.

16. The system of claim 1, wherein the means responsive to the first and second control signals includes:
an actuator, and
a closure lock,
wherein the actuator is responsive to at least one of the first and second control signals to cause the closure lock to lock and unlock.

17. The system of claim 1, wherein the means responsive to the first and second control signals includes:
an E-latch module, and
a closure lock,
wherein the E-latch module is responsive to at least one of the first and second control signals to cause the closure lock to lock and unlock.

18. The system of claim 1, wherein the means responsive to the first and second control signals includes:
a closure latch, and
an E-latch module,
wherein the E-latch module is responsive to at least one of the first and second control signals to cause the closure latch to unlatch.

19. The system of claim 1, further comprising at least one accessory associated with the system or with the motor vehicle,
and wherein the at least one accessory is responsive to the first or second control signal to control operation of the at least one accessory,
and wherein the at least one accessory comprises one or any combination at least one lamp internal to the motor vehicle, at least one lamp external to the motor vehicle, at least one power window, at least one power occupant seat, at least one occupant seat heater, at least one occupant seat cooling device, at least one occupant seat support or comfort device, at least one haptic feedback device internal to the motor vehicle, at least one haptic feedback device external to the motor vehicle, a climate control system of the motor vehicle, an entertainment system of the motor vehicle, a color of at least one interior or external surface of the motor vehicle, a retractable roof of the motor vehicle, a position of a rearview or side mirror, a position of a steering wheel position of the motor vehicle, and a display screen mounted within or to an external surface of the motor vehicle.

20. The system claim 1, wherein the one or more signal processing circuits comprises:
a processor, and
a memory having instructions stored therein executable by the processor to cause the processor to be responsive to the detectable changes in the first and second sensor signals to produce the respective first and second control signals.

21. A door handle assembly for a motor vehicle door, the door handle assembly comprising:
a first housing component having an inner surface and an outer surface,
a second housing component having an inner surface and an outer surface, the first and second housing components together forming a housing with the inner surfaces of the first and second housing components facing one another and with outer surfaces of the first and second housing components together defining an outer surface of the housing, the housing configured to be mounted to the motor vehicle door to define at least a portion of a door handle,
a first sensor mounted in the housing along a first detection surface defined by at least a portion of the outer surface of the housing, the first sensor configured to produce a first sensor signal upon detection of one of an object within a detection proximity of the first detection surface and deflection of at least a portion of the inner surface of the housing opposite the first detection surface to within a detection proximity of the first sensor, and
a second sensor mounted in the housing along a second detection surface defined by at least another portion of the outer surface of the housing, the second sensor configured to produce a second sensor signal upon detection of deflection of at least a portion of the inner surface of the housing opposite the second detection surface to within a detection proximity of the second sensor,
wherein the first and second sensor signals are configured to enable any of locking, unlocking, latching, unlatching, automatically opening and automatically closing of the motor vehicle door.

22. The door handle assembly of claim 21, wherein the first sensor signal is configured to enable one of unlocking and unlocking of the motor vehicle door and the second sensor signal is configured to enable the other of locking and unlocking of the motor vehicle door.

23. The door handle assembly of claim 21, wherein one of the first and second sensor signals is configured to enable at least one of unlocking and unlocking of the motor vehicle door, and the other of the first and second sensor signals is configured to enable unlatching of the motor vehicle door.

24. The door handle assembly of claim 21, wherein one of the first and second sensor signals is configured to enable at least one of unlocking and unlocking of the motor vehicle door, and the other of the first and second sensor signals is configured to enable at least one of automatic opening and automatic closing of the motor vehicle door.

25. The door handle assembly of claim 21, further comprising:
a processor mounted in the housing, and
a memory mounted in the housing and having instructions stored therein executable by the processor cause the processor to be responsive to the first and second sensor signals to control any of the locking, unlocking, latching, unlatching, automatically opening and automatically closing of the motor vehicle door.
